(19) United States
(12) Patent Application Publication
(10) Pub. No.: US 2026/0215126 A1
(43) Pub. Date: Jul. 23, 2026

(54) Light-Emitting Device

(71) Applicant: Semiconductor Energy Laboratory Co., Ltd., Kanagawa-ken (JP)

(72) Inventors: Takeyoshi WATABE, Atsugi, Kanagawa (JP); Hayato YAMAWAKI, Atsugi, Kanagawa (JP); Toshiki SASAKI, Kawasaki, Kanagawa (JP); Nobuharu OHSAWA, Zama, Kanagawa (JP); Satoshi SEO, Sagamihara, Kanagawa (JP)

(73) Assignee: Semiconductor Energy Laboratory Co., Ltd., Kanagawa-ken (JP)

(21) Appl. No.: 19/143,554

(22) PCT Filed: Dec. 21, 2023
(86) PCT No.: PCT/IB2023/063058

§ 371 Date: Jun. 26, 2025

(30) Foreign Application Priority Data
Dec. 28, 2022 (JP) 2022-212557

(51) Int. Cl. H10K 59/80

(52) U.S. Cl. CPC H10K 59/80515

(57) ABSTRACT

An organic semiconductor device with high resolution and high reliability is provided. The organic semiconductor device is a light-emitting device of a plurality of light-emitting devices formed over an insulating layer by a photolithography method. The light-emitting device includes a layer containing an organic compound between a pair of electrodes. The layer containing an organic compound includes a light-emitting layer containing an emission center substance and a first substance. The longest-wavelength absorption edge in the absorption spectrum of the first substance is at a wavelength of less than 400 nm. Alternatively, the first substance does not include a fused ring composed only of six-membered rings.

### TECHNICAL FIELD

One embodiment of the present invention relates to a light-emitting device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Display apparatuses are being developed into a variety of applications these days. For example, a television device for home use (also referred to as TV or television receiver), digital signage, and a public information display (PID) are being developed as large-sized display apparatuses, and a smartphone and a tablet terminal each provided with a touch panel are being developed as small-sized display apparatuses.

At the same time, display apparatuses are also required to achieve higher resolution. As devices requiring high-resolution display apparatuses, for example, devices for virtual reality (VR), augmented reality (AR), substitutional reality (SR), and mixed reality (MR) have been actively developed.

Development is actively conducted on light-emitting devices (also referred to as light-emitting elements) as display elements used in display apparatuses. Light-emitting devices (also referred to as EL devices or EL elements) utilizing electroluminescence (hereinafter referred to as EL) phenomenon, specifically, organic EL devices using mainly organic compounds have features such as ease of reduction in thickness and weight, high-speed response to input signals, and driving with a constant DC voltage power source, thereby being suitable for display apparatuses.

In order to obtain a higher-resolution light-emitting apparatus using an organic EL device, patterning an organic layer by a photolithography method using a photoresist or the like, instead of an evaporation method using a metal mask, has been studied. With the use of the photolithography method, a high-resolution display apparatus in which a distance between EL layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

### Problems to be Solved by the Invention

It has been known that EL layers of organic EL devices exposed to atmospheric components such as water and oxygen have affected initial characteristics or reliability, and thus it was a common sense to treat the EL layers in a near-vacuum atmosphere. However, it is difficult to keep a high vacuum state in a step of processing by a photolithography method as described above. Thus, the reliability of a light-emitting device manufactured by a photolithography method is often lower than that of a light-emitting device manufactured in a near-vacuum atmosphere.

In view of the above, an object of one embodiment of the present invention is to provide a highly reliable light-emitting device using an organic compound that is formed by a photolithography method. An object of another embodiment of the present invention is to provide a light-emitting device which enables a light-emitting apparatus to have high resolution and high reliability.

Another object of one embodiment of the present invention is to provide a light-emitting device with high reliability, which can be arranged at a high density. Another object of one embodiment of the present invention is to provide a light-emitting device with high reliability, which can provide a high-resolution display apparatus.

Another object of one embodiment of the present invention is to provide a display apparatus with high display performance. Another object of one embodiment of the present invention is to provide a display apparatus with high definition and high display performance. Another object of one embodiment of the present invention is to provide a display apparatus with high display quality and high display performance.

Another object is to provide a novel display apparatus, a novel display module, or a novel electronic device.

Note that the description of these objects does not preclude the existence of other objects. One embodiment of the present invention does not necessarily achieve all of these objects. Other objects can be derived from the description of the specification, the drawings, and the claims.

### Means for Solving the Problems

In view of the above, one embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. A longest-wavelength absorption edge in an absorption spectrum of the first substance is at a wavelength of less than 400 nm. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. The first substance does not include a fused ring composed only of six-membered rings. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. The first substance has none of a structure where two adjacent six-membered aromatic rings are fused, a structure where two adjacent six-membered heteroaromatic rings are fused, and a structure where a six-membered aromatic ring and a six-membered heteroaromatic ring that are adjacent to each other are fused. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. The first substance does not have a naphthalene structure. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. The first substance includes none of a naphthalene ring, a phenanthrene ring, and a naphthacene ring. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer containing an emission center substance and a first substance. The first substance includes a fused ring. The number of elements forming the fused ring is 10 or less. A distance between the first layer included in the light-emitting device and a first layer included in another light-emitting device adjacent to the light-emitting device is greater than or equal to 2 μm and less than or equal to 5 μm.

Another embodiment of the present invention is a light-emitting device of a plurality of light-emitting devices included in a light-emitting device group including a first electrode group formed over the same insulating surface, a second electrode facing the first electrode group, and a first layer group positioned between the first electrode group and the second electrode. The first electrode group includes a plurality of first electrodes independent of each other in the plurality of light-emitting devices. The first layer group includes a plurality of first layers each of which are independently provided in each of the plurality of light-emitting devices. The second electrode is a continuous conductive layer shared by the plurality of light-emitting devices. The light-emitting device includes a first electrode of the first electrode group, the second electrode, and a first layer of the first layer group. The second electrode and the first layer overlap with the first electrode. The first layer includes a light-emitting layer including an emission center substance and a first substance. The first substance includes a fused ring. In the fused ring, a six-membered ring and a five-membered ring are alternately fused. A distance between the first layer included in the light-emitting device and a first layer included in another light-emitting device adjacent to the light-emitting device is greater than or equal to 2 μm and less than or equal to 5 μm.

Another embodiment of the present invention is the light-emitting device with the above structure, in which a longest-wavelength absorption edge in an absorption spectrum of the first substance is at a wavelength of less than 400 nm.

Another embodiment of the present invention is the light-emitting device with the above structure, in which a longest-wavelength absorption edge in an absorption spectrum of the light-emitting substance is at a wavelength of less than 400 nm.

Another embodiment of the present invention is the light-emitting device with the above structure, in which the first substance does not absorb light with a wavelength of greater than or equal to 400 nm and less than or equal to 475 nm.

Another embodiment of the present invention is the light-emitting device with the above structure, in which the light-emitting substance absorbs light with a wavelength of greater than or equal to 400 nm and less than or equal to 475 nm.

Another embodiment of the present invention is the light-emitting device with the above structure, in which a difference between a wavelength of a longest-wavelength absorption edge in the absorption spectrum of the light-emitting substance and a wavelength of the longest-wavelength absorption edge in the absorption spectrum of the first substance is preferably greater than or equal to 60 nm.

Another embodiment of the present invention is the light-emitting device with the above structure, in which the first layer contains a second substance and the second substance has a structure having the same feature as the structure described as the feature of the structure of the first substance.

Another embodiment of the present invention is the light-emitting device with the above structure, in which the first layer contains a second substance and a longest-wavelength absorption edge in an absorption spectrum of the second substance is at a wavelength of less than 400 nm.

Another embodiment of the present invention is the light-emitting device with the above structure, in which the first layer contains a second substance and the second substance does not include a fused ring composed only of six-membered rings.

Another embodiment of the present invention is the light-emitting device with the above structure, in which the first layer contains a second substance and the second substance has none of a structure where two adjacent six-membered aromatic rings are fused, a structure where two adjacent six-membered heteroaromatic rings are fused, and a structure where a six-membered aromatic ring and a six-membered heteroaromatic ring that are adjacent to each other are fused.

Another embodiment of the present invention is the light-emitting device with the above structure, in which the first layer contains a second substance and the second substance does not have a naphthalene structure.

Another embodiment of the present invention is the light-emitting device with the above structure, in which the first layer contains a second substance and the second substance includes none of a naphthalene ring, a phenanthrene ring, and a naphthacene ring.

Another embodiment of the present invention is the light-emitting device with the above structure, in which the first layer contains a second substance, the second substance includes a fused ring, and the number of elements forming the fused ring is 10 or less.

Another embodiment of the present invention is the light-emitting device with the above structure, in which the first layer contains a second substance, the second substance includes a fused ring, and the fused ring has a structure where a six-membered ring and a five-membered ring are alternately fused.

Another embodiment of the present invention is the light-emitting device with the above structure, in which one of the first substance and the second substance has a function of transporting electrons and the other has a function of transporting holes.

Another embodiment of the present invention is the light-emitting device with the above structure, in which one of the first substance and the second substance is an organic compound including a π-electron rich heteroaromatic ring and the other is an organic compound having a T-electron deficient heteroaromatic skeleton.

Another embodiment of the present invention is the light-emitting device with the above structure, in which the light-emitting substance emits phosphorescent light.

Another embodiment of the present invention is the light-emitting device with the above structure, in which the light-emitting substance exhibits thermally activated delayed fluorescence.

Another embodiment of the present invention is the light-emitting device with the above structure, in which the light-emitting substance emits light having a shorter wavelength than green.

Another embodiment of the present invention is the light-emitting device with the above structure, in which the light-emitting substance emits light having a spectrum peak at a wavelength of less than or equal to 500 nm.

Another embodiment of the present invention is a display module including the above-described display apparatus and at least one of a connector and an integrated circuit.

Another embodiment of the present invention is an electronic device including the above-described display module and at least one of a housing, a battery, a camera, a speaker, and a microphone.

### Effect of the Invention

According to one embodiment of the present invention, a highly reliable light-emitting device using an organic compound that is formed by a photolithography method can be provided. According to another embodiment of the present invention, a light-emitting device which enables a light-emitting apparatus to have high resolution and high reliability can be provided.

According to another embodiment of the present invention, a light-emitting device with high reliability, which can be arranged at a high density, can be provided. According to another embodiment of the present invention, a light-emitting device with high reliability, which can provide a high-resolution display apparatus.

According to another embodiment of the present invention, a highly reliable display apparatus can be provided. According to another embodiment of the present invention, a display apparatus with high definition and high display performance can be provided. According to another embodiment of the present invention, a display apparatus with high display quality and high display performance can be provided.

According to another embodiment of the present invention, a novel display apparatus, a novel display module, or a novel electronic device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are diagrams illustrating a light-emitting device.

FIG. 2 is diagrams illustrating a light-emitting device.

FIG. 3A and FIG. 3B are a top view and a cross-sectional view of a light-emitting apparatus.

FIG. 4A to FIG. 4E are cross-sectional views illustrating an example of a method for manufacturing a display apparatus.

FIG. 5A to FIG. 5D are cross-sectional views illustrating an example of a method for manufacturing a display apparatus.

FIG. 6A to FIG. 6D are cross-sectional views illustrating an example of a method for manufacturing a display apparatus.

FIG. 7A to FIG. 7C are cross-sectional views illustrating an example of a method for manufacturing a display apparatus.

FIG. 8A to FIG. 8C are cross-sectional views illustrating an example of a method for manufacturing a display apparatus.

FIG. 9A to FIG. 9C are cross-sectional views illustrating an example of a method for manufacturing a display apparatus.

FIG. 10A and FIG. 10B are perspective views illustrating a structure example of a display module.

FIG. 11A and FIG. 11B are cross-sectional views illustrating structure examples of a display apparatus.

FIG. 12 is a perspective view illustrating a structure example of a display apparatus.

FIG. 13 is a cross-sectional view illustrating a structure example of a display apparatus.

FIG. 14 is a cross-sectional view illustrating a structure example of a display apparatus.

FIG. 15 is a cross-sectional view illustrating a structure example of a display apparatus.

FIG. 16A to FIG. 16D are diagrams illustrating examples of electronic devices.

FIG. 17A to FIG. 17F are diagrams illustrating examples of electronic devices.

FIG. 18A to FIG. 18G are diagrams illustrating examples of electronic devices.

FIG. 19A is a graph showing the absorption spectra of organic compounds used in a light-emitting layer of a light-emitting device 1, and FIG. 19B is a graph showing the emission spectrum of fluorescent lamp light and the emission spectrum of orange light.

FIG. 20A is a graph showing the absorption spectra of organic compounds used in a light-emitting layer of a light-emitting device 2, and FIG. 20B is a graph showing the emission spectrum of fluorescent lamp light and the emission spectrum of orange light.

FIG. 21A is a graph showing the absorption spectra of organic compounds used in a light-emitting layer of a light-emitting device 3, and FIG. 21B is a graph showing the emission spectrum of fluorescent lamp light and the emission spectrum of orange light.

FIG. 22A is a graph showing the absorption spectra of organic compounds used in a light-emitting layer of a light-emitting device 4, and FIG. 22B is a graph showing the emission spectrum of fluorescent lamp light and the emission spectrum of orange light.

FIG. 23A to FIG. 23D are graphs showing the initial characteristics of the light-emitting devices 1.

FIG. 24A to FIG. 24D are graphs showing the initial characteristics of the light-emitting devices 2.

FIG. 25A to FIG. 25D are graphs showing the initial characteristics of the light-emitting devices 3.

FIG. 26A to FIG. 26D are graphs showing the initial characteristics of the light-emitting devices 4.

FIG. 27A to FIG. 27D are graphs showing changes in luminance over driving time of the light-emitting devices 1 to the light-emitting devices 4.

FIG. 28A is a graph showing the absorption spectra of host materials used in a light-emitting layer of a light-emitting device 5, and FIG. 28B is a graph showing the emission spectrum of fluorescent lamp light and the emission spectrum of orange light.

FIG. 29 is a graph showing the luminance-current density characteristics of the light-emitting devices 5.

FIG. 30 is a graph showing the current efficiency-luminance characteristics of the light-emitting devices 5.

FIG. 31 is a graph showing the luminance-voltage characteristics of the light-emitting devices 5.

FIG. 32 is a graph showing the current density-voltage characteristics of the light-emitting devices 5.

FIG. 33 is a graph showing the blue index-luminance characteristics of the light-emitting devices 5.

FIG. 34 is a graph showing the emission spectra of the light-emitting devices 5.

FIG. 35 is a graph showing changes in luminance over driving time of the light-emitting devices 5.

FIG. 36A is a graph showing the absorption spectra of host materials used in a light-emitting layer of a comparative light-emitting device 1, and FIG. 36B is a graph showing the emission spectrum of fluorescent lamp light and the emission spectrum of orange light.

FIG. 37 is a graph showing the luminance-current density characteristics of the comparative light-emitting devices 1.

FIG. 38 is a graph showing the current efficiency-luminance characteristics of the comparative light-emitting devices 1.

FIG. 39 is a graph showing the luminance-voltage characteristics of the comparative light-emitting devices 1.

FIG. 40 is a graph showing the current density-voltage characteristics of the comparative light-emitting devices 1.

FIG. 41 is a graph showing the blue index-luminance characteristics of the comparative light-emitting devices 1.

FIG. 42 is a graph showing the emission spectra of the comparative light-emitting devices 1.

FIG. 43 is a graph showing changes in luminance over driving time of the comparative light-emitting devices 1.

FIG. 44A is a graph showing the absorption spectra of host materials used in a light-emitting layer of a comparative light-emitting device 2, and FIG. 44B is a graph showing the emission spectrum of fluorescent lamp light and the emission spectrum of orange light.

FIG. 45 is a graph showing the luminance-current density characteristics of the comparative light-emitting devices 2.

FIG. 46 is a graph showing the current efficiency-luminance characteristics of the comparative light-emitting devices 2.

FIG. 47 is a graph showing the luminance-voltage characteristics of the comparative light-emitting devices 2.

FIG. 48 is a graph showing the current density-voltage characteristics of the comparative light-emitting devices 2.

FIG. 49 is a graph showing the external quantum efficiency-luminance characteristics of the comparative light-emitting devices 2.

FIG. 50 is a graph showing the emission spectra of the comparative light-emitting devices 2.

FIG. 51 is a graph showing changes in luminance over driving time of the comparative light-emitting devices 2.

FIG. 52A and FIG. 52B are graphs showing the absorbance of host materials.

FIG. 53 is a graph showing the molar absorption coefficients of light-emitting substances.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in this specification and the like, a device manufactured using a metal mask or an FMM (a fine metal mask, a high-resolution metal mask) may be referred to as a device having an MM (a metal mask) structure. In addition, in this specification and the like, a device manufactured without using a metal mask or an FMM is sometimes referred to as a device having an MML (metal maskless) structure.

### Embodiment 1

As a method for forming an organic semiconductor film in a predetermined shape, a vacuum evaporation method using a metal mask (mask vapor deposition) is widely used. Meanwhile, in these days, higher density and higher resolution are being progressed; mask vapor deposition has come close to the limit of increasing the resolution for various reasons such as the alignment accuracy and the distance between the mask and the substrate.

Meanwhile, shape processing of an organic semiconductor film by a photolithography method is expected to achieve an organic semiconductor device with a finer pattern. Moreover, since a photolithography method facilitates processing on a large area as compared to a mask vapor deposition method, the processing of an organic semiconductor film by a photolithography method is being researched.

However, the shape processing of an organic semiconductor film by a photolithography method requires many problems to be overcome. Examples of these problems include an effect of exposure to the air of the organic semiconductor film, an effect of light irradiation in exposure of a photosensitive resin to light, and an effect of developer, water, and the like to which the light-exposed photosensitive resin is exposed at the time of development. Due to these effects, the characteristics of the light-emitting devices manufactured by a photolithography method is often lower than those of the light-emitting devices manufactured in a continuous vacuum.

One of the causes of such malfunction is impurities (deterioration products) generated when a material included in a light-emitting device deteriorates. It is known that such impurities (deterioration products) are generated by light irradiation in an air atmosphere.

The impurities correspond to a decomposition product, an oxygen adduct, or the like of a material and can be actually detected. The generation and present of such impurities in the light-emitting device greatly influence the initial characteristics and reliability. Thus, it has been difficult to perform processing by a photolithography process on a light-emitting device including a material that could generate such impurities.

However, when white light is replaced with light not containing short-wavelength components of 475 nm or less as light with which an organic semiconductor film is irradiated in an air atmosphere or when light irradiation is not performed, processing can be performed without causing deterioration of the organic semiconductor film. That is, a light-emitting device is not irradiated with light with high energy including short-wavelength components of 475 nm or less in the step of performing air exposure in the photolithography process, which enables processing by the photolithography process without generation of impurities (deterioration products).

However, white light is generally used for lights and includes short-wavelength components of 475 nm or less. Accordingly, replacement of lights that emit white light with lights that emit light not including light with a wavelength of 475 nm or less such as orange lights allows processing of a light-emitting device by a photolithography process without generation of impurities (deterioration products); however, it requires a relatively large amount of capital investment. Furthermore, the light in which the short-wavelength components are removed lowers visibility and thus might be likely to cause oversight of troubles.

Here, in one embodiment of the present invention, an organic compound having the longest-wavelength absorption edge among absorption edges in the absorption spectrum at 400 nm or less is used for a material other than a light-emitting substance (hereinafter referred to as a host material, and the host material may be formed of a plurality of organic compounds), which is contained in a light-emitting layer of a light-emitting device, so that a light-emitting device in which deterioration is less likely to occur even when an organic semiconductor film is exposed to the air under a white light such as a fluorescent lamp or a white LED can be obtained. That is, the host material does not absorb light with a wavelength of 400 nm to 475 nm and cause formation of an unstable excited state, which enables the light-emitting device in which deterioration is less likely to occur even with air exposure under a white light such as a fluorescent lamp or a white LED. Note that the light-emitting substance refers to a substance that actually emits light in the light-emitting layer.

“The host material does not absorb light with a wavelength of 400 nm to 475 nm” means the case where the absorbance at a wavelength of greater than or equal to 400 nm and less than or equal to 475 nm of a 50-nm-thick film containing the host material is less than or equal to 0.05, preferably less than or equal to 0.01, further preferably less than or equal to 0.005, still further preferably less than or equal to 0.001, for example.

At this time, even when the longest-wavelength absorption edge among absorption edges in the absorption spectrum of the light-emitting substance is at greater than or equal to 400 nm and less than or equal to 475 nm, deterioration of the light-emitting device is not promoted. Thus, the longest-wavelength absorption edge among absorption edges in the absorption spectrum of the light-emitting substance may be at a wavelength of greater than or equal to 400 nm and less than or equal to 475 nm. That is, the light-emitting device in which deterioration is less likely to occur even when exposed to the air under a white light such as a fluorescent lamp or a white LED can be obtained unless the host material in the organic semiconductor film containing the light-emitting substance and the host material does not absorb light with high energy having a wavelength of 400 nm to 475 nm even when the light-emitting substance absorbs light with high energy having a wavelength of 400 nm to 475 nm. Note that at this time, the difference in the wavelength between the longest-wavelength absorption edge among absorption edges in the absorption spectrum of the host material and that of the light-emitting substance is preferably greater than or equal to 60 nm. This can inhibit energy of light absorbed by the light-emitting substance from transferring to the host material owing to the energy of room temperature or the influence of an electric field or the like and enables the light-emitting device in which deterioration is less likely to occur, which is preferable.

Note that the molar absorption coefficient of the light-emitting substance at a wavelength of greater than or equal to 400 nm and less than or equal to 475 nm may be higher than or equal to 1000 M⁻¹·cm⁻¹, higher than or equal to 2000 M⁻¹·cm⁻¹, higher than or equal to 5000 M⁻¹·cm⁻¹, or higher than or equal to 10000 M⁻¹·cm⁻¹

The light-emitting substance is preferably a material that emits phosphorescent light, particularly preferably a material that emits phosphorescent light with a wavelength shorter than that of green, further preferably a material that emits phosphorescent light with a spectrum peak at less than or equal to 500 nm because excitation energy of the host material having the longest-wavelength absorption edge among absorption edges at a wavelength of less than 400 nm can be efficiently transferred to the light-emitting substance to cause light emission

Alternatively, the light-emitting substance is preferably a material that exhibits thermally activated delayed fluorescence because excitation energy of the host material having the longest-wavelength absorption edge among absorption edges at a wavelength of less than 400 nm can be efficiently transferred to emit light.

Note that the absorption spectra can be measured either in a thin-film state or in a solution state. Note that when spectra are compared with each other, it is preferable that the samples have the same state, i.e., the samples be in a thin-film state or the samples be in a solution state.

In the case where the measurement is performed with a sample in a solution state, as a solvent, hexane, benzene, toluene, diethyl ether, ethyl acetate, chloroform, chlorobenzene, dichloromethane, 2-methyltetrahydrofuran (2-MeTHF), or the like can be used; it is preferable to use toluene, dichloromethane, or 2-MeTHF. Furthermore, in observation of a phosphorescent component at a low temperature, a mixed solvent of iodobenzene:dichloromethane:toluene=20%:40%:40%, or the like may be used, in which case a favorable glass state can be formed.

The wavelength of the absorption edge of the absorption spectrum is the wavelength at the intersection of the horizontal axis (wavelength) or the base line and a tangent which is drawn at a value at which the slope of the spectrum on the longer wavelength side with respect to the longest-wavelength peak among absorption edges in the absorption spectrum is most negative.

When the host material absorbs light, the weak skeleton included in the host material is affected and deteriorates. In the light-emitting device of one embodiment of the present invention, the molecular structure of the host material contained in the light-emitting layer does not include a fused aromatic ring composed only of six-membered rings, whereby the light-emitting device in which deterioration is less likely to occur even when exposed to the air under a white light such as a fluorescent lamp or a white LED can be obtained. In the case where the molecular structure of the host material contained in the light-emitting layer does not include a fused aromatic ring composed only of six-membered rings, the light-emitting device which has a resistance to air exposure under a white light such as a fluorescent lamp or a white LED and whose deterioration is reduced can be obtained even when the longest-wavelength absorption edge among absorption edges in the absorption spectrum of the host material is at a wavelength of greater than or equal to 400 nm. Note that the host material preferably does not include a fused aromatic ring composed only of six-membered rings and has the longest-wavelength absorption edge among absorption edges in the absorption spectrum at a wavelength of less than or equal to 400 nm.

Examples of a structure of the above-described fused aromatic ring composed only of six-membered rings include a structure in which two or more adjacent six-membered aromatic hydrocarbon rings are fused, a structure in which two or more adjacent six-membered heteroaromatic rings are fused, a structure in which one or more six-membered aromatic hydrocarbon rings and one or more six-membered heteroaromatic rings that are adjacent to each other are fused, and the like. An example of the six-membered aromatic hydrocarbon ring is a benzene ring. Examples of the six-membered heteroaromatic ring include a pyridine ring, a pyrazine ring, a pyrimidine ring, a pyridazine ring, a triazine ring, an oxazine ring, a pyran ring, a dioxin ring, a thiopyran ring, a thiazine ring, and a dithiin ring.

A typical example of the structure in which two or more adjacent six-membered heteroaromatic rings are fused is a naphthalene structure in which two adjacent six-membered aromatic hydrocarbon rings are fused. Examples of the fused ring having the naphthalene structure include a naphthalene ring, an anthracene ring, a phenanthrene ring, a triphenylene ring, a pyrene ring, a chrysene ring, a tetraphene ring, a perylene ring, and a naphthacene ring. Typical examples of the structure in which two or more adjacent six-membered heteroaromatic rings are fused include a naphthydyrine ring, a pteridine ring, and an anthyridine ring. Typical examples of the structure in which one or more six-membered aromatic hydrocarbon rings and one or more six-membered heteroaromatic rings that are adjacent to each other are fused include a quinoline ring, an isoquinoline ring, a quinoxaline ring, a quinazoline ring, a phthalazine ring, a cinnoline ring, a phenanthridine ring, an acridine ring, a phenanthroline ring, a phenazine ring, a phenoxazine ring, and a phenothiazine ring.

In the case where the host material contained in the light-emitting layer does not have the above-described weak skeletons, the light-emitting device in which deterioration is less likely to occur even when exposed to the air under a white light such as a fluorescent lamp or a white LED can be obtained even when the longest-wavelength absorption edge among absorption edges in the absorption spectrum of the host material is at a wavelength of greater than or equal to 400 nm. Note that even in the case where the host material contained in the light-emitting layer does not have the above-described weak skeletons, the longest-wavelength absorption edge among absorption edges in the absorption spectrum of the host material is preferably at a wavelength of less than 400 nm, in which case deterioration is further inhibited.

Note that the case where the host material contained in the light-emitting layer does not have the above-described weak skeletons indicates the case where the host material does not include a fused ring and the case where the host material includes a fused ring having a structure other than the above-described structure.

That is, in the light-emitting device of one embodiment of the present invention, in the case where the host material includes a fused ring, the fused ring is a fused aromatic ring composed of 10 or less elements or a fused ring having a structure where a five-membered ring and a six-membered ring are alternately fused. In the case where the host material includes a plurality of fused rings, the plurality of fused rings are preferably fused aromatic rings composed of 10 or less elements or fused rings having a structure where a five-membered ring and a six-membered ring are alternately fused, neither of which has the structure where two or more adjacent six-membered aromatic hydrocarbon rings are fused; and the plurality of fused rings are each preferably a fused aromatic ring composed of 10 or less elements or a fused ring having a structure where a five-membered ring and a six-membered ring are alternately fused. Specific examples of the fused ring include an indene ring, a fluorene ring, an indacene ring, a pyrindine ring, an indoline ring, a carbazole ring, a benzofuran ring, a dibenzofuran ring, a benzothiophene ring, a dibenzothiophene ring, an indolocarbazole ring, an indole ring, an isoindole ring, an indazole ring, a purine ring, an azaindole ring, a benzoxazole ring, and a benzothiazole ring. In the case where all the fused rings included in the host material are rings having such a structure, the light-emitting device in which deterioration is less likely to occur even when exposed to the air under a white light such as a fluorescent lamp or a white LED can be obtained even when the longest-wavelength absorption edge among absorption edges in the absorption spectrum of the host material is at a wavelength of greater than or equal to 400 nm. Note that even in the case where all the fused rings included in the host material have such structures, the longest-wavelength absorption edge among absorption edges in the absorption spectrum of the host material is preferably at a wavelength of less than 400 nm, in which case deterioration is further inhibited.

Note that in the case where the host material is composed of a plurality of materials, each of the plurality of host materials preferably has the above-described structure. That is, in the case where the host material is composed of two kinds of materials, for example, a second host material is preferably an organic compound having the longest-wavelength absorption edge among absorption edges in the absorption spectrum at less than 400 nm, like the above-described host material. Alternatively, the second host material preferably does not absorb light with high energy having a wavelength of 400 nm to 475 nm. Alternatively, the second host material preferably does not include a fused aromatic ring composed only of six-membered rings in the molecular structure. Alternatively, the second host material preferably does not have a structure in which two or more adjacent six-membered aromatic hydrocarbon rings are fused, a structure in which two or more adjacent six-membered heteroaromatic rings are fused, and a structure in which one or more six-membered aromatic hydrocarbon rings and one or more six-membered heteroaromatic rings that are adjacent to each other are fused. Alternatively, the second host material preferably has a structure without a fused ring including a naphthalene structure, e.g., a naphthalene ring, an anthracene ring, a phenanthrene ring, or a naphthacene ring. Alternatively, the second host material preferably includes a fused ring composed of 10 or less elements and not having the structure where two or more adjacent six-membered aromatic hydrocarbon rings are fused or a fused ring having a structure where a five-membered ring and a six-membered ring are alternately fused.

In the case where the host material is composed of two kinds of materials, one of them preferably has an electron-transport property and the other preferably has a hole-transport property. That is, one of the two kinds of host materials is preferably an electron-transport organic compound and the other is preferably a hole-transport organic compound.

The electron-transport organic compound is preferably a substance having an electron mobility higher than or equal to 1×10⁻⁷ cm²/Vs, further preferably higher than or equal to 1×10⁻⁶ cm²/Vs at a square root of the electric field intensity [V/cm] of 600. Note that any other substance can also be used as long as the substance has an electron-transport property higher than a hole-transport property. An organic compound having a π-electron deficient heteroaromatic ring skeleton is preferably used. Examples of the organic compound having a T-electron deficient heteroaromatic ring skeleton includes an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton. Among the above materials, the organic compound including a heteroaromatic ring having a diazine skeleton (such as a pyrimidine skeleton, a pyrazine skeleton, or a pyridazine skeleton), the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor property and reliability. Examples of such organic compounds include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl) tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis (5-methylbenzoxazol-2-yl) stilbene (abbreviation: BzOs); an organic compound including a heteroaromatic ring having a pyridine skeleton, such as 3,5-bis[3-(9H-carbazol-9-yl)phenyl]pyridine (abbreviation: 35DCzPPy), 1,3,5-tri [3-(3-pyridyl)phenyl] benzene (abbreviation: TmPyPB), bathophenanthroline (abbreviation: BPhen), bathocuproine (abbreviation: BCP), 2,9-di (naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{3-[3-(N-phenyl-9H-carbazol-3-yl)-9H-carbazol-9-yl]phenyl}dibenzo[f,h]quinoxaline (abbreviation: 2mPCCzPDBq), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl] benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8 (βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl) bis {4-[4-(2-naphthyl)phenyl]-6-phenylpyrimidine} (abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound including a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl] phenyl}-4,6-diphenyl-1,3,5-triazine (abbreviation: mBnfBPTzn), 2-{3-[3-(benzo[b]naphtho[1,2-d]furan-6-yl)phenyl] phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno [2,1-b]carbazole (abbreviation: mINc (II) PTzn), 2-{3-[3-(dibenzothiophen-4-yl)phenyl] phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo [2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl-1-dibenzofuranyl]-1,3,5-triazine (abbreviation: mBP-TPDBfTzn), or 2-[4-(2-naphthalenyl)phenyl]-4-phenyl-6-spiro[9H-fluorene-9,9′-[9H]xanthen]-4-yl-1,3,5-triazine (abbreviation: βNP-SFx(4)Tzn). Among these examples, it is preferable to use an organic compound that does not include a fused aromatic ring composed only of six-membered rings; or an organic compound that does not have a structure in which two or more adjacent six-membered aromatic hydrocarbon rings are fused, a structure in which two or more adjacent six-membered heteroaromatic rings are fused, and a structure in which one or more six-membered aromatic hydrocarbon rings and one or more six-membered heteroaromatic rings that are adjacent to each other are fused. Among them, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage, which is preferable.

The hole-transport organic compound is preferably a substance having a hole mobility higher than or equal to 1×10⁻⁷ cm²/Vs, further preferably higher than or equal to 1×10⁻⁶ cm²/Vs at a square root of the electric field intensity [V/cm] of 600. Note that any other substance can also be used as long as the substance have a hole-transport property higher than an electron-transport property. An organic compound having an amine skeleton or a π-electron rich heteroaromatic ring skeleton is preferably used. Examples of such organic compounds include a compound having an aromatic amine skeleton, 4,4′-bis[N-(1-naphthyl)-N-phenylamino]biphenyl (abbreviation: NPB), N,N-diphenyl-N,-bis(3-methylphenyl)-4,4′-diaminobiphenyl (abbreviation: TPD) (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among these examples, it is preferable to use an organic compound that does not include a fused aromatic ring composed only of six-membered rings; or an organic compound that does not have a structure in which two or more adjacent six-membered aromatic hydrocarbon rings are fused, a structure in which two or more adjacent six-membered heteroaromatic rings are fused, and a structure in which one or more six-membered aromatic hydrocarbon rings and one or more six-membered heteroaromatic rings that are adjacent to each other are fused. Among the above materials, the compound having an aromatic amine skeleton and the compound having a carbazole skeleton are preferable because these compounds are highly reliable and have high hole-transport properties to contribute to a reduction in driving voltage.

The light-emitting device of one embodiment of the present invention having the above-described structure can have favorable characteristics with reduced deterioration even when manufactured through a photolithography process. In particular, the light-emitting device can have favorable reliability. Alternatively, the light-emitting device can have a low driving voltage. Alternatively, the light-emitting device can have favorable emission efficiency.

### Embodiment 2

In this embodiment, a light-emitting device of one embodiment of the present invention will be described in detail.

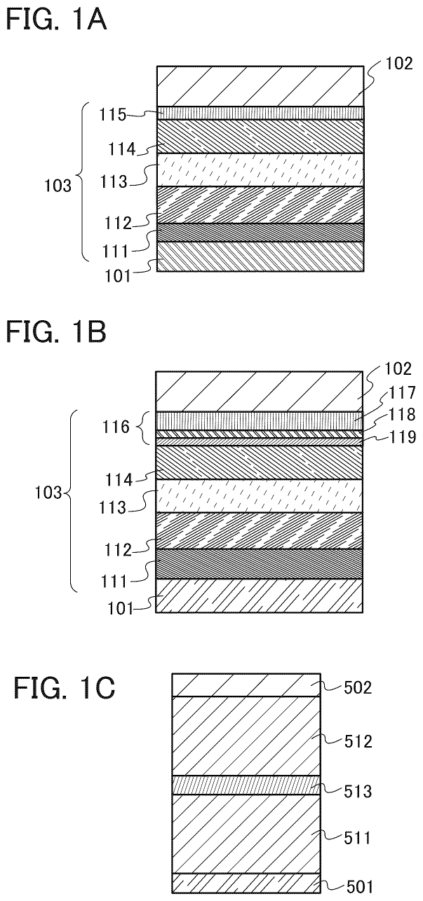

FIG. 1 illustrate schematic diagrams of light-emitting devices of one embodiment of the present invention. A light-emitting device 130 includes a first electrode 101 over an insulator, and an organic compound layer 103 between the first electrode 101 and a second electrode 102. The organic compound layer 103 includes at least a light-emitting layer 113, and the light-emitting layer 113 includes a light-emitting substance and a host material. The light-emitting substance emits light when voltage is applied between the first electrode 101 and the second electrode 102. Furthermore, the organic compound layer 103 has both patterns: a case where the organic compound layer 103 is composed of a first layer 104 independently provided in each light-emitting device and a case where the organic compound layer 103 has a stacked-layer structure of the first layer 104 independently provided in each light-emitting device and a second layer (common layer) 105 shared by a plurality of light-emitting devices.

The host material corresponds to the host material described in Embodiment 1. Note that the host material may be composed of a plurality of materials as described in Embodiment 1. For example, in the case where the host material is composed of two kinds of materials, the light-emitting layer 113 contains the light-emitting substance, a first substance, and a second substance, and in the case where the host material is composed of three kinds of materials, the light-emitting layer contains the light-emitting substance, the first substance, the second substance, and a third substance. In the case where the host material is composed of a plurality of materials, all of the plurality of materials are preferably substances having the feature of the host material described in Embodiment 1. The detailed structure of the host material and the substance used are described in detail in Embodiment 1; thus, repeated description will be omitted.

The organic compound layer 103 preferably includes functional layers such as a hole-injection layer 111, a hole-transport layer 112, an electron-transport layer 114, and an electron-injection layer 115 in addition to the light-emitting layer 113, as illustrated in FIG. 1A. Note that the organic compound layer 103 may include functional layers other than the above functional layers, such as a hole-blocking layer, an electron-blocking layer, an exciton-blocking layer, and a charge-generation layer. Alternatively, any of the above-described layers may be omitted.

Although the first electrode 101 includes an anode and the second electrode 102 includes a cathode in this embodiment, the first electrode 101 may include a cathode and the second electrode 102 may include an anode. The first electrode 101 and the second electrode 102 each have a single-layer structure or a stacked-layer structure. In the case of the stacked-layer structure, a layer in contact with the organic compound layer 103 serves as an anode or a cathode. In the case where the electrodes each have the stacked-layer structure, there is no limitation on work functions of materials for layers other than the layer in contact with the organic compound layer 103, and the materials can be selected in accordance with required properties such as a resistance value, processing easiness, reflectivity, light-transmitting property, and stability.

The anode is preferably formed using any of a metal, an alloy, and a conductive compound with a high work function (specifically, higher than or equal to 4.0 eV), a mixture thereof, or the like. Specific examples include indium oxide-tin oxide (ITO: Indium Tin Oxide), indium oxide-tin oxide containing silicon or silicon oxide (ITSO: Indium Tin Silicon Oxide), indium oxide-zinc oxide, and indium oxide containing tungsten oxide and zinc oxide (IWZO). Such conductive metal oxide films are usually deposited by a sputtering method, but may be formed by application of a sol-gel method or the like. In an example of the formation method, indium oxide-zinc oxide is formed by a sputtering method using a target obtained by adding 1 to 20 wt % of zinc oxide to indium oxide. Furthermore, indium oxide containing tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), and nitride of a metal material (e.g., titanium nitride). The anode may be a stack of layers formed using any of these materials. For example, a film in which Al, Ti, and ITSO are stacked in this order over Ti is preferable because the film has high efficiency owing to high reflectivity and enables high resolution of several thousand ppi. Graphene can also be used for the anode. Note that when a composite material described later, which can be used in the hole-injection layer 111, is used for a layer (typically, a hole-injection layer) that is in contact with the anode, an electrode material can be selected regardless of its work function.

The hole-injection layer 111 is provided in contact with the anode and has a function of facilitating injection of holes into the organic compound layer 103. The hole-injection layer 111 can be formed using phthalocyanine (abbreviation: H₂Pc), a phthalocyanine-based compound or complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. Examples of the substance having an acceptor property include an organic compound having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds.

The hole-injection layer 111 is preferably formed using a composite material containing the above material having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the organic compound having a hole-transport property that is used in the composite material preferably has a hole mobility of 1×10⁻⁶ cm²/Vs or higher. The organic compound having a hole-transport property that is used in the composite material is preferably a compound including a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further fused to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property is preferably a substance having an N,N-bis(4-biphenyl)amino group in order to manufacture a light-emitting device having a long lifetime.

Specific examples of the above-described organic compounds having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used: N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, whereby a light-emitting device having a low driving voltage can be obtained.

Among substances having an acceptor property, an organic compound having an acceptor property is easy to use because it is easily deposited by vapor deposition.

The hole-transport layer 112 is formed to contain an organic compound having a hole-transport property. The organic compound having a hole-transport property preferably has a hole mobility higher than or equal to 1×10⁻⁶ cm²/Vs. The organic compound having a hole-transport property is preferably an organic compound having an amine skeleton, a π-electron rich heteroaromatic ring skeleton, or the like. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property is preferably an organic compound having an N,N-bis(4-biphenyl)amino group in order to manufacture a light-emitting device having a long lifetime.

Examples of the organic compound having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in the hole-transport layer 112.

As an emission center substance, a fluorescent substance, a phosphorescent substance, a material exhibiting thermally activated delayed fluorescence (TADF material), or any other light-emitting substance may be used, and the phosphorescent substance or the TADF material is preferably used because excitation energy can be efficiently transferred from the host material having the longest-wavelength absorption edge among absorption edges at a wavelength of less than or equal to 400 nm. In particular, an emission center substance is preferably a material emitting light with a wavelength shorter than that of green, further preferably a phosphorescent substance which has a spectrum peak at a wavelength of less than or equal to 500 nm or a TADF material.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

In the case where a phosphorescent substance is used as the light-emitting substance in the light-emitting layer, the following materials can be given as examples of the phosphorescent substance.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-{1-[2,6-bis(1-methylethyl)phenyl]-1H-imidazol-2-yl-κN3}-4-cyanophenyl-κC}(abbreviation: CNImIr); an organometallic complex having a benzimidazolidene skeleton, such as tris[(6-tert-butyl-3-phenyl-(2H-imidazo[4,5-b]pyrazin-1-yl-κC2)phenyl-κC]iridium(III) (abbreviation: [Ir(cb)₃]); and an organometallic iridium complex in which a phenylpyridine derivative having an electron-withdrawing group is a ligand, such as bis[2-(4′, 6′-difluorophenyl)pyridinato-N,C^{2′}]iridium(III) tetrakis(1-pyrazolyl)borate (abbreviation: FIr6), bis[2-(4′, 6′-difluorophenyl)pyridinato-N,C^{2′}]iridium(III) picolinate (abbreviation: FIrpic), bis{2-[3′, 5′-bis(trifluoromethyl)phenyl]pyridinato-N,C^{2′}}iridium(III) picolinate (abbreviation: [Ir(CF₃ppy)₂(pic)]), or bis[2-(4′, 6′-difluorophenyl)pyridinato-N,C^{2′}]iridium(III) acetylacetonate (abbreviation: FIracac). These compounds emit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)2(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)2(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-AN)benzofuro[2,3-b]pyridine-κC]bis[2-(5-d₃-methyl-2-pyridinyl-κN2)phenyl-κC]iridium(III) (abbreviation: [Ir(5mppy-d₃)2(mbfpypy-d₃)]), {2-(methyl-d₃)-8-[4-(1-methylethyl-1-d)-2-pyridinyl-κN]benzofuro[2,3-b]pyridine-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-AV)benzofuro[2,3-b]pyridine-κC]bis[2-(2-pyridinyl-AN)phenyl-κC]iridium(III) (abbreviation: Ir(ppy)₂(mbfpypy-d₃)), [2-(4-methyl-5-phenyl-2-pyridinyl-AN)phenyl-κC]bis[2-(2-pyridinyl-κN)phenyl-κC]iridium(III) (abbreviation: Ir(ppy)₂(mdppy)), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-AN)phenyl-κC]iridium(III) (abbreviation: [Ir(ppy)₂(mbfpypy)]), or [2-(4-methyl-5-phenyl-2-pyridinyl-AN)phenyl-κC]bis[2-(2-pyridinyl-κN)phenyl-κC]iridium (abbreviation: [Ir(ppy)₂(mdppy)]); and a rare earth metal complex such as tris(acetylacetonato) (monophenanthroline)terbium(III) (abbreviation: [Tb(acac)₃(Phen)]). These are mainly compounds that emit green phosphorescent light and have an emission peak in the wavelength range of 500 nm to 600 nm. Note that organometallic iridium complexes having a pyrimidine skeleton have distinctively high reliability or emission efficiency and thus are particularly preferable.

The examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO4,κO6)bis[2,4-dimethyl-6-[7-(1-methylethyl)-1-isoquinolinyl-κN]phenyl-κC]iridium(III), and (3,7-diethyl-4,6-nonanedionato-κO4,κO6)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range of 600 nm to 700 nm. Organometallic iridium complexes having a pyrazine skeleton can provide red light emission with favorable chromaticity.

Besides the above-described phosphorescent compounds, other known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

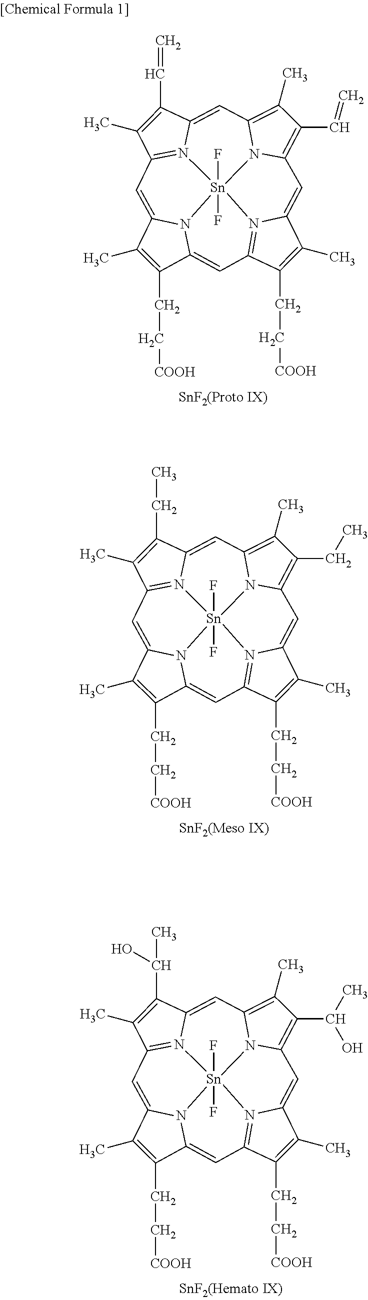

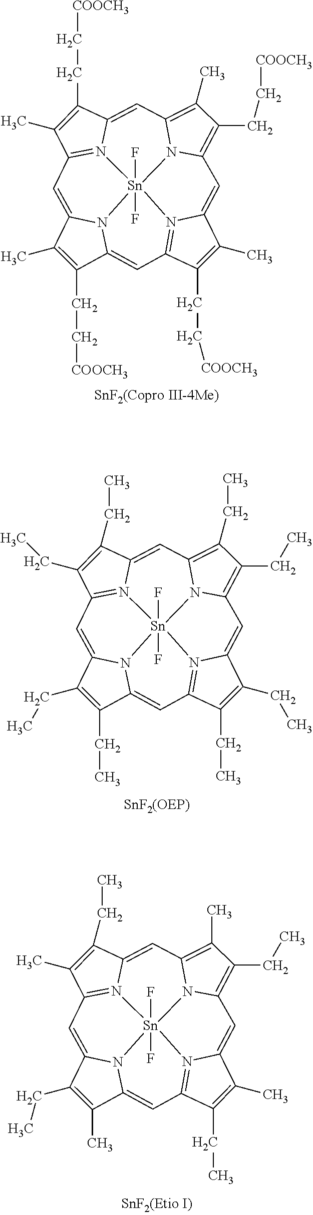

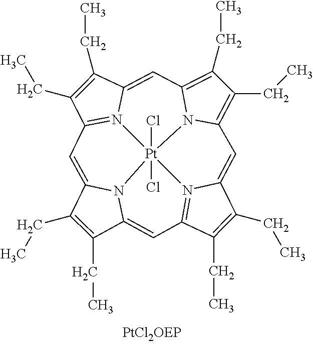

A heterocyclic compound having one or both of a 7r-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons including the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons including the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

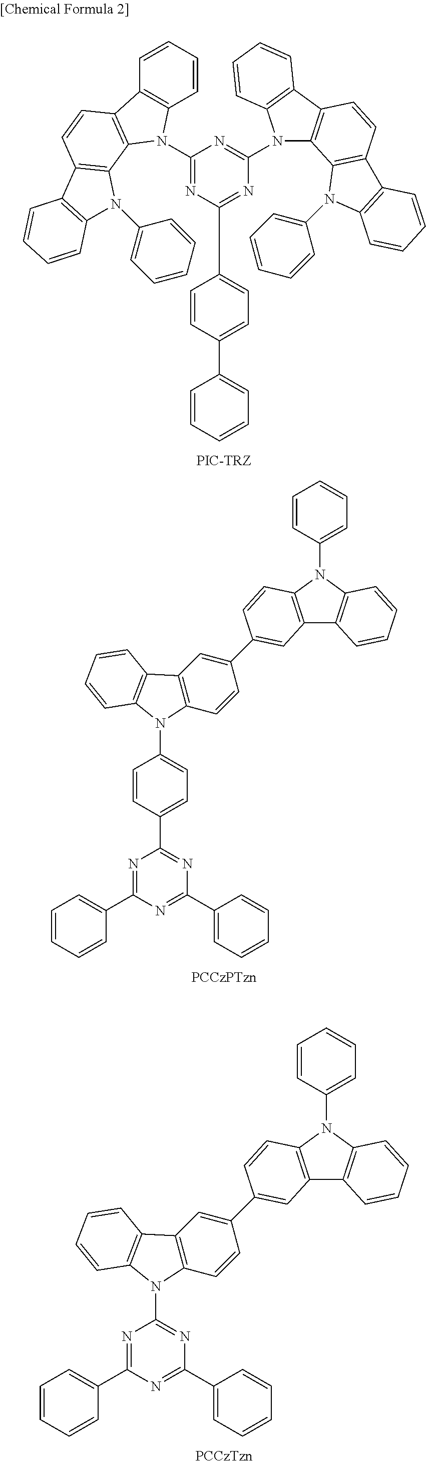 [SMILES: c1ccc(-c2ccc(Cc3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

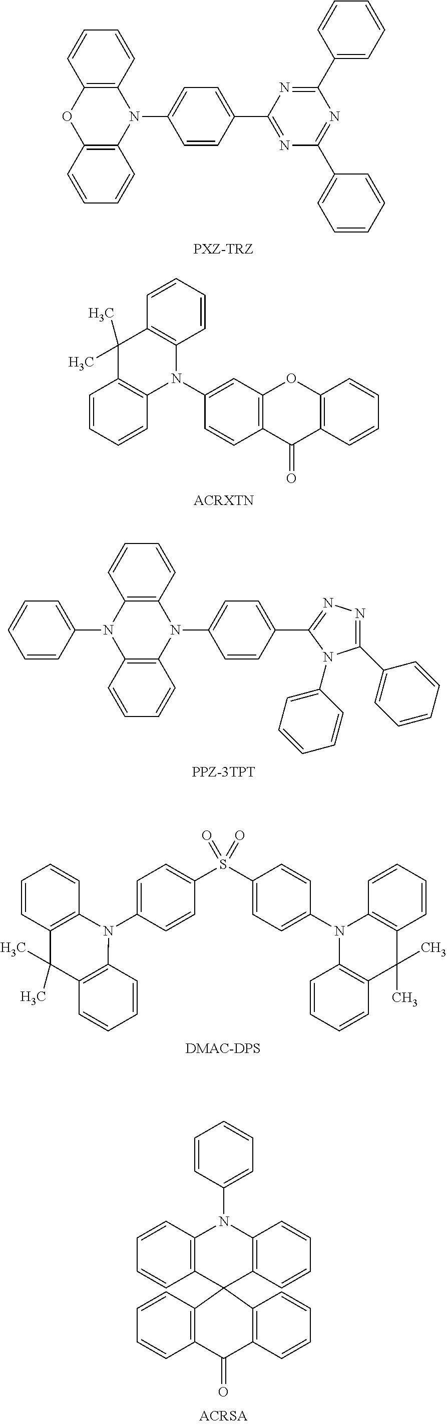 [SMILES: c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, it is possible to upconvert triplet excitation energy into singlet excitation energy (reverse intersystem crossing) using a small amount of thermal energy and efficiently generate a singlet excited state. In addition, the triplet excitation energy can be converted into luminescence.

An exciplex whose excited state is formed of two kinds of substances has an extremely small difference between the S₁ level and the T₁ level and has a function of a TADF material capable of converting triplet excitation energy into singlet excitation energy.

A phosphorescent spectrum observed at low temperature (e.g., 77 K to 10 K) may be used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than the S₁ level of the TADF material. In addition, the T₁ level of the host material is preferably higher than the T₁ level of the TADF material.

As the host material of the light-emitting layer, a material having an electron-transport property and/or a material having a hole-transport property as described in Embodiment 1 can be used. Besides, the above-described TADF material and the like that satisfy the conditions described in Embodiment 1 can be used. In addition, any of a variety of carrier-transport materials can also be used as long as the materials satisfy the conditions described in Embodiment 1.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than the S₁ level of the fluorescent substance in order that high emission efficiency can be achieved. Furthermore, the T₁ level of the TADF material is preferably higher than the S₁ level of the fluorescent substance. Thus, the T₁ level of the TADF material is preferably higher than the T₁ level of the fluorescent substance.

It is also preferable to use a TADF material that emits light whose wavelength overlaps with the wavelength of a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier-transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that emits light with a wavelength overlapping with the wavelength of a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable to form an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

The electron-transport layer 114 is a layer containing a substance having an electron-transport property. The organic compound having an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property. An organic compound having a π-electron deficient heteroaromatic ring skeleton is preferably used. The organic compound having a π-electron deficient heteroaromatic ring skeleton is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton. Among the above materials, the organic compound including a heteroaromatic ring having a diazine skeleton (such as a pyrimidine skeleton, a pyrazine skeleton, or a pyridazine skeleton), the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor property and reliability.

Examples of such organic compounds include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound including a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[(3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound including a heteroaromatic ring having a triazine skeleton, such as 2-[(biphenyl)-4-yl]-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-[8-(1,1′:4′,1″-terphenyl)-4-yl-1-dibenzofuranyl]-1,3,5-triazine (abbreviation: mBP-TPDBfTzn). Among these examples, it is preferable to use an organic compound that does not include a fused aromatic ring composed only of six-membered rings; or an organic compound that does not have a structure in which two or more adjacent six-membered aromatic hydrocarbon rings are fused, a structure in which two or more adjacent six-membered heteroaromatic rings are fused, or a structure in which one or more six-membered aromatic hydrocarbon rings and one or more six-membered heteroaromatic rings that are adjacent to each other are fused.

Among the above materials, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. The organic compound including a heteroaromatic ring having a diazine (pyrimidine or pyrazine) skeleton and the organic compound including a heteroaromatic ring having a triazine skeleton are particularly preferable because these organic compounds have a high electron-transport property to contribute to a reduction in driving voltage. In particular, organic compounds having a phenanthroline skeleton, such as mTpPPhen, PnNPhen, and mPPhen2P, are preferable, and an organic compound having a phenanthroline dimeric structure, such as mPPhen2P, is further preferable because of its excellent stability.

Note that the electron-transport layer 114 may have a stacked-layer structure. A layer that is included in the stacked-layer structure of the electron-transport layer 114 and that is in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than a material contained in the light-emitting layer 113 by greater than or equal to 0.5 eV.

As an electron-injection layer 115, a layer that contains a compound or a complex of an alkali metal or an alkaline earth metal such as lithium fluoride, 8-hydroxyquinolinato-lithium (abbreviation: Liq), or a mixed material of lithium fluoride and ytterbium; a mixture of any of these; 1,1′-pyridine-2,6-diyl-bis(1,3,4,6,7,8-hexahydro-2H-pyrimido[1,2-a]pyrimidine) (abbreviation: hpp2Py); or the like may be provided. The electron-injection layer 115 may be a layer that is formed using a substance with an electron-transport property and contains any of the above substances.

Instead of the electron-injection layer 115, a charge-generation layer 116 may be provided (FIG. 1). The charge-generation layer 116 refers to a layer capable of injecting holes into a layer in contact with the cathode side of the charge-generation layer and electrons into a layer in contact with the anode side thereof when a potential is applied. The charge-generation layer 116 includes at least a P-type layer 117. The P-type layer 117 is preferably formed using any of the composite materials given above as the material that can be used for the hole-injection layer 111. The P-type layer 117 may be formed by stacking a film containing the above-described acceptor material as a material included in the composite material and a film containing a hole-transport material. When a potential is applied to the P-type layer 117, electrons are injected into the electron-transport layer 114 and holes are injected into the cathode; thus, the organic EL element operates. Since the organic compound of one embodiment of the present invention has a low refractive index, the use of the organic compound for the P-type layer 117 enables the organic EL element to have high external quantum efficiency.

Note that the charge-generation layer 116 preferably includes one or both of an electron-relay layer 118 and an electron-injection buffer layer 119 in addition to the P-type layer 117.

The electron-relay layer 118 at least contains a substance having an electron-transport property and has a function of preventing an interaction between the electron-injection buffer layer 119 and the P-type layer 117 and smoothly transferring electrons. The LUMO level of the substance having an electron-transport property contained in the electron-relay layer 118 is preferably between the LUMO level of the acceptor substance in the P-type layer 117 and the LUMO level of a substance contained in a layer of the electron-transport layer 114 that is in contact with the charge-generation layer 116. As a specific value of the energy level, the LUMO level of the substance having an electron-transport property used in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material such as phthalocyanine (abbreviation: H₂Pc), copper phthalocyanine (abbreviation: CuPc), or zinc phthalocyanine (abbreviation: ZnPc) or a metal complex having a metal-oxygen bond and an aromatic ligand is preferably used.

The electron-injection buffer layer 119 can be formed using a substance with a high electron-injection property, e.g., an alkali metal, an alkaline earth metal, a rare earth metal, or a compound thereof (an alkali metal compound (including an oxide such as lithium oxide, a halide such as lithium fluoride, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide such as lithium fluoride, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material forming the electron-transport layer 114 can be used.

The second electrode 102 is an electrode including a cathode. The second electrode 102 may have a stacked-layer structure where the layer in contact with the organic compound layer 103 functions as the cathode. As a substance of the cathode, any of a metal, an alloy, and an electrically conductive compound with a low work function (specifically, lower than or equal to 3.8 eV), a mixture thereof, or the like can be used. Specific examples of such a cathode material include elements belonging to Group 1 or Group 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film containing any of the above materials with a low work function is provided between the second electrode 102 and the electron-transport layer, a variety of conductive materials such as Al, Ag, ITO, and indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

Any of a variety of methods can be used for forming the organic compound layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure where a plurality of light-emitting units are stacked (also referred to as a stacked element or a tandem element) will be described with reference to FIG. 1C. This organic EL element is an organic EL element that includes a plurality of light-emitting units between an anode and a cathode. One light-emitting unit has substantially the same structure as the organic compound layer 103 illustrated in FIG. 1A. In other words, the organic EL element illustrated in FIG. 1C includes a plurality of light-emitting units, and the organic EL elements illustrated in FIG. 1A or FIG. 1B each include a single light-emitting unit.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other light-emitting unit when a voltage is applied to the first electrode 501 and the second electrode 502. That is, in FIG. 1C, any layer can be used as the charge-generation layer 513 as long as the layer injects electrons into the first light-emitting unit 511 and injects holes into the second light-emitting unit 512 in the case where a voltage is applied such that the potential of the anode is higher than the potential of the cathode.

The charge-generation layer 513 is preferably formed with a structure similar to that of the charge-generation layer 116 described with reference to FIG. 1B. A composite material of an organic compound and a metal oxide has an excellent carrier-injection property and an excellent carrier-transport property; thus, low-voltage driving and low-current driving can be achieved. Note that in the case where the anode-side surface of a light-emitting unit is in contact with the charge-generation layer 513, the charge-generation layer 513 can also serve as a hole-injection layer of the light-emitting unit; thus, a hole-injection layer is not necessarily provided in the light-emitting unit.

In the case where the electron-injection buffer layer 119 is provided in the charge-generation layer 513, the electron-injection buffer layer 119 serves as an electron-injection layer in the light-emitting unit on the anode side; thus, an electron-injection layer is not necessarily formed in the light-emitting unit on the anode side.

The organic EL element having two light-emitting units is described with reference to FIG. 1C; however, the same can also be applied to an organic EL element in which three or more light-emitting units are stacked. With a plurality of light-emitting units partitioned by the charge-generation layer 513 between a pair of electrodes as in the organic EL element of this embodiment, it is possible to provide a long-life element that can emit light with high luminance at a low current density. A light-emitting apparatus that can be driven at a low voltage and has low power consumption can be achieved.

When the emission colors of the light-emitting units are different, light emission of a desired color can be obtained from the organic EL element as a whole. For example, in an organic EL element having two light-emitting units, the emission colors of the first light-emitting unit may be red and green and the emission color of the second light-emitting unit may be blue, so that the organic EL element can emit white light as a whole.

The organic compound layer 103, the first light-emitting unit 511, the second light-emitting unit 512, and the layers such as the charge-generation layer, and the electrodes that are described above can be formed by a method such as an evaporation method (including a vacuum evaporation method), a droplet discharge method (also referred to as an ink-jet method), a coating method, or a gravure printing method, for example. A low molecular material, a middle molecular material (including an oligomer and a dendrimer), or a high molecular material may be contained in the layers or electrodes.

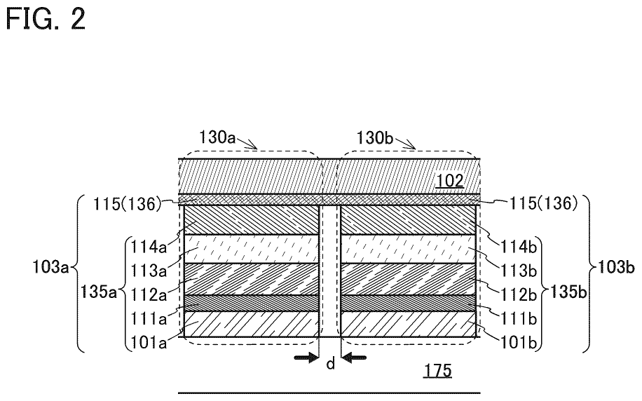

FIG. 2 illustrates two adjacent light-emitting devices (a light-emitting device 130a and a light-emitting device 130b) in a light-emitting device group 130A including a plurality of light-emitting devices 130 in the display apparatus of one embodiment of the present invention. Note that the display apparatus includes a first electrode group 101A including a plurality of first electrodes 101 formed over the insulating layer 175, the second electrode 102, and a first layer group 135A including a plurality of first layers 135, and at least the first electrode 101, the first layer 135, and the second electrode 102 overlap with each other in the light-emitting device.

The light-emitting device 130a includes an organic compound layer 103a between a first electrode 101a and the facing second electrode 102, over an insulating layer 175. The illustrated organic compound layer 103a includes a hole-injection layer 111a, a hole-transport layer 112a, a light-emitting layer 113a, an electron-transport layer 114a, and an electron-injection layer 115, but may have a different stacked-layer structure. The organic compound layer 103a includes a first layer 135a that is independently provided for each light-emitting device, and may further include a common layer 136 shared by the plurality of light-emitting devices. In FIG. 2, the hole-injection layer 111a, the hole-transport layer 112a, the light-emitting layer 113a, and the electron-transport layer 114a correspond to the first layer, and the electron-injection layer 115 corresponds to the common layer. Note that the electron-injection layer 115 may be independently provided for each light-emitting device and the whole organic compound layer 103a may be the first layer 135a.

The light-emitting device 130b includes an organic compound layer 103b between a first electrode 101b and the facing second electrode 102, over the insulating layer 175. The illustrated organic compound layer 103b includes a hole-injection layer 111b, a hole-transport layer 112b, a light-emitting layer 113b, an electron-transport layer 114b, and the electron-injection layer 115, but may have a different stacked-layer structure. In FIG. 2, the hole-injection layer 111b, the hole-transport layer 112b, the light-emitting layer 113b, and the electron-transport layer 114b correspond to a first layer 135b, and the electron-injection layer 115 corresponds to the common layer 136. Note that the electron-injection layer 115 may be independently provided for each light-emitting device and the whole organic compound layer 103b may be the first layer 135b.

The electron-injection layer 115 and the second electrode 102 are each preferably one continuous layer (common layer) shared by the light-emitting device 130a and the light-emitting device 130b. The organic compound layer 103a and the organic compound layer 103b except for the electron-injection layer 115, i.e., the first layer is processed by a photolithography method after the formation of the electron-transport layer 114a and after the formation of the electron-transport layer 114b; thus, the organic compound layer 103a and the organic compound layer 103b are independent of each other. Furthermore, since end portions (outlines) of the organic compound layer 103a except for the electron-injection layer 115 are processed by a photolithography method, the end portions are substantially aligned in the direction perpendicular to the substrate surface. Since end portions (outlines) of the organic compound layer 103b except for the electron-injection layer 115 are processed by a photolithography method, the end portions are substantially aligned in the direction perpendicular to the substrate surface. At this time, the heating step in the photolithography process is performed after the formation of the electron-transport layer 114a and the electron-transport layer 114b.

Since the organic compound layers are processed by a photolithography method, a distance d between the first electrode 101a and the first electrode 101b can be smaller than that of the case where the light-emitting devices are formed through mask vapor deposition. The distance d can be more than or equal to 2 μm and less than or equal to 5 μm.

### Embodiment 3

In this embodiment, a mode of a light-emitting device capable of using the organic semiconductor device of one embodiment of the present invention as a display element of a display apparatus will be described.

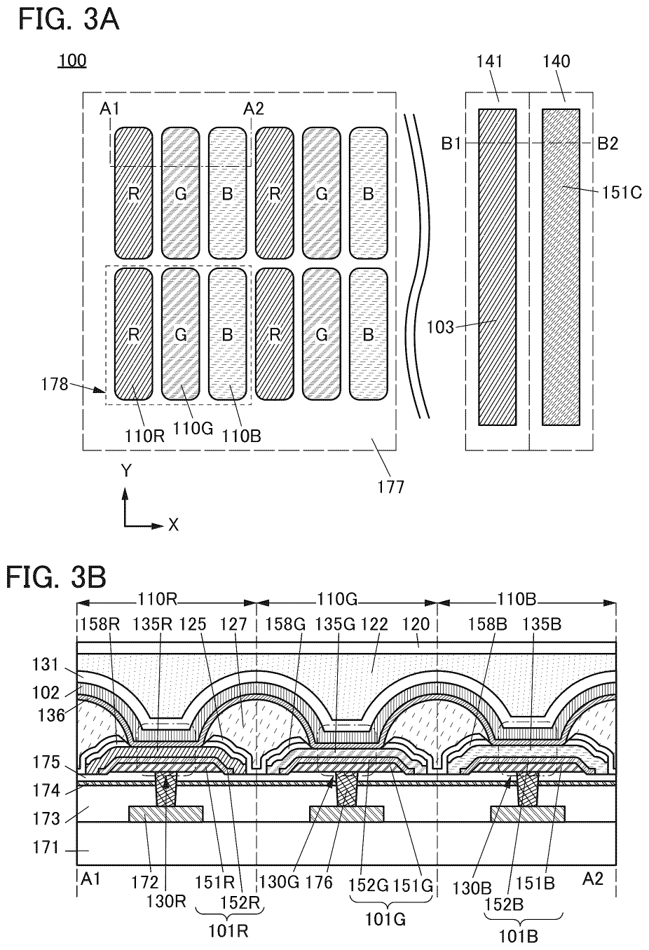

As illustrated in FIG. 3A and FIG. 3B, a plurality of the light-emitting devices 130 are formed over the insulating layer 175 to constitute a display apparatus.

The display apparatus includes a pixel portion 177 in which a plurality of pixels 178 are arranged in a matrix. The pixels 178 each include a subpixel 110R, a subpixel 110G, and a subpixel 110B.

In this specification and the like, for example, matters common to the subpixel 110R, the subpixel 110G, and the subpixel 110B are sometimes described using the collective term “subpixel 110”. In the same manner, in the description common to other components that are distinguished by alphabets, reference numerals without alphabets are sometimes used.

The subpixel 110R emits red light, the subpixel 110G emits green light, and the subpixel 110B emits blue light. Thus, an image can be displayed on the pixel portion 177. Note that in this embodiment, subpixels of three colors of red (R), green (G), and blue (B) are given as examples; however, subpixels of a different combination of colors may be employed. The number of subpixels is not limited to three, and four or more of subpixels may be used. Examples of four subpixels include subpixels of four colors of R, G, B, and white (W), subpixels of four colors of R, G, B, and Y, and four subpixels of R, G, B, and infrared light (IR).

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 3 illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 3B is an example of a cross-sectional view taken along a dashed-dotted line A1-A2 in FIG. 3A. As illustrated in FIG. 3A, the display apparatus includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided so as to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. In a region between adjacent light-emitting device 130, an inorganic insulating layer 125 and an insulating layer 127 over the inorganic insulating layer 125 are preferably provided.

Although FIG. 3B illustrates a plurality of cross sections of the inorganic insulating layer 125 and the insulating layer 127, it is preferable that the inorganic insulating layer 125 and the insulating layer 127 be each a continuous layer when the display apparatus is seen from above. In other words, the insulating layer 127 preferably has an opening portion over a first electrode.

In FIG. 3B, a light-emitting device 130R, a light-emitting device 130G, and a light-emitting device 130B are illustrated as the light-emitting device 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light. Note that in FIG. 3B, the light-emitting device 130R and the light-emitting device 130G can be regarded as being adjacent to each other, and the light-emitting device G and the light-emitting device B can be regarded as being adjacent to each other.

The display apparatus of one embodiment of the present invention is a top-emission display apparatus where light is emitted in the direction opposite to a substrate over which the light-emitting devices are formed. Note that the display apparatus of one embodiment of the present invention may be of a bottom-emission type.

The light-emitting device 130R emits red light and preferably has a structure as described in Embodiment 1 or Embodiment 2. The light-emitting device 130R includes a first electrode (pixel electrode) including a conductive layer 151R and a conductive layer 152R, a first layer 135R over the first electrode, the common layer 136 over the first layer 135R, and the second electrode (common electrode) 102 over the common layer 136. The common layer 136 is preferably an electron-injection layer.

The light-emitting device 130G emits green light and may have a structure as described in Embodiment 1 or Embodiment 2. The light-emitting device 130G includes a first electrode (pixel electrode) including a conductive layer 151G and a conductive layer 152G, a first layer 135G over the first electrode, the common layer 136 over the first layer 135G, and the second electrode (common electrode) 102 over the common layer 136. The common layer 136 is preferably an electron-injection layer.

The light-emitting device 130B emits blue light and preferably has a structure as described in Embodiment 1 or Embodiment 2. The light-emitting device 130B includes a first electrode (pixel electrode) including a conductive layer 151B and a conductive layer 152B, a first layer 135B over the first electrode, the common layer 136 over the first layer 135B, and the second electrode (common electrode) 102 over the common layer 136. The common layer 136 is preferably an electron-injection layer.

One of the pixel electrode (first electrode) and the common electrode (second electrode) of the light-emitting device functions as an anode, and the other thereof functions as a cathode. In this embodiment, description is made on the assumption that the pixel electrode functions as the anode and the common electrode functions as the cathode unless otherwise specified.

The first layer 135R, the first layer 135G, and the first layer 135B are island-shaped layers that are independent of each other for the respective colors. It is preferable that the first layer 135R, the first layer 135G, and the first layer 135B not overlap with each other. Note that the first layers included in the plurality of light-emitting devices 130 formed in the light-emitting apparatus, such as the first layer 135R, the first layer 135G, and the first layer 135B, are collectively referred to as a first layer group 135A in some cases. Providing the island-shaped first layer group 135A in each of the light-emitting devices 130 can inhibit a leakage current between the adjacent light-emitting devices 130 even in a high-resolution display apparatus. This can prevent crosstalk, so that the display apparatus can achieve extremely high contrast. Specifically, a display apparatus having high current efficiency at low luminance can be obtained.

The island-shaped first layer group 135A is formed by forming an EL film for each emission color and processing the EL film by a photolithography method.

The first layer 135 is preferably provided to cover the top surface and the side surface of the first electrode (pixel electrode) 101 of the light-emitting device 130. Such a structure can easily increase the aperture ratio of the display apparatus as compared with the structure in which the end portion of the first layer 135 is positioned on the inner side of the end portion of the pixel electrode. Covering the side surface of the pixel electrode of the light-emitting device 130 with the first layer 135 inhibits contact between the first electrode 101 and the second electrode 102, thereby inhibiting a short circuit in the light-emitting device 130.

In the display apparatus of one embodiment of the present invention, the first electrode (pixel electrode) 101 of the light-emitting device preferably has a stacked-layer structure. For example, in the example illustrated in FIG. 3B, the first electrode 101 of the light-emitting device 130 has a stacked-layer structure of the conductive layer 151 provided on the substrate 171 side and the conductive layer 152 provided on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 may have a stacked-layer structure of a plurality of layers containing different materials and the conductive layer 152 may have a stacked-layer structure of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

The conductive layer 151 preferably has the end portion with a tapered shape. Specifically, the end portion of the conductive layer 151 preferably has a tapered shape with a taper angle of less than 90°. In that case, the conductive layer 152 provided along the side surface of the conductive layer 151 also has an end portion with a tapered shape. When the side surface of the conductive layer 152 has a tapered shape, coverage with the first layer 135 provided along the side surface of the conductive layer 152 can be improved.

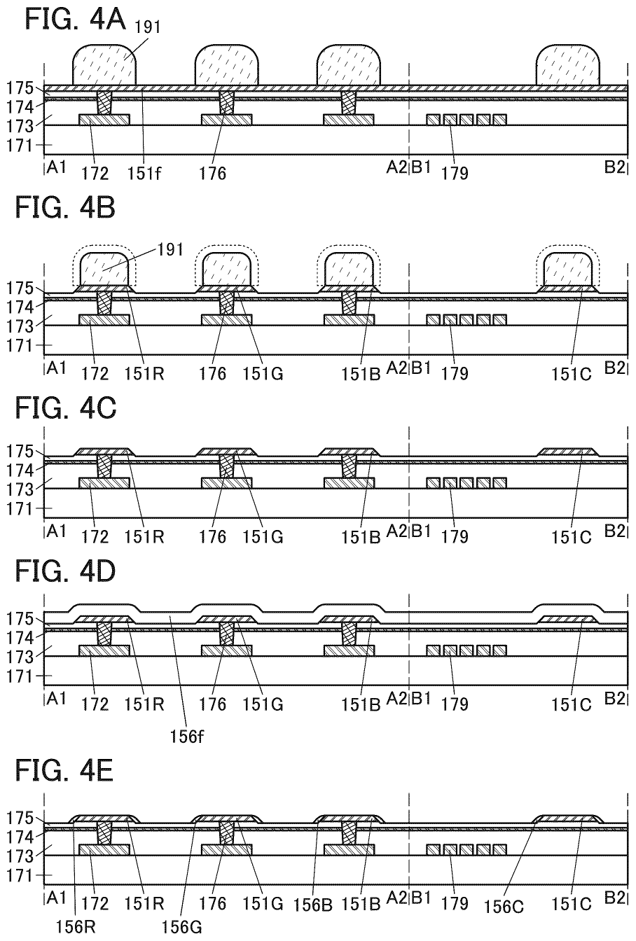

Next, a method for manufacturing the display apparatus having the structure illustrated in FIG. 3A is described with reference to FIG. 4 to FIG. 9.

### Manufacturing Method Example 1

Thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an ALD method, or the like.

The thin films included in the display apparatus (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, or knife coating.

Thin films included in the display apparatus can be processed by, for example, a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. The light exposure may be performed by liquid immersion exposure technique. As the light used for light exposure, extreme ultraviolet (EUV) light or X-rays may be used. Instead of the light used for the light exposure, an electron beam can be used.

For etching of thin films, a dry etching method, a wet etching method, a sandblast method, or the like can be used.

First, the insulating layer 171 is formed over a substrate (not illustrated), as illustrated in FIG. 4A. Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, a glass substrate, a quartz substrate, a sapphire substrate, or a ceramic substrate; a single crystal semiconductor substrate or a polycrystalline semiconductor substrate including silicon, silicon carbide, or the like as a material; a compound semiconductor substrate of silicon germanium or the like; or a semiconductor substrate such as an SOI substrate can be used.

Next, openings reaching the conductive layer 172 are formed in the insulating layer 175, the insulating layer 174, and the insulating layer 173, as illustrated in FIG. 4A. Then, the plugs 176 are formed to fill the openings.

Next, a conductive film 151f to be the conductive layer 151R, the conductive layer 151G, the conductive layer 151B, and the conductive layer 151C later is formed over the plugs 176 and the insulating layer 175, as illustrated in FIG. 4A. A metal material can be used for the conductive film 151f, for example.

Next, as illustrated in FIG. 4A, a resist mask 191 is formed over the conductive film 151cf. The resist mask 191 can be formed by application of a photosensitive material (photoresist), light exposure, and development.

Subsequently, as illustrated in FIG. 4B, the conductive film 151f in a region not overlapping with the resist mask 191 is removed, for example. Thus, the conductive layer 151 is formed.

Next, as illustrated in FIG. 4C, the resist mask 191 is removed. The resist mask 191 can be removed by ashing using oxygen plasma, for example.

Next, as illustrated in FIG. 4D, an insulating film 156f to be an insulating layer 156R, an insulating layer 156G, an insulating layer 156B, and an insulating layer 156C later is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., a silicon oxynitride film, can be used, for example.

Subsequently, as illustrated in FIG. 4E, the insulating film 156f is processed to form the insulating layer 156R, the insulating layer 156G, the insulating layer 156B, and the insulating layer 156C.

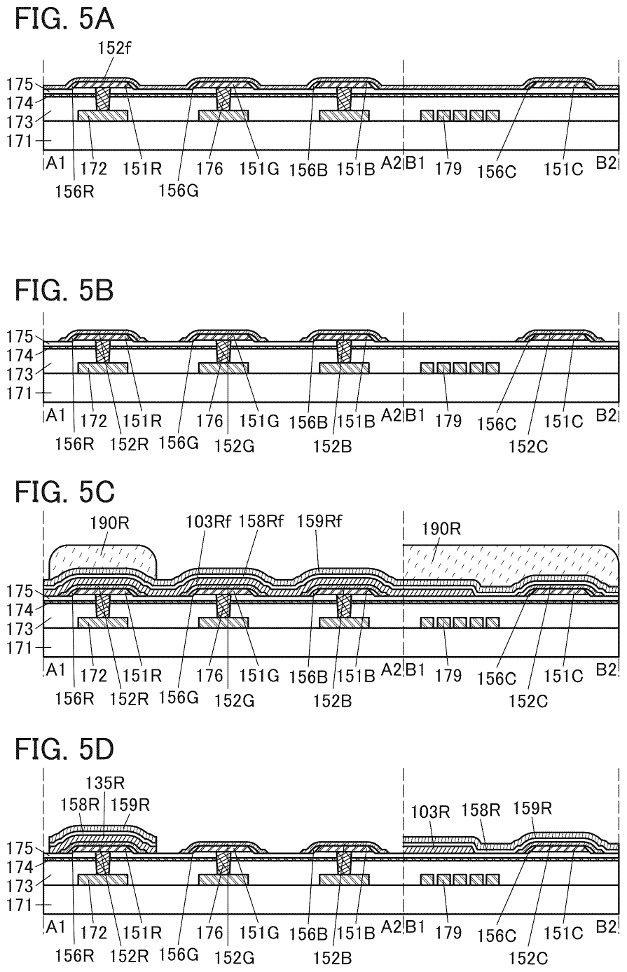

Then, as illustrated in FIG. 5A, a conductive film 152f is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175.

A conductive oxide can be used for the conductive film 152f, for example. The conductive film 152f may have a stacked-layer structure.

Then, as illustrated in FIG. 5B, the conductive film 152f is processed, so that the conductive layer 152R, the conductive layer 152G, the conductive layer 152B, and the conductive layer 152C are formed.

Next, as illustrated in FIG. 5C, an organic compound film 103Rf is formed over the conductive layer 152R, the conductive layer 152G, the conductive layer 152B, and the insulating layer 175. Note that as illustrated in FIG. 5C, the organic compound film 103Rf is not formed over the conductive layer 152C.

Then, as illustrated in FIG. 5C, a sacrificial film 158Rf and a mask film 159Rf are formed.

The sacrificial film 158Rf provided over the organic compound film 103Rf can reduce damage to the organic compound film 103Rf in the manufacturing process of the display apparatus, increasing the reliability of the light-emitting device.

As the sacrificial film 158Rf, a film that is highly resistant to the processing conditions for the organic compound film 103Rf, specifically, a film having high etching selectivity with the organic compound film 103Rf is used. As the mask film 159Rf, a film having high etching selectivity with the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. Since the light-emitting device of one embodiment of the present invention includes the first compound, a display apparatus with favorable display quality can be provided even after a heating step at a higher temperature is performed.

As the sacrificial film 158Rf and the mask film 159Rf, it is preferable to use a film that can be removed by a wet etching method or a dry etching method.

Note that the sacrificial film 158Rf, which is formed over and in contact with the organic compound film 103Rf, is preferably formed by a formation method that causes less damage to the organic compound film 103Rf than a formation method for the mask film 159Rf. For example, the sacrificial film 158Rf is preferably formed by an atomic layer deposition (ALD) method or a vapor deposition method rather than a sputtering method.

As the sacrificial film 158Rf and the mask film 159Rf, it is possible to use one or more of a metal film, an alloy film, a metal oxide film, a semiconductor film, an organic insulating film, and an inorganic insulating film, for example.

For the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the sacrificial film 158Rf and the mask film 159Rf is preferable, in which case the organic compound film 103Rf can be inhibited from being irradiated with ultraviolet rays in exposure for patterning and deteriorating.

For each of the sacrificial film 158Rf and the mask film 159Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

Note that an element M(Mis one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium as the described-above metal oxide.

The sacrificial film 158Rf and the mask film 159Rf are preferably formed using a semiconductor material such as silicon or germanium, for example, for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Next, as illustrated in FIG. 5C, a resist mask 190R is formed. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the manufacturing process of the display apparatus.

Subsequently, as illustrated in FIG. 5D, part of the mask film 159Rf is removed using the resist mask 190R, whereby the mask layer 159R is formed. The mask layer 159R remains over the conductive layer 152R and over the conductive layer 152C. After that, the resist mask 190R is removed. Then, part of the sacrificial film 158Rf is removed using the mask layer 159R as a mask (also referred to as a hard mask), whereby the sacrificial layer 158R is formed.

Using a wet etching method can reduce damage to the organic compound film 103Rf in processing the sacrificial film 158Rf and the mask film 159Rf, as compared to the case of using a dry etching method. In the case of using a wet etching method, it is preferable to use an alkaline aqueous solution such as a developer or a tetramethylammonium hydroxide aqueous solution (TMAH), dilute hydrofluoric acid, oxalic acid, phosphoric acid, acetic acid, nitric acid, or an acid aqueous solution such as a chemical solution including a mixed solution of any of these acids, for example.

In the case of using a dry etching method for processing the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 5D, the organic compound film 103Rf is processed to form the first layer 135R. For example, part of the organic compound film 103Rf is removed using the mask layer 159R and the sacrificial layer 158R as hard masks, so that the first layer 135R is formed.

Thus, as illustrated in FIG. 5D, a stacked-layer structure of the first layer 135R, the sacrificial layer 158R, and the mask layer 159R remains over the conductive layer 152R. The conductive layer 152G and the conductive layer 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Thus, damage to the organic compound film 103Rf can be inhibited. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas.

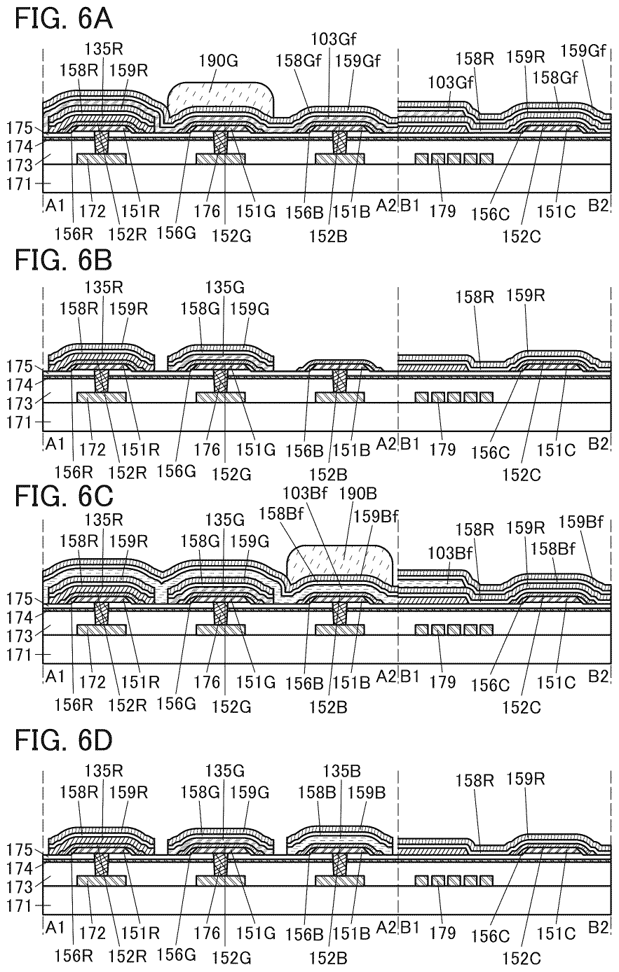

Next, as illustrated in FIG. 6A, an organic compound film 103Gf to be the first layer 135G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 6A, a sacrificial film 158Gf and a mask film 159Gf are formed in this order. After that, a resist mask 190G is formed. The materials and the formation methods of the sacrificial film 158Gf and the mask film 159Gf are similar to conditions applicable to the sacrificial film 158Rf and the mask film 159Rf. The materials and the formation method of the resist mask 190G are similar to conditions applicable to the resist mask 190R.

The resist mask 190G is provided at a position overlapping the conductive layer 152G.

Subsequently, as illustrated in FIG. 6B, part of the mask film 159Gf is removed using the resist mask 190G, whereby the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the organic compound film 103Gf is processed to form the first layer 135G.

Subsequently, an organic compound film 103Bf is formed as illustrated in FIG. 6C.

The organic compound film 103Bf can be formed by a method similar to that for forming the organic compound film 103Rf. The organic compound film 103Bf can have a structure similar to that of the organic compound film 103Rf.

Next, a sacrificial film 158Bf and a mask film 159Bf are formed in this order as illustrated in FIG. 6C. After that, a resist mask 190B is formed. The materials and the formation methods of the sacrificial film 158Bf and the mask film 159Bf are similar to conditions applicable to the sacrificial film 158Rf and the mask film 159Rf. The materials and the formation method of the resist mask 190B are similar to conditions applicable to the resist mask 190R.

The resist mask 190B is provided at a position overlapping the conductive layer 152B.

Subsequently, as illustrated in FIG. 6D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the organic compound film 103Bf is processed to form the first layer 135B. For example, part of the organic compound film 103Bf is removed using the mask layer 159B and the sacrificial layer 158B as hard masks, so that the first layer 135B is formed.

Thus, as illustrated in FIG. 6D, the stacked-layer structure of the first layer 135B, the sacrificial layer 158B, and the mask layer 159B remains over the conductive layer 152B. The mask layer 159R and the mask layer 159G are exposed.

Note that the side surfaces of the first layer 135R, the first layer 135G, and the first layer 135B are preferably perpendicular or substantially perpendicular to their formation surfaces. For example, the angle between the formation surfaces and these side surfaces is preferably greater than or equal to 60° and less than or equal to 90°.

The distance between two adjacent layers among the first layer 135R, the first layer 135G, and the first layer 135B, which are formed by a photolithography method as described above, can be shortened to less than or equal to 8 μm, less than or equal to 5 μm, less than or equal to 3 μm, less than or equal to 2 μm, or less than or equal to 1 μm. Here, the distance can be specified, for example, by the distance between facing end portions of two adjacent layers among the first layer 135R, the first layer 135G, and the first layer 135B. The distance between the island-shaped organic compound layers is shortened in this manner, whereby a display apparatus with high resolution and a high aperture ratio can be provided. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

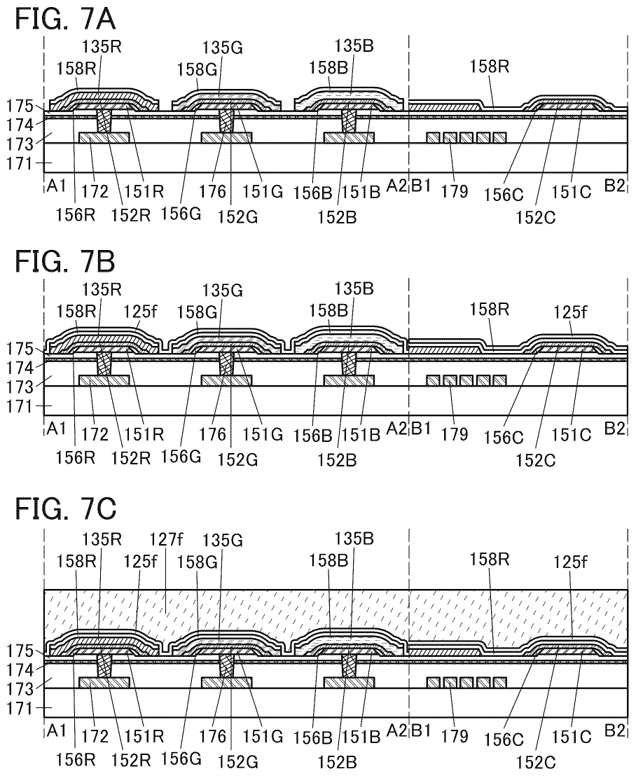

Next, the mask layer 159R, the mask layer 159G, and the mask layer 159B are preferably removed as illustrated in FIG. 7A.

The step of removing the mask layers can be performed by a method similar to that for the step of processing the mask layers. In particular, using a wet etching method can reduce damage to the first layers 135 in removal of the mask layers, as compared to the case of using a dry etching method.

The mask layers may be removed by being dissolved in a polar solvent such as water or alcohol. Examples of an alcohol include ethyl alcohol, methyl alcohol, isopropyl alcohol (IPA), and glycerin.

After the mask layers are removed, drying treatment may be performed to remove water adsorbed onto the surface. For example, heat treatment in an inert gas atmosphere or a reduced-pressure atmosphere can be performed. The heat treatment can be performed at a substrate temperature of higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 7B.

Then, as illustrated in FIG. 7C, an insulating film 127f to be the insulating layer 127 later is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case deposition damage is reduced and a film with good coverage can be deposited. As the inorganic insulating film 125f, an aluminum oxide film is preferably formed by an ALD method, for example.

The insulating film 127f is preferably formed by the above-described wet process. The insulating film 127f is preferably formed by spin coating using a photosensitive material, for example, and specifically preferably formed using a photosensitive resin composition containing an acrylic resin.

Then, part of the insulating film 127f is exposed to visible light or ultraviolet rays. The insulating layer 127 is formed in regions that are sandwiched between any two of the conductive layer 152R, the conductive layer 152G, and the conductive layer 152B and around the conductive layer 152C.

The width of the insulating layer 127 formed later can be controlled in accordance with the light-exposure region of the insulating film 127f. In this embodiment, processing is performed such that the insulating layer 127 includes a portion overlapping the top surface of the conductive layer 151.

Light used for the light exposure preferably includes the i-line (wavelength: 365 nm). The light used for light exposure may include at least one of the g-line (wavelength: 436 nm) and the h-line (wavelength: 405 nm).

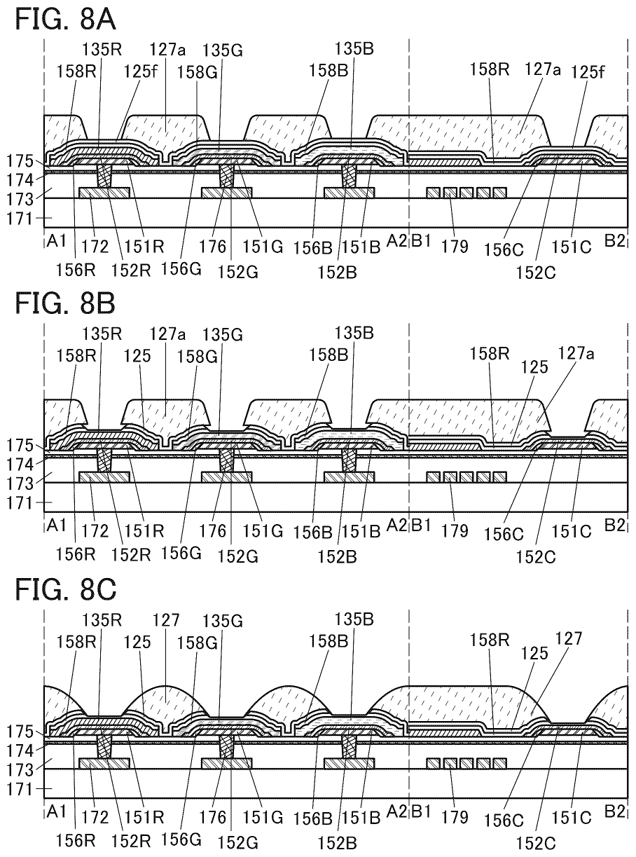

Next, as illustrated in FIG. 8A, development is performed to remove the light-exposure region of the insulating film 127f, so that an insulating layer 127a is formed.

Next, as illustrated in FIG. 8B, etching treatment is performed with the insulating layer 127a as a mask to remove part of the inorganic insulating film 125f and reduce the thickness of part of the sacrificial layer 158R, the sacrificial layer 158G, and the sacrificial layer 158B. Thus, the inorganic insulating layer 125 is formed under the insulating layer 127a. Moreover, the surfaces of the thin portions in the sacrificial layer 158R, the sacrificial layer 158G, and the sacrificial layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layer 158R, the sacrificial layer 158G, and the sacrificial layer 158B, in which case the first etching treatment can be performed collectively.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layer 158R, the sacrificial layer 158G, and the sacrificial layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. Employing a wet etching method can reduce damage to the first layer 135R, the first layer 135G, and the first layer 135B as compared with the case of employing a dry etching method. Wet etching can be performed using an alkaline solution, for example. For instance, TMAH, which is an alkaline solution, can be used for wet etching of an aluminum oxide film. Alternatively, an acid solution including fluoride can also be used. In that case, puddle wet etching can be performed. Note that the inorganic insulating film 125f is preferably formed using a material similar to that of the sacrificial layer 158R, the sacrificial layer 158G, and the sacrificial layer 158B, in which case the etching treatment can be performed collectively.

In the first etching treatment, the etching treatment is stopped when the sacrificial layer 158R, the sacrificial layer 158G, and the sacrificial layer 158B are thinned before the sacrificial layers are completely removed. The corresponding parts of the sacrificial layer 158R, the sacrificial layer 158G, and the sacrificial layer 158B remain over the first layer 135R, the first layer 135G, and the first layer 135B in this manner, whereby the first layer 135R, the first layer 135G, and the first layer 135B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (such as an aluminum oxide film) is provided as each of the sacrificial layer 158R, the sacrificial layer 158G, and the sacrificial layer 158B, diffusion of oxygen into the first layer 135R, the first layer 135G, and the first layer 135B can be inhibited.

Then, heat treatment (also referred to as post-baking) is performed. The heat treatment can change the insulating layer 127a into the insulating layer 127 with a tapered side surface (FIG. 8C). The heat treatment is performed at a temperature lower than the upper temperature limit of the organic compound layer. The heat treatment can be performed at a substrate temperature of higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layer 158R, the sacrificial layer 158G, and the sacrificial layer 158B are not completely removed by the first etching treatment and the sacrificial layer 158R, the sacrificial layer 158G, and the sacrificial layer 158B with reduced thicknesses remain, the first layer 135R, the first layer 135G, and the first layer 135B can be prevented from being damaged and deteriorating in the heat treatment. This increases the reliability of the light-emitting device.

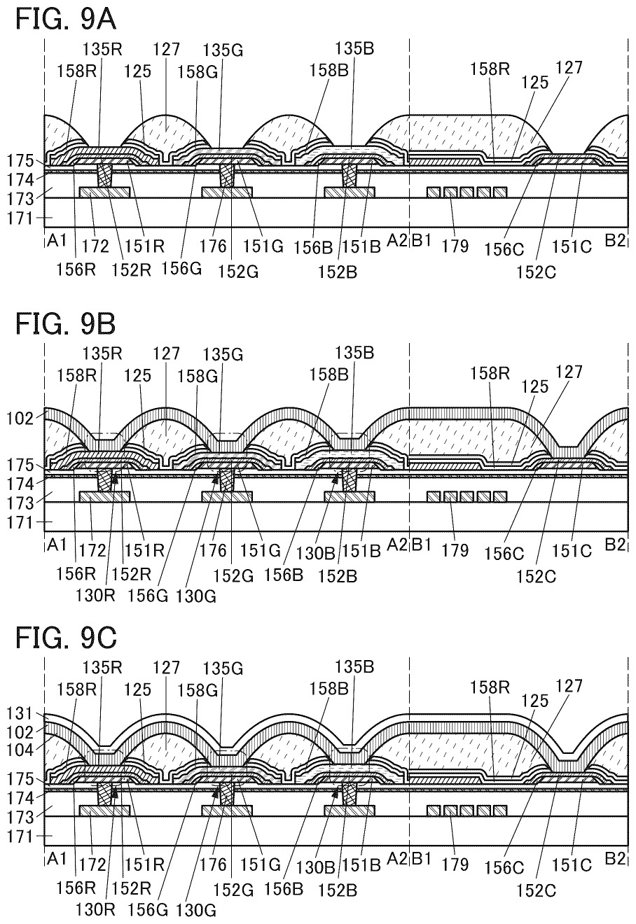

Next, as illustrated in FIG. 9A, etching treatment is performed with the insulating layer 127 as a mask to remove part of the sacrificial layer 158R, the sacrificial layer 158G, and the sacrificial layer 158B. Thus, openings are formed in the sacrificial layer 158R, the sacrificial layer 158G, and the sacrificial layer 158B, and the top surfaces of the first layer 135R, the first layer 135G, the first layer 135B, and the conductive layer 152C are exposed. Note that this etching treatment may be hereinafter referred to as second etching treatment.

The end portion of the inorganic insulating layer 125 is covered with the insulating layer 127. FIG. 9A illustrates an example where part of the end portion of the sacrificial layer 158G (specifically, a tapered portion formed by the first etching treatment) is covered with the insulating layer 127 and the tapered portion formed by the second etching treatment is exposed.

The second etching treatment is performed by wet etching. Employing a wet etching method can reduce damage to the first layer 135R, the first layer 135G, and the first layer 135B as compared with the case of employing a dry etching method. Wet etching can be performed using an alkaline solution or an acidic solution, for example. An aqueous solution is preferably used in order that the first layer 135 is not dissolved.

Next, as illustrated in FIG. 9B, the second electrode 102 is formed over the first layer 135R, the first layer 135G, the first layer 135B, the conductive layer 152C, and the insulating layer 127. The second electrode 102 can be formed by a sputtering method, a vacuum evaporation method, or the like. In that case, as illustrated in FIG. 3, the first layer 135 may have a stacked-layer structure of the first layer 135 and the common layer 136, and the second electrode 102 may be formed thereover.

Next, the protective layer 131 is formed over the second electrode 102, as illustrated in FIG. 9C. The protective layer 131 can be formed by a vacuum evaporation method, a sputtering method, a CVD method, an ALD method, or the like.

Subsequently, the substrate 120 is bonded over the protective layer 131 with the resin layer 122, whereby the display apparatus can be manufactured. In the method for manufacturing the display apparatus of one embodiment of the present invention, the insulating layer 156 is provided to include a region overlapping with the side surface of the conductive layer 151, and the conductive layer 152 is formed to cover the conductive layer 151 and the insulating layer 156 as described above. This can increase the yield of the display apparatus and inhibit generation of a defect.

As described above, in the method for manufacturing the display apparatus of one embodiment of the present invention, the island-shaped first layer 135R, the island-shaped first layer 135G, and the first layer 135B are formed not by using a fine metal mask but by processing a film formed over the entire surface; thus, the island-shaped layers can be formed to have a uniform thickness. Accordingly, a display apparatus having high resolution or a display apparatus having a high aperture ratio can be achieved. Furthermore, even when the resolution or the aperture ratio is high and the distance between subpixels is extremely short, the first layer 135R, the first layer 135G, and the first layer 135B of adjacent subpixels can be inhibited from being in contact with each other. As a result, generation of a leakage current between the subpixels can be inhibited. This can prevent crosstalk, so that the display apparatus can achieve extremely high contrast. Furthermore, even when a display apparatus includes a tandem light-emitting device formed by a photolithography method, the display apparatus can have favorable characteristics.

### Embodiment 4

In this embodiment, display apparatuses of one embodiment of the present invention will be described.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display apparatus of this embodiment can be a display apparatus having high definition or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### [Display Module]

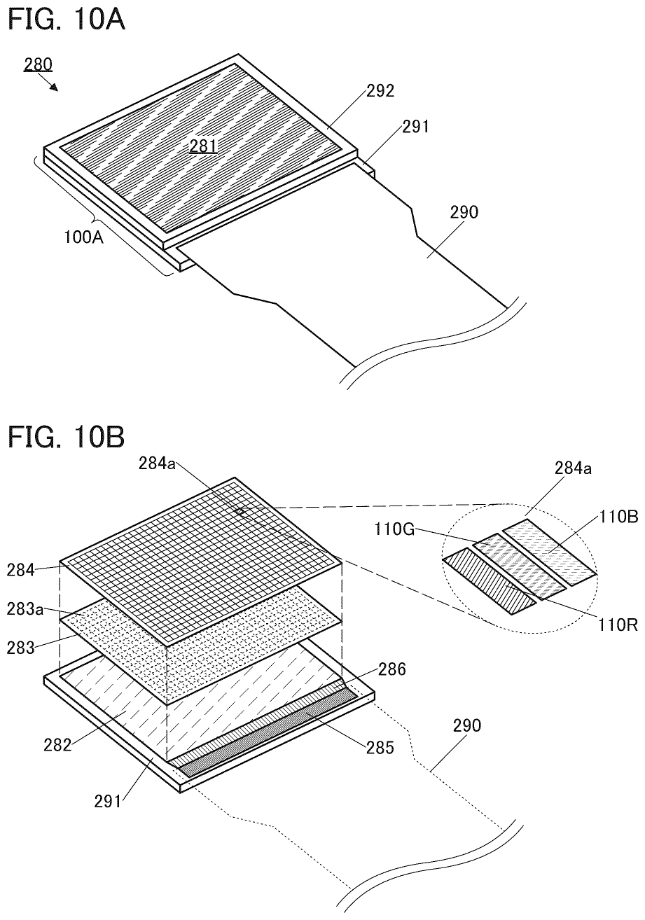

FIG. 10A is a perspective view of a display module 280. The display module 280 includes a display apparatus 100A and an FPC 290. Note that the display apparatus included in the display module 280 is not limited to the display apparatus 100A and may be any of a display apparatus 100B and a display apparatus 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 10B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapped by the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 10B. The pixels 284a can employ any of the structures described in the above embodiments. FIG. 10B illustrates an example where the pixel 284a has a structure similar to that of the pixel 178 illustrated in FIG. 3.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of agate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Apparatus 100A]

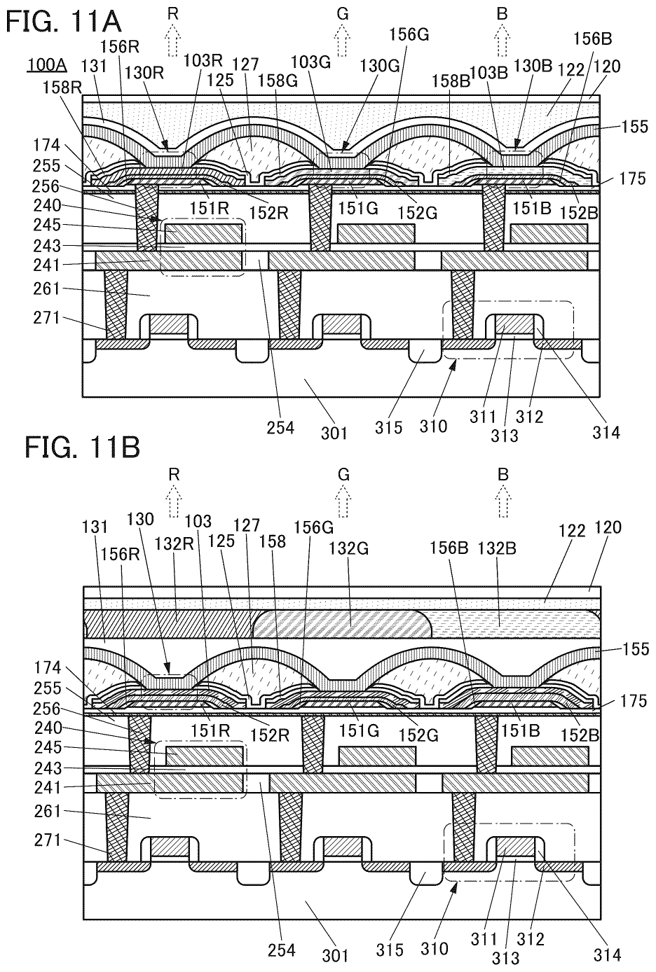

The display apparatus 100A illustrated in FIG. 11A includes a substrate 301, the light-emitting device 130R, the light-emitting device 130G, the light-emitting device 130B, a capacitor 240, and a transistor 310.

The substrate 301 corresponds to the substrate 291 in FIG. 10A and FIG. 10B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting device 130R, the light-emitting device 130G, and the light-emitting device 130B are provided over the insulating layer 175. An insulator is provided in regions between adjacent light-emitting devices.

The insulating layer 156R is provided to include a region overlapping with the side surface of the conductive layer 151R, the insulating layer 156G is provided to include a region overlapping with the side surface of the conductive layer 151G, and the insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the first layer 135R. The sacrificial layer 158G is positioned over the first layer 135G. The sacrificial layer 158B is positioned over the first layer 135B.

Each of the conductive layer 151R, the conductive layer 151G, and the conductive layer 151B is electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. Any of a variety of conductive materials can be used for the plugs.

The protective layer 131 is provided over the light-emitting device 130R, the light-emitting device 130G, and the light-emitting device 130B. The substrate 120 is bonded over the protective layer 131 with the resin layer 122. Embodiment 3 can be referred to for details of the light-emitting devices 130 and the components thereover up to the substrate 120. The substrate 120 corresponds to the substrate 292 in FIG. 10A.

FIG. 11B illustrates a modification example of the display apparatus 100A illustrated in FIG. 11A. The display apparatus illustrated in FIG. 11B includes the coloring layer 132R, the coloring layer 132G, and the coloring layer 132B, and each of the light-emitting devices 130 includes a region overlapping with one of the coloring layer 132R, the coloring layer 132G, and the coloring layer 132B. In the display apparatus illustrated in FIG. 11B, the light-emitting device 130 can emit white light, for example. For example, the coloring layer 132R, the coloring layer 132G, and the coloring layer 132B can transmit red light, green light, and blue light, respectively.

### [Display Apparatus 100B]

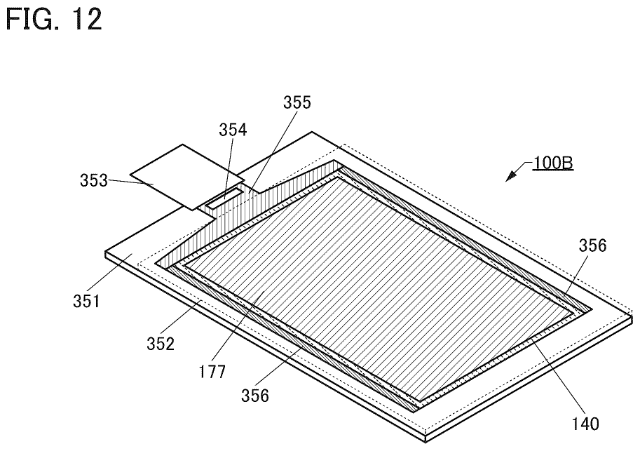

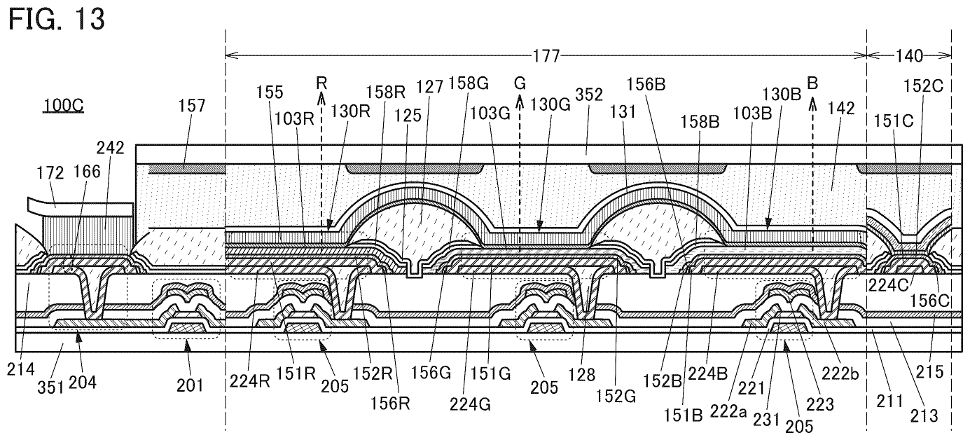

FIG. 12 is a perspective view of the display apparatus 100B, and FIG. 13 is a cross-sectional view of the display apparatus 100n.

In the display apparatus 100B, a substrate 352 and a substrate 351 are bonded to each other. In FIG. 12, the substrate 352 is denoted by a dashed line.

The display apparatus 100B includes the pixel portion 177, the connection portion 140, a circuit 356, a wiring 355, and the like. FIG. 12 illustrates an example where an IC 354 and an FPC 353 are mounted on the display apparatus 100B. Thus, the structure illustrated in FIG. 12 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 12 illustrates an example where the IC 354 is provided over the substrate 351 by a COG (Chip On Glass) method, a COF (Chip on Film) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 13 illustrates cross section examples of part of a region including the FPC 353, part of the circuit 356, part of the pixel portion 177, part of the connection portion 140, and part of a region including an end portion of the display apparatus 100B.

### [Display Apparatus 100C]

The display apparatus 100C illustrated in FIG. 13 includes a transistor 201, a transistor 205, the light-emitting device 130R emitting red light, the light-emitting device 130G emitting green light, the light-emitting device 130B emitting blue light, and the like between the substrate 351 and the substrate 352.

Embodiment 1 can be referred to for the details of the light-emitting device 130R, the light-emitting device 130G, and the light-emitting device 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. The end portion of the conductive layer 151R is positioned outward from the end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, the conductive layer 152G, and the insulating layer 156G in the light-emitting device 130G and the conductive layer 224B, the conductive layer 151B, the conductive layer 152B, and the insulating layer 156B in the light-emitting device 130B are not described in detail because they are respectively similar to the conductive layer 224R, the conductive layer 151R, and the conductive layer 152R and the insulating layer 156R in the light-emitting device 130R.

The conductive layer 224R, the conductive layer 224G, and the conductive layer 224B each have a depression portion covering an opening provided in the insulating layer 214. A layer 128 is embedded in the depression portion.

The layer 128 has a function of filling the depression portions of the conductive layer 224R, the conductive layer 224G, and the conductive layer 224B to obtain planarity. Over the conductive layer 224R, the conductive layer 224G, the conductive layer 224B, and the layer 128, the conductive layer 151R, the conductive layer 151G, and the conductive layer 151B that are respectively electrically connected to the conductive layer 224R, the conductive layer 224G, and the conductive layer 224B are provided. Thus, the regions overlapping the depression portions of the conductive layer 224R, the conductive layer 224G, and the conductive layer 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 13, a solid sealing structure is employed in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap the light-emitting device. Furthermore, the space may be filled with a resin other than the frame-like adhesive layer 142.

FIG. 13 illustrates an example in which the connection portion 140 includes a conductive layer 224C obtained by processing the same conductive film as the conductive layer 224R, the conductive layer 224G, and the conductive layer 224B, the conductive layer 151C obtained by processing the same conductive film as the conductive layer 151R, the conductive layer 151G, and the conductive layer 15113, and the conductive layer 152C obtained by processing the same conductive film as the conductive layer 152R, the conductive layer 152G, and the conductive layer 152B. FIG. 13 illustrates an example in which the insulating layer 156C is provided to include a region overlapping with the side surface of the conductive layer 151C.

The display apparatus 100B has atop-emission structure. Light from the light-emitting device is emitted toward the substrate 352. For the substrate 352, a material having a high visible-light-transmitting property is preferably used. In the case where the light-emitting element emits infrared or near-infrared light, a material with a high transmitting property with respect to infrared or near-infrared light is preferably used. The first electrode (pixel electrode) contains a material that reflects visible light, and the counter electrode (the second electrode 102) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layer 211, the insulating layer 213, and the insulating layer 215.

An organic insulating layer is suitable as the insulating layer 214 functioning as a planarization layer.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate.

A connection portion 204 is provided in a region of the substrate 351 where the substrate 352 does not overlap. In the connection portion 204, the wiring 355 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

A light-blocking layer 157 is preferably provided on the surface of the substrate 352 on the substrate 351 side. The light-blocking layer 157 can be provided between adjacent light-emitting devices, in the connection portion 140, in the circuit 356, and the like. A variety of optical members can be arranged outside the substrate 352.

A material that can be used for the substrate 120 can be used for each of the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

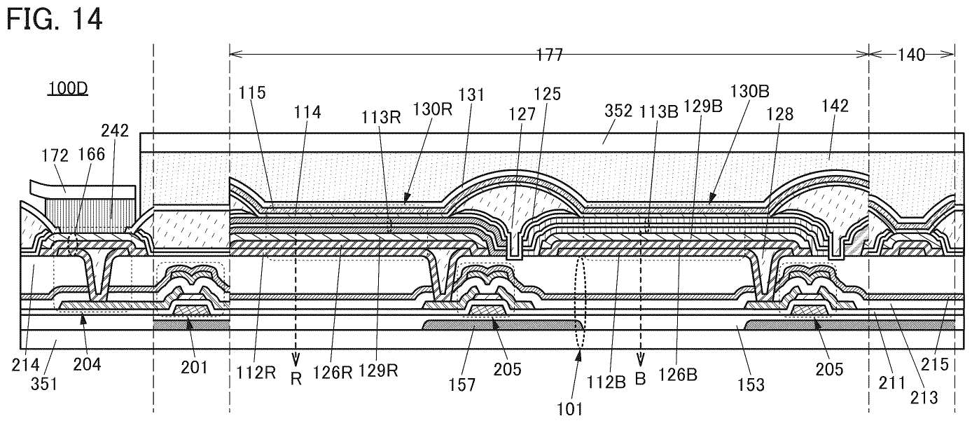

A display apparatus 100D illustrated in FIG. 14 is different from the display apparatus 100A illustrated in FIG. 13 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 1117 is preferably formed between the substrate 351 and the transistor 201 and between the substrate 351 and the transistor 205. FIG. 14 illustrates an example where the light-blocking layer 1117 is provided over the substrate 351, an insulating layer 153 is provided over the light-blocking layer 1117, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 14, the light-emitting device 130G is also provided.

Although FIG. 14 and the like illustrate an example where the top surface of the layer 128 includes a flat portion, there is no particular limitation on the shape of the layer 128.

[Display apparatus 100E]

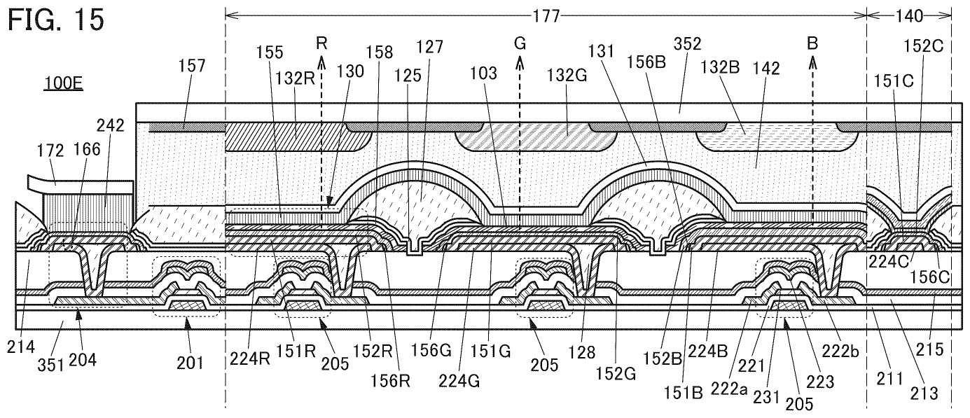

A display apparatus 100E illustrated in FIG. 15 is a modification example of the display apparatus 100B illustrated in FIG. 13 and differs from the display apparatus 100B mainly in including the coloring layer 132R, the coloring layer 132G, and the coloring layer 132B.

In the display apparatus 100E, the light-emitting device 130 includes a region overlapping with one of the coloring layer 132R, the coloring layer 132G, and the coloring layer 132B. The coloring layer 132R, the coloring layer 132G, and the coloring layer 132B can be provided on a surface of the substrate 352 on the substrate 351 side. The end portions of the coloring layer 132R, the end portions of the coloring layer 132G, and the end portions of the coloring layer 132B can overlap the light-blocking layer 157.

In the display apparatus 100E, the light-emitting device 130 can emit white light, for example. For example, the coloring layer 132R, the coloring layer 132G, and the coloring layer 132B can transmit red light, green light, and blue light, respectively. Note that in the display apparatus 100E, the coloring layer 132R, the coloring layer 132G, and the coloring layer 132B may be provided between the protective layer 131 and the adhesive layer 142.

Although FIG. 13, FIG. 15, and the like illustrate an example where the top surface of the layer 128 includes a flat portion, there is no particular limitation on the shape of the layer 128.

This embodiment can be combined as appropriate with the other embodiments or an example. In this specification, in the case where a plurality of structure examples are shown in one embodiment, the structure examples can be combined as appropriate.

### Embodiment 5

In this embodiment, electronic devices of one embodiment of the present invention will be described.

Electronic devices of this embodiment each include the display apparatus of one embodiment of the present invention in a display portion. The display apparatus of one embodiment of the present invention exhibits high display performance and can be easily increased in resolution and definition. Thus, the light-emitting apparatus of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminal devices (wearable devices) and wearable devices worn on the head, such as a VR device like a head-mounted display, a glasses-type AR device, and an MR device.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

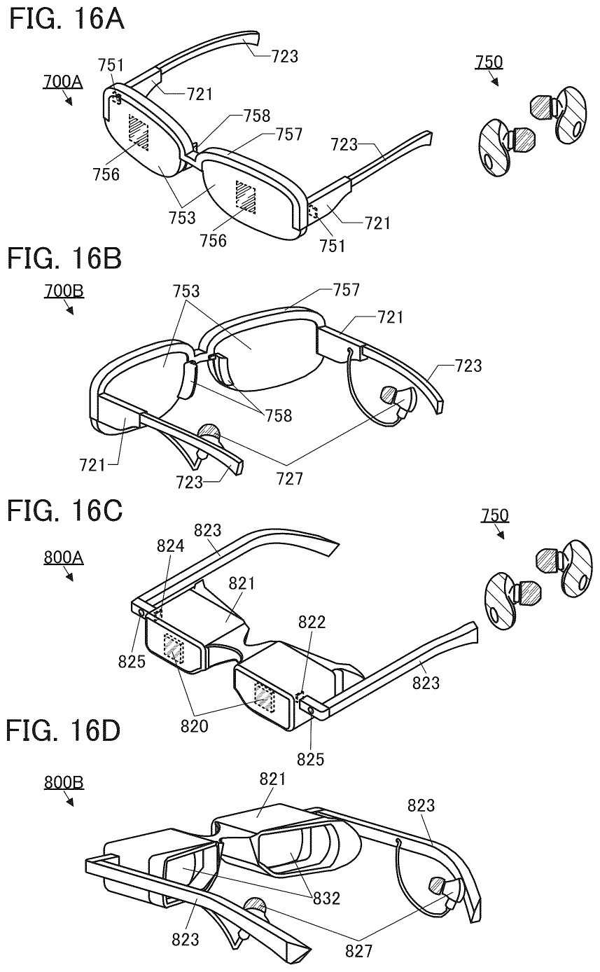

Examples of a wearable device that can be worn on a head are described with reference to FIG. 16A to FIG. 16D.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panel 751. Thus, a highly reliable electronic device is obtained.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

A display apparatus of one embodiment of the present invention can be used in the display portions 820. Thus, a highly reliable electronic device is obtained.

The display portions 820 are positioned inside the housing 821 so as to be seen through the lenses 832. When the pair of display portions 820 display different images, three-dimensional display using parallax can be performed.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes.

The electronic device 800A or the electronic device 800B can be worn on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic device 800A and the electronic device 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750.

The electronic device may include an earphone portion. The electronic device 700B in FIG. 16B includes earphone portions 727. Part of a wiring that connects the earphone portion 727 and the control portion may be positioned inside the housing 721 or the wearing portion 723.

Similarly, the electronic device 800B illustrated in FIG. 16D includes earphone portions 827. For example, the earphone portion 827 can be connected to the control portion 824 by wire.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

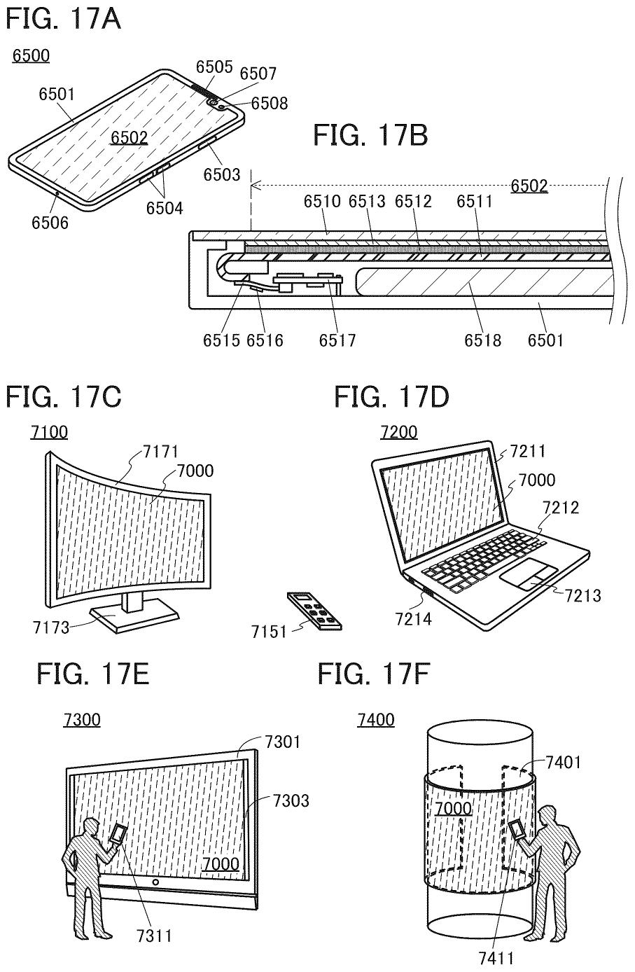

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device is obtained.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used in the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 17C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, a highly reliable electronic device is obtained.

Operation of the television device 7100 shown in FIG. 17C can be performed with an operation switch provided in the housing 7171 and a separate remote controller 7151.

FIG. 17D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic device is obtained.

FIG. 17E and FIG. 17F illustrate examples of digital signage.

Digital signage 7300 illustrated in FIG. 17E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 17F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 17E and FIG. 17F. Thus, a highly reliable electronic device is obtained.

A larger area of the display portion 7000 can increase the amount of information that can be provided at a time. The display portion 7000 having a larger area attracts more attention, so that the effectiveness of the advertisement can be increased, for example.

As illustrated in FIG. 17E and FIG. 17F, it is preferable that the digital signage 7300 or the digital signage 7400 can work with an information terminal 7311 or an information terminal 7411 such as a smartphone a user has through wireless communication.

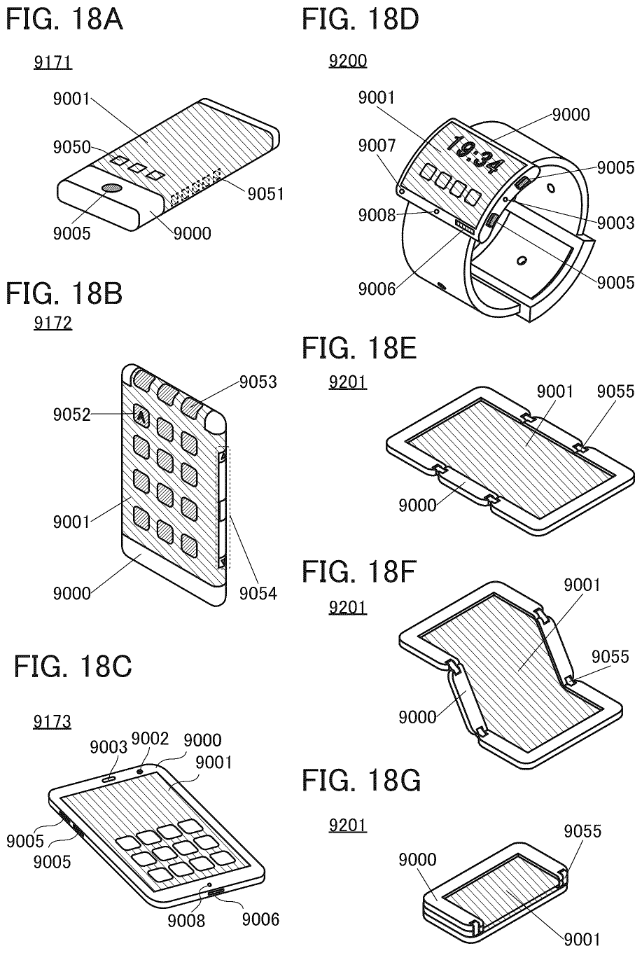

Electronic devices illustrated in FIG. 18A to FIG. 18G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 18A to FIG. 18G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The details of the electronic devices illustrated in FIG. 18A to FIG. 18G are described below.

FIG. 18A is a perspective view illustrating a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 18A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view illustrating a portable information terminal 9172. The portable information terminal 9172 has a function of displaying information on three or more surfaces of the display portion 9001. Here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 18C is a perspective view illustrating a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 18E to FIG. 18G are perspective views illustrating a foldable portable information terminal 9201. FIG. 18E is a perspective view of an opened state of the portable information terminal 9201, FIG. 18G is a perspective view of a folded state thereof, and FIG. 18F is a perspective view of a state in the middle of change from one of FIG. 18E and FIG. 18G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined as appropriate with the other embodiments or an example. In this specification, in the case where a plurality of structure examples are shown in one embodiment, the structure examples can be combined as appropriate.

### Example

In this example, a light-emitting device of one embodiment of the present invention and a comparative light-emitting device are described. Note that in this specification, light-emitting devices with different suffix numbers are sometimes referred to collectively; for example, a light-emitting device 1-1 and a light-emitting device 1-2 are collectively referred to as a light-emitting device 1.

### [Light-Emitting Device 1 to Light-Emitting Device 4]

The fabrication methods and characteristics of the light-emitting devices 1 to the light-emitting devices 4, which are light-emitting devices of one embodiment of the present invention that emit green phosphorescent light, will be described in detail below. Structural formulae of main compounds used in the light-emitting device 1 to the light-emitting device 4 are shown below.

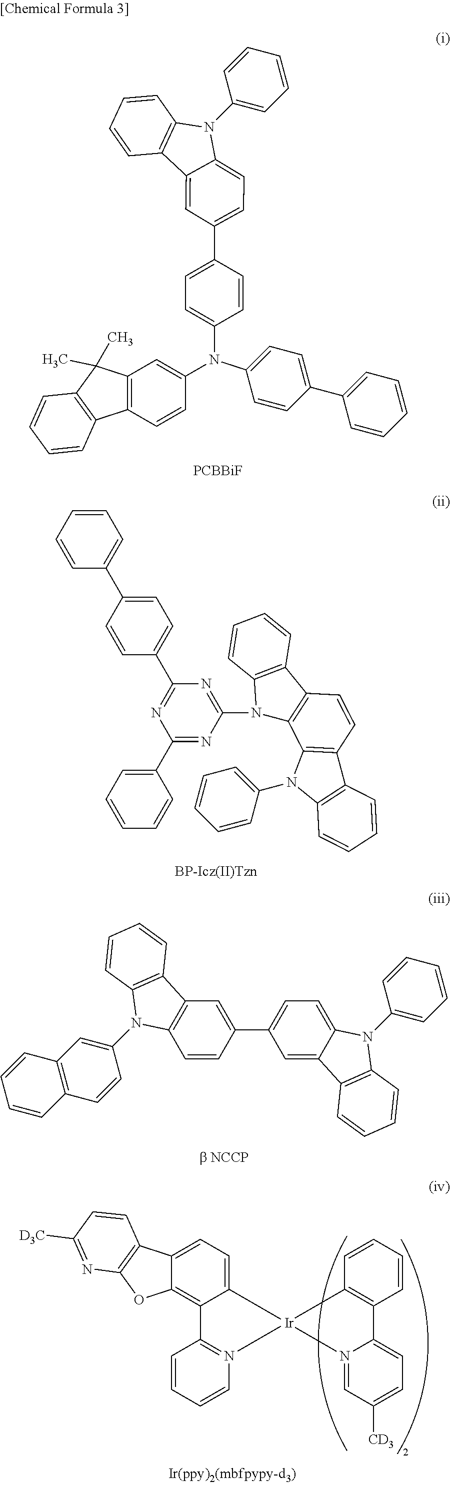

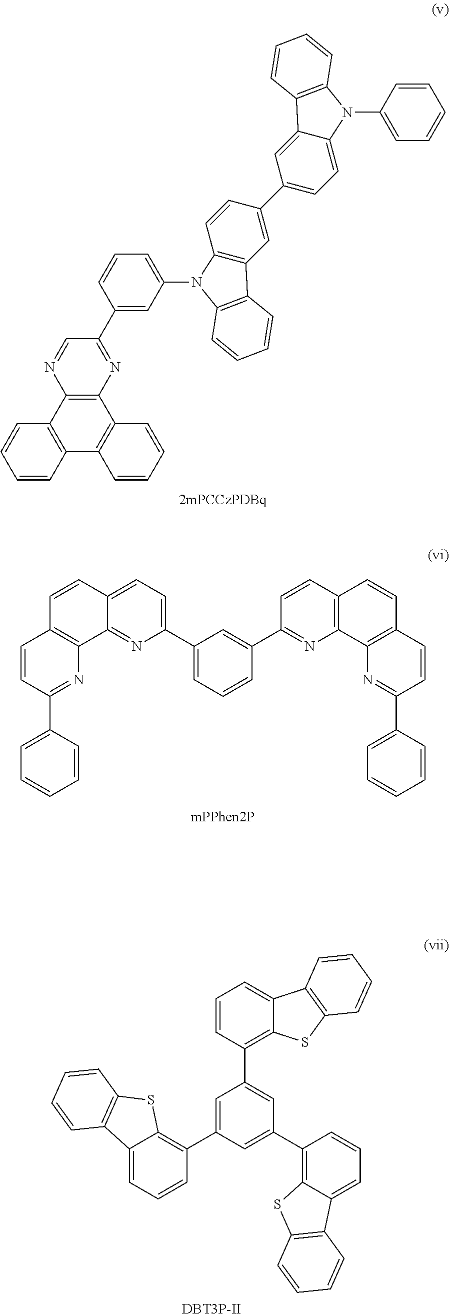 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

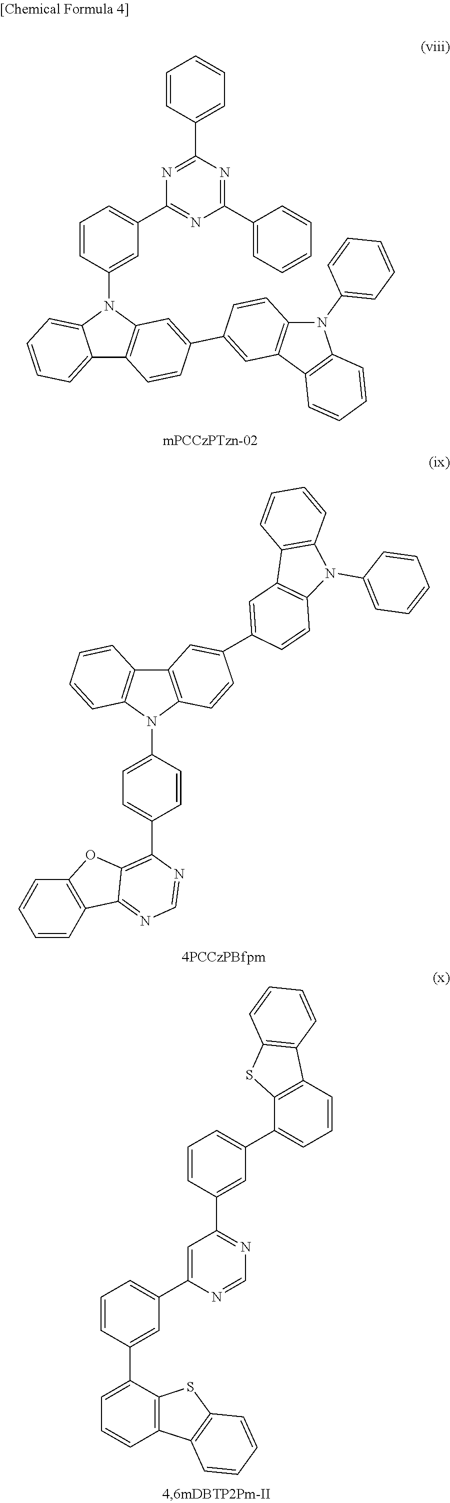 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-n2c3ccccc3c3cc(-c4ccc5c(c4)c4ccccc4n5-c4ccc(-c5ncnc6c5oc5ccccc56)cc4)ccc32)cc1 ; c1cc(-c2cc(-c3cccc(-c4cccc5c4sc4ccccc45)c3)ncn2)cc(-c2cccc3c2sc2ccccc23)c1]

### (Method for Fabricating Light-Emitting Device 1-1)

First, 100-nm-thick silver (Ag) as a reflective electrode and 85-nm-thick indium tin oxide containing silicon oxide (ITSO) as a transparent electrode were stacked over a glass substrate sequentially from the substrate side by a sputtering method, whereby the first electrode 101 with a size of 2 mm×2 mm was formed. Note that ITSO functions as an anode, and the stacked-layer structure of Ag and ITSO is regarded as the first electrode 101.

Then, pretreatment for formation of the light-emitting device over the substrate was performed by washing the substrate surface with water.

After that, the substrate was transferred into a vacuum evaporation apparatus in which the pressure was reduced to approximately 1×10⁻⁴ Pa, vacuum baking was performed at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an inorganic insulating film and the first electrode 101, the hole-injection layer 111 was formed by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) to have a thickness of 10 nm and a weight ratio of 1:0.03 (=PCBBiF:OCHD-003).

Over the hole-injection layer 111, PCBBiF was formed to have a thickness of 70 nm by evaporation, whereby the hole-transport layer 112 was formed.

Then, 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn) represented by Structural Formula (ii) above, 9-(2-naphthyl)-9′-phenyl-9H,9′H-3,3′-bicarbazole (abbreviation: βNCCP) represented by Structural Formula (iii) above, and [2-d₃-methyl-8-(2-pyridinyl-AN)benzofuro[2,3-b]pyridine-κC]bis[2-(5-d₃-methyl-2-pyridinyl-κN2)phenyl-κC]iridium(III) (abbreviation: Ir(5mppy-d₃)₂(mbfpypy-d₃)) represented by Structural Formula (iv) above were deposited by co-evaporation to a thickness of 40 nm such that the weight ratio was 0.5:0.5:0.1 (=BP-Icz(II)Tzn:βNCCP:Ir(5mppy-d₃)₂(mbfpypy-d₃)), whereby the light-emitting layer 113 was formed over the hole-injection layer 112.

After that, a first electron-transport layer was formed to a thickness of 20 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above, and then a second electron-transport layer was formed to a thickness of 15 nm by evaporation of 2,2′-(1,3-phenylene)bis(9-phenyl-1,10-phenanthroline) (abbreviation: mPPhen2P) represented by Structural Formula (vi) above, whereby the electron-transport layer 114 was formed. Note that the first electron-transport layer also functions as a hole-blocking layer.

This was followed by standing in an air atmosphere for one hour in the light-blocking state, and then heat treatment was performed at 110° C. for one hour in an atmosphere under approximately 1×10⁻⁴ Pa or lower.

After the heat treatment, lithium fluoride (LiF) and ytterbium (Yb) were formed by co-evaporation to a thickness of 1.5 nm such that the volume ratio of LiF to Yb was 1:0.5 to form the electron-injection layer 115, and then, silver (Ag) and magnesium (Mg) were formed by co-evaporation to a thickness of 15 nm such that the volume ratio of Ag to Mg was 1:0.1 to form the second electrode 102. Over the second electrode 102, 4,4′,4″-(benzene-1,3,5-triyl)tri(dibenzothiophene) (abbreviation: DBT3P-II) represented by Structural Formula (v) above was deposited to a thickness of 70 nm as a cap layer to improve light extraction efficiency.

Then, the light-emitting device was sealed using a glass substrate in a glove box containing a nitrogen atmosphere so as not to be exposed to the air (a UV curable sealing material was applied to surround the element, only the sealing material was irradiated with UV while the light-emitting device was prevented from being irradiated with the UV, and heat treatment was performed at 80° C. under an atmospheric pressure for one hour), so that the light-emitting device 1-1 was fabricated.

### (Method for Fabricating Light-Emitting Device 1-2)

The light-emitting device 1-2 was fabricated in a manner similar to that for the light-emitting device 1-1 except that standing in an air atmosphere was performed in the environment with fluorescent lamp light irradiation after formation of the electron-transport layer. Note that the illuminance of the fluorescent lamp light was 317 lux.

### (Method for Fabricating Light-Emitting Device 2-1)

A light-emitting device 2-1 was fabricated in a manner similar to that for the light-emitting device 1-1 except that BP-Icz(II)Tzn in the light-emitting device 1-1 was replaced with 9-[3-(4,6-diphenyl-1,3,5-triazin-2-yl)phenyl]-9′-phenyl-2,3′-bi-9H-carbazole (abbreviation: mPCCzPTzn-02) represented by Structural Formula (viii) above.

### (Method for Fabricating Light-Emitting Device 2-2)

A light-emitting device 2-2 was fabricated in a manner similar to that for the light-emitting device 2-1 except that standing in an air atmosphere was performed in the environment with fluorescent lamp light irradiation after formation of the electron-transport layer.

### (Method for Fabricating Light-Emitting Device 3-1)

A light-emitting device 3-1 was fabricated in a manner similar to that for the light-emitting device 1-1 except that BP-Icz(II)Tzn in the light-emitting device 1-1 was replaced with 4-{4-[2-(N-phenyl-9H-carbazol-3-yl)-9H-carbazol-9-yl]phenyl}benzofuro(3,2-d)pyrimidine (abbreviation: 4PCCzPBfpm) represented by Structural Formula (ix) above.

### (Method for Fabricating Light-Emitting Device 3-2)

A light-emitting device 3-2 was fabricated in a manner similar to that for the light-emitting device 3-1 except that standing in an air atmosphere was performed in the environment with fluorescent lamp light irradiation after formation of the electron-transport layer. Note that the illuminance of the fluorescent lamp light was 317 lux.

### (Method for Fabricating Light-Emitting Device 4-1)

A light-emitting device 4-1 was fabricated in a manner similar to that for the light-emitting device 1-1 except that BP-Icz(II)Tzn in the light-emitting device 1-1 was replaced with 4,6-bis[3-(dibenzothiophen-4-yl)phenyl]pyrimidine (abbreviation: 4,6mDBTP2Pm-II) represented by Structural Formula (x) above.

### (Method for Fabricating Light-Emitting Device 4-2)

A light-emitting device 4-2 was fabricated in a manner similar to that for the light-emitting device 4-1 except that standing in an air atmosphere was performed in the environment with fluorescent lamp light irradiation after formation of the electron-transport layer. Note that the illuminance of the fluorescent lamp light was 317 lux.

The element structures of the light-emitting device 1-1 to the light-emitting device 4-2 are listed in the following table.

TABLE 1

| | | | | |
|---|---|---|---|---|
| Film | | | | |
| thickness | Light-emitting | Light-emitting | Light-emitting | Light-emitting |
| (nm) | device 1-X | device 2-X | device 3-X | device 4-X |

| Cap layer | | 70 | DBT3P-II |
|---|---|---|---|
| Second electrode | | 15 | Ag:Mg (1:0.1) |
| | | 1.5 | LiF:Yb (2:1) |
| Air exposure | | | *1 |
| Second electron-transport layer | | 15 | mPPhen2P |
| First electron-transport layer | | 20 | 2mPCCzPDBq |
| Light-emitting layer | | 40 | *2:βNCCP:Ir(5mppy-d₃)₂(mbfpypy-d₃) |
| | | | (0.5:0.5:0.1) |
| Hole-transport layer | | 70 | PCBBiF |
| Hole-injection layer | | 10 | PCBBiF:OCHD-003 |
| | | | (1:0.03) |
| First | Transparent electrode | 85 | ITSO |
| electrode | Reflective electrode | 100 | Ag |

*1 X = 1:In light-blocking state, X = 2:Under fluorescent lamp light irradiation
*2Light-emitting device 1-X:BP-Icz(II)Tzn
Light-emitting device 2-X:mPCCzPTzn-02
Light-emitting device 3-X:4PCCzPBfpm
Light-emitting device 4-X:4,6mDBTP2Pm-II

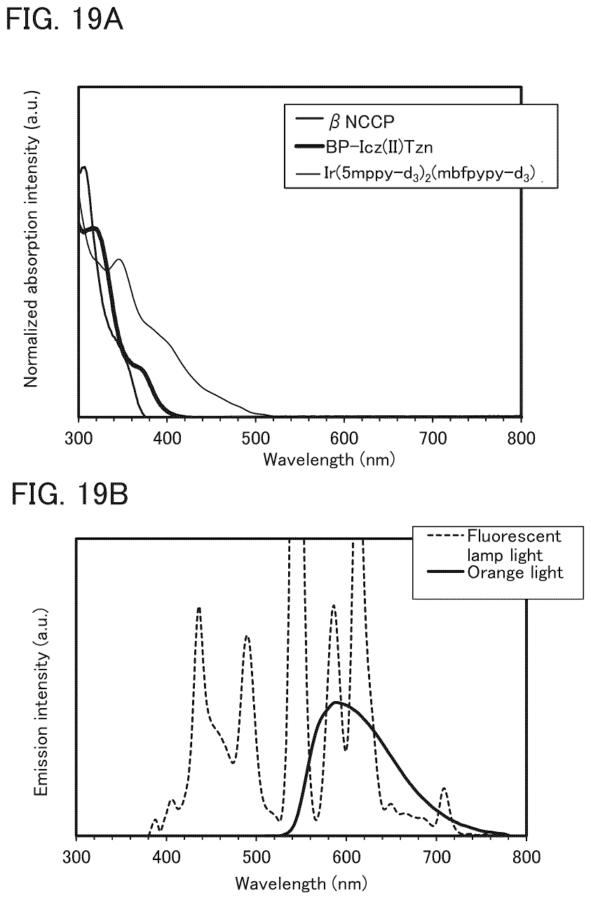

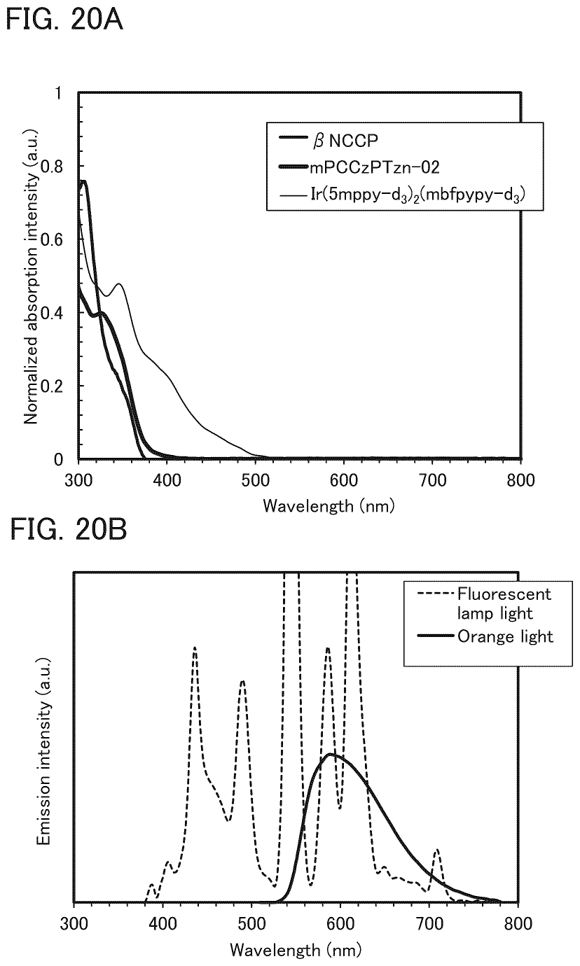

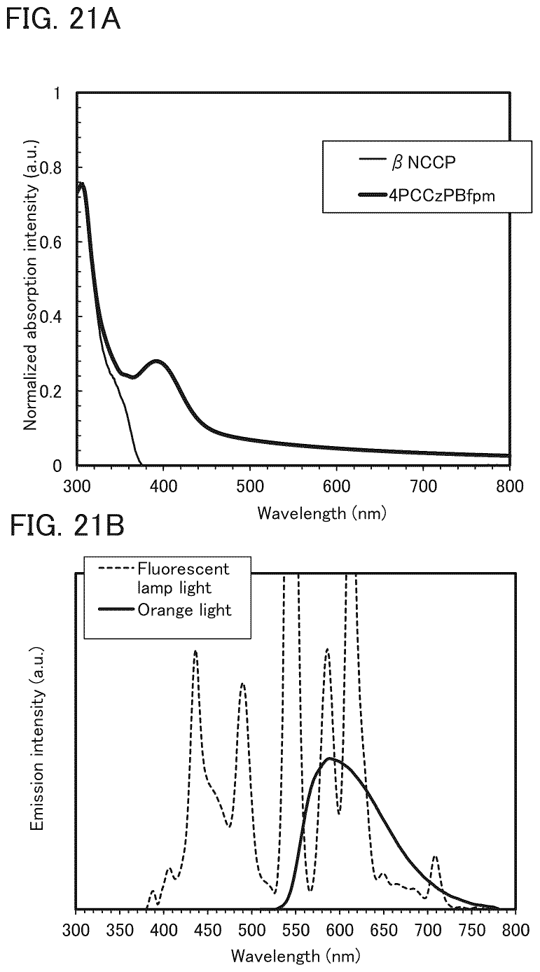

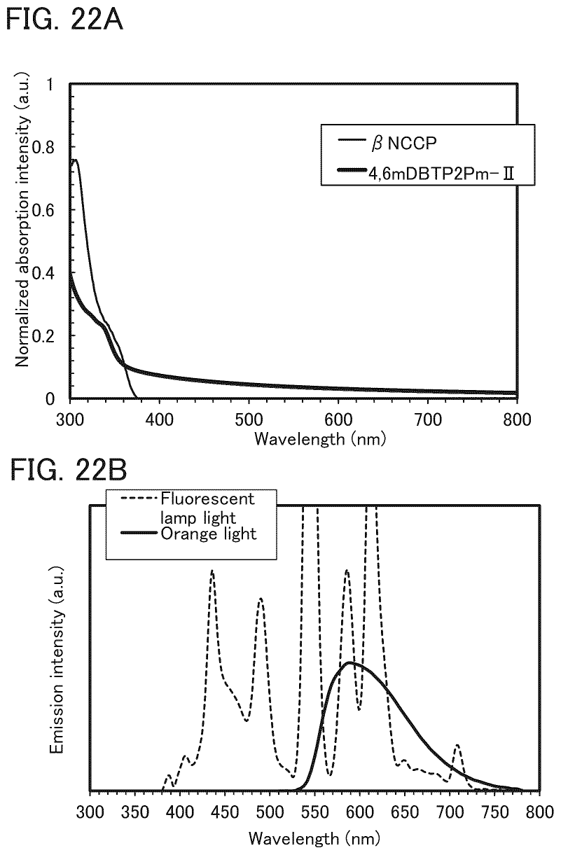

FIG. 19 to FIG. 22 show the absorption spectra of the organic compounds used in the light-emitting layers of the light-emitting device 1 to the light-emitting device 4 and the emission spectrum of fluorescent lamp light, and the emission spectrum of orange light.

Note that the absorption spectra of the host materials were measured in a thin-film state. Specifically, each of the organic compounds was formed as a thin film having a thickness of approximately 50 nm over a quartz substrate and measurement was performed thereon. The measurement was performed with a UV-visible spectrophotometer (U-4100, Hitachi High-Technologies Corporation). The absorption spectrum of the thin film was calculated using an absorbance (−log₁₀(% T/(100−% R))) obtained from a transmittance (% T) and a reflectance (% R) of the substrate and the thin film.

The measurement was performed on a light-emitting substance in a solution state. Specifically, the absorption spectrum (ultraviolet-visible absorption spectrum) of Ir(5mppy-d₃)₂(mbfpypy-d₃) in a dichloromethane solution was measured. The absorption spectrum was measured with an ultraviolet-visible spectrophotometer (V550 manufactured by JASCO Corporation).

From FIG. 19 to FIG. 22 or the above structural formulae, it was found that each of the substances other than the light-emitting substance (the host material and the assist material) used for the light-emitting device 1 to the light-emitting device 4 satisfies any of the following: having the longest-wavelength absorption edge in the absorption spectrum at a wavelength of less than 400 nm; having none of a structure where two adjacent six-membered aromatic rings are fused, a structure where two adjacent six-membered heteroaromatic rings are fused, and a structure where a six-membered aromatic ring and a six-membered heteroaromatic ring that are adjacent to each other are fused; including a fused ring where a six-membered ring and a five-membered ring are alternately fused; or not having a naphthalene skeleton; including none of a naphthalene ring, a phenanthrene ring, and a naphthacene ring; and not including a fused ring composed only of six-membered rings, and thus, the light-emitting devices are each regarded as the light-emitting device of one embodiment of the present invention.

Specifically, the longest-wavelength absorption edges among the absorption edges in the absorption spectra of βNCCP, BP-Icz(II)Tzn, mPCCzPTzn-02, 4PCCzPBfpm, 4,6mDBTP2Pm-II were at 372 nm, 398 nm, 375 nm, 448 nm, and 355 nm, respectively. Furthermore, the absorbances at a wavelength of greater than or equal to 400 nm and less than or equal to 475 nm of βNCCP, BP-Icz(II)Tzn, and mPCCzPTzn-02 were less than or equal to 0.01.

The longest-wavelength absorption edge among the absorption edges in the absorption spectrum of Ir(5mppy-d₃)₂(mbfpypy-d₃) was at 526 nm. The molar absorption coefficient at a wavelength of 400 nm of Ir(5mppy-d₃)₂(mbfpypy-d₃) was 11700 M⁻¹·cm⁻¹.

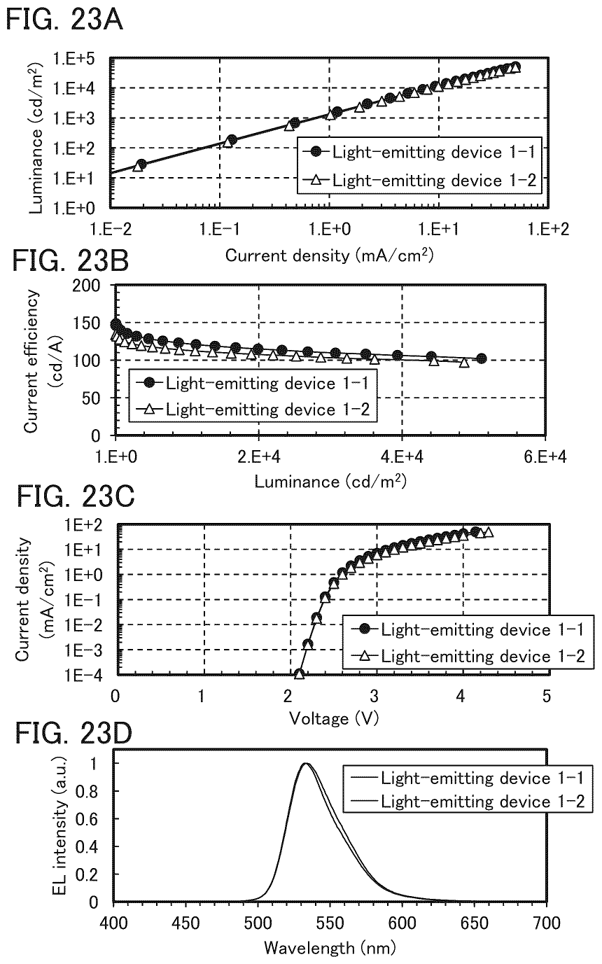

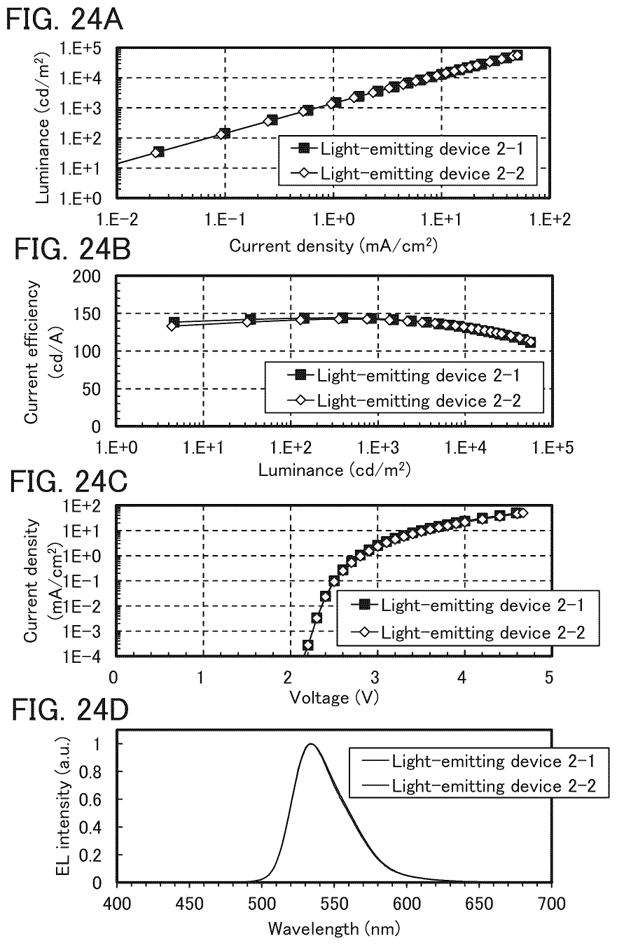

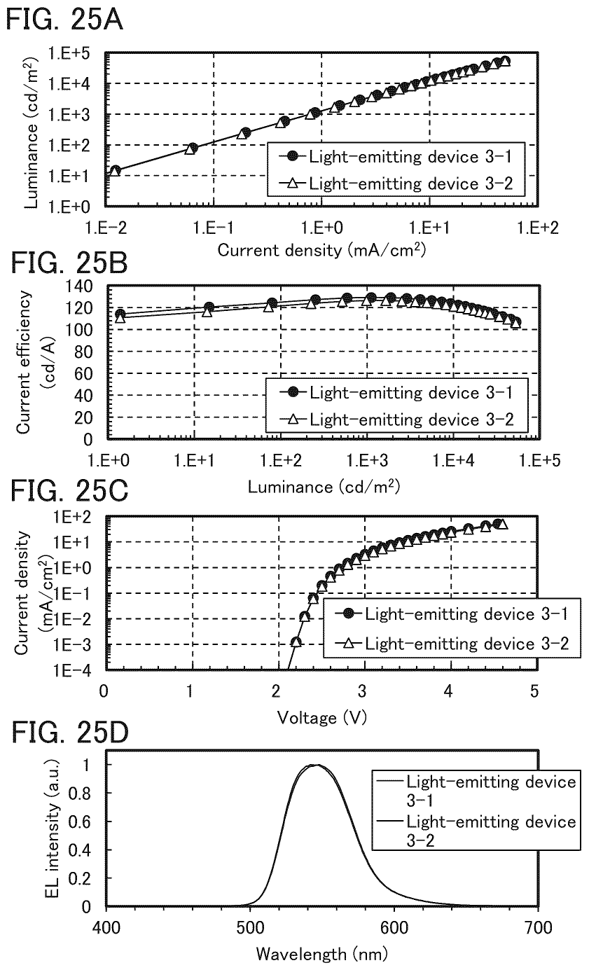

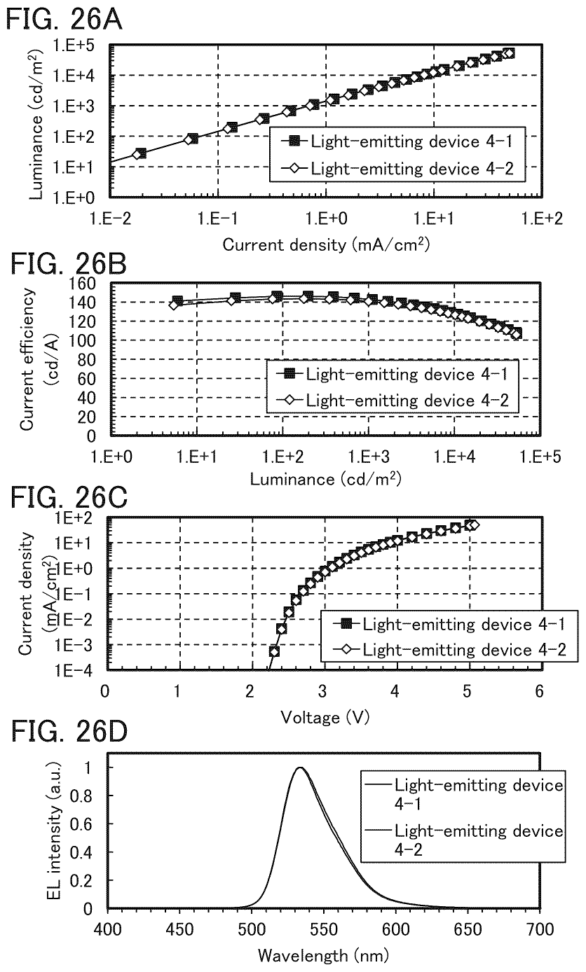

FIG. 23 to FIG. 26 show the initial characteristics of these light-emitting devices. Note that among those graphs, A shows luminance-current density characteristics, B shows current efficiency-luminance characteristics, C shows current density-voltage characteristics, and D shows electroluminescence spectra. The values of the main voltage, current, current density, CIE chromaticity, and current efficiency at approximately 1000 cd/cm² are shown below. The luminance, CIE chromaticity, and emission spectra were measured at normal temperature with a spectroradiometer (SR-UL1R manufactured by TOPCON CORPORATION).

TABLE 2

| | | | Current | Chroma- | Chroma- | Current |
|---|---|---|---|---|---|---|
| | Voltage | Current | density | ticity | ticity | efficiency |
| | (V) | (mA) | (mA/cm²) | x | y | (cd/A) |
| Light- | 2.5 | 0.02 | 0.5 | 0.28 | 0.69 | 140.1 |
| emitting | | | | | | |
| device 1-1 | | | | | | |
| Light- | 2.6 | 0.04 | 1.0 | 0.29 | 0.69 | 124.4 |
| emitting | | | | | | |
| device 1-2 | | | | | | |
| Light- | 2.7 | 0.02 | 0.6 | 0.29 | 0.68 | 143.3 |
| emitting | | | | | | |
| device 2-1 | | | | | | |
| Light- | 2.7 | 0.02 | 0.5 | 0.29 | 0.69 | 142.2 |
| emitting | | | | | | |
| device 2-2 | | | | | | |
| Light- | 2.7 | 0.03 | 0.9 | 0.33 | 0.65 | 129.1 |
| emitting | | | | | | |
| device 3-1 | | | | | | |
| Light- | 2.7 | 0.03 | 0.8 | 0.34 | 0.65 | 126.2 |
| emitting | | | | | | |
| device 3-2 | | | | | | |
| Light- | 3.0 | 0.03 | 0.8 | 0.29 | 0.69 | 142.6 |
| emitting | | | | | | |
| device 4-1 | | | | | | |
| Light- | 3.0 | 0.03 | 0.7 | 0.29 | 0.68 | 140.6 |
| emitting | | | | | | |
| device 4-2 | | | | | | |

It was found from FIG. 23 to FIG. 26 that in the case where the light-emitting device of one embodiment of the present invention is exposed to the air in the middle of fabrication, the driving voltage does not vary depending on the presence or absence of fluorescent lamp light irradiation. In addition, a reduction in current efficiency also did not occur in the light-emitting device 2 to the light-emitting device 4.

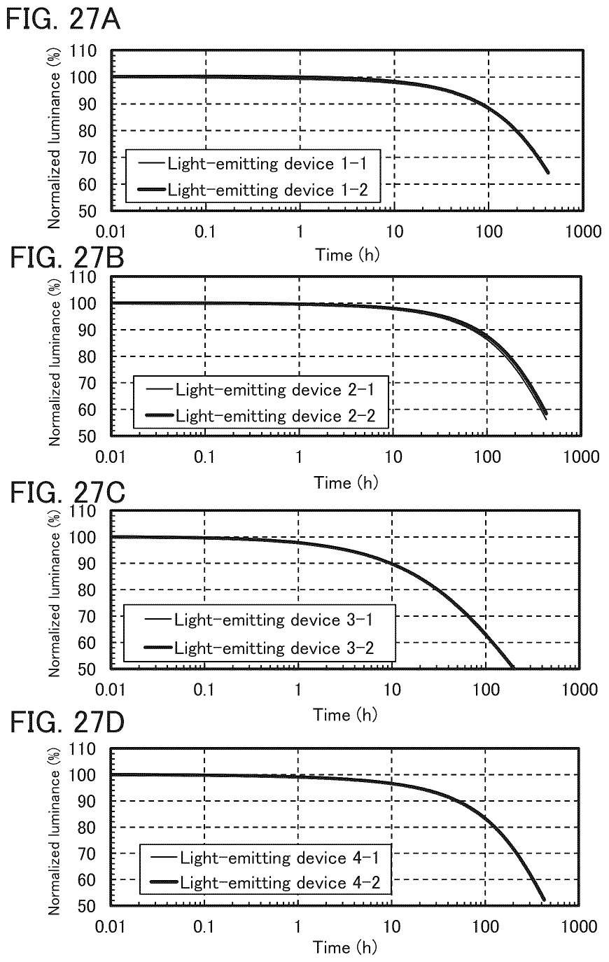

FIG. 27 shows the results of measuring changes in luminance over driving time in constant-current driving at a current density of 50 mA/cm². It was found from FIG. 27 that the presence or absence of fluorescent lamp light irradiation does not affect a change in luminance over driving time of the light-emitting of one embodiment of the present invention.

### [Light-Emitting Device 5]

The fabrication methods and characteristics of light-emitting devices 5 that are light-emitting devices of one embodiment of the present invention emitting blue phosphorescent light will be described in detail below. Organic compounds used for the light-emitting device 5 are shown below.

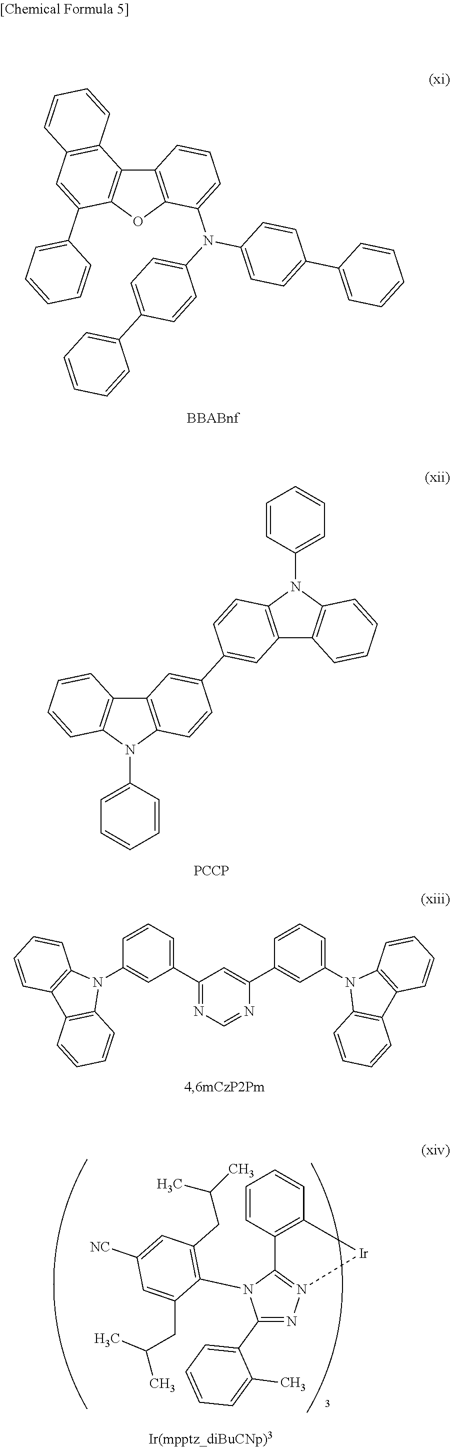

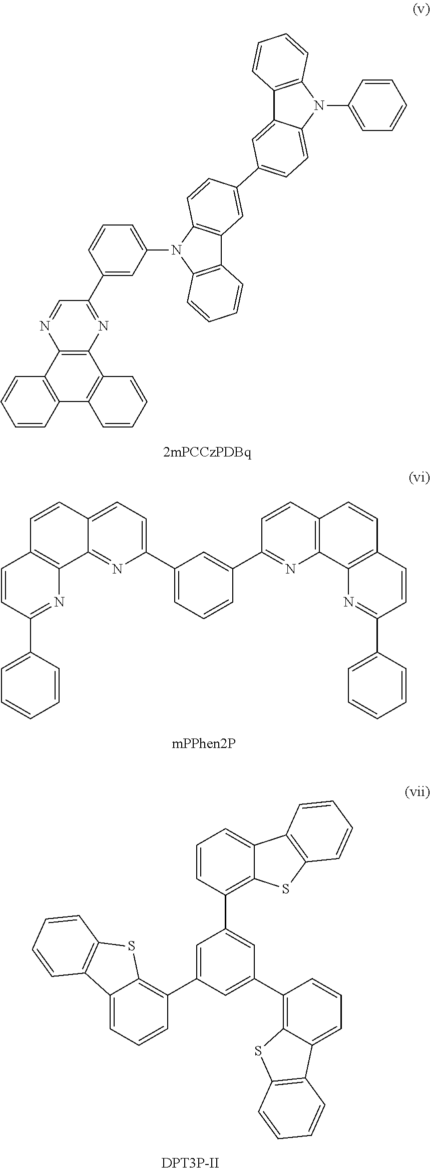 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; c1ccc2c(c1)sc1c(-c3cc(-c4cccc5c4sc4ccccc45)cc(-c4cccc5c4sc4ccccc45)c3)cccc12 ; "DPT3P-II"]

### (Method for Fabricating Light-Emitting Device 5-1)

First, 100-nm-thick silver (Ag) as a reflective electrode and 85-nm-thick indium tin oxide containing silicon oxide (ITSO) as a transparent electrode were stacked over a glass substrate sequentially from the substrate side by a sputtering method, whereby the first electrode 101 with a size of 2 mm×2 mm was formed. Note that ITSO functions as an anode, and the stacked-layer structure of Ag and ITSO is regarded as the first electrode 101.

Then, pretreatment for formation of the light-emitting device over the substrate was performed by washing the substrate surface with water.

After that, the substrate was transferred into a vacuum evaporation apparatus in which the pressure was reduced to approximately 1×10⁻⁴ Pa, vacuum baking was performed at 170° C. for 30 minutes in a heating chamber of the vacuum evaporation apparatus, and then the substrate was cooled down for approximately 30 minutes.

Next, the substrate was fixed to a substrate holder provided in the vacuum evaporation apparatus such that the side on which the first electrode 101 was formed faced downward. Then, over an inorganic insulating film and the first electrode 101, N,N-bis(4-biphenyl)-6-phenylbenzo[b]naphtho[1,2-d]furan-8-amine (abbreviation: BBABnf) represented by Structural Formula (xi) above and a fluorine-containing electron acceptor material (OCHD-003) with a molecular weight of 672 were deposited by co-evaporation to a thickness of 10 nm such that the weight ratio of BBABnf to OCHD-003 was 1:0.1; thus, the hole-injection layer 111 was formed.

After BBABnf was deposited over the hole-injection layer 111 by evaporation to a thickness of 40 nm, 3,3′-bis(9-phenyl-9H-carbazole) (abbreviation: PCCP) represented by Structural Formula (xii) above was deposited by evaporation to a thickness of 20 nm to form the hole-transport layer 112.

Then, the light-emitting layer 113 was formed in the following manner: 4,6-bis[3-(9H-carbazol-9-yl)phenyl]pyrimidine (abbreviation: 4,6mCzP2Pm) represented by Structural Formula (xiii) above, PCCP, and tris{2-[4-(4-cyano-2,6-diisobutylphenyl)-5-(2-methylphenyl)-4H-1,2,4-triazol-3-yl-κN₂]phenyl-κC}iridium(III) (abbreviation: Ir(mpptz-diBuCNp)₃) represented by Structural Formula (xiv) above were deposited by co-evaporation to a thickness of 30 nm at a weight ratio of 0.5:0.5:0.06 (=4,6mCzP2Pm:PCCP:Ir(mpptz-diBuCNp)₃) to form a first light-emitting layer, and then, 4,6mCzP2Pm, PCCP, and [Ir(mpptz-diBuCNp)₃]were deposited by co-evaporation to a thickness of 10 nm at a weight ratio of 0.8:0.2:0.06 (=4,6mCzP2Pm:PCCP:Ir(mpptz-diBuCNp)₃) to form a second light-emitting layer, whereby the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 10 nm to form the first electron-transport layer, and then 2,2′-(1,3-phenylene)bis(9-phenyl-1,10-phenanthroline) (abbreviation: mPPhen2P) represented by Structure Formula (vi) above was deposited by evaporation to a thickness of 15 nm to form the second electron-transport layer, whereby the electron-transport layer 114 was formed. Note that the first electron-transport layer also functions as a hole-blocking layer.

This was followed by standing in an air atmosphere for one hour in the light-blocking state, and then heat treatment was performed at 110° C. for one hour in an atmosphere under approximately 1×10⁻⁴ Pa or lower.

After the heat treatment, lithium fluoride (LiF) and ytterbium (Yb) were formed by co-evaporation to a thickness of 1.5 nm such that the volume ratio of LiF to Yb was 1:0.5 to form the electron-injection layer 115, and then, silver (Ag) and magnesium (Mg) were formed by co-evaporation to a thickness of 15 nm such that the volume ratio of Ag to Mg was 1:0.1 to form the second electrode 102. Over the second electrode 102, 4,4′,4″-(benzene-1,3,5-triyl)tri(dibenzothiophene) (abbreviation: DBT3P-II) represented by Structural Formula (v) above was deposited to a thickness of 70 nm as a cap layer to improve light extraction efficiency.

The light-emitting device was sealed using a glass substrate in a glove box containing a nitrogen atmosphere so as not to be exposed to the air (a UV curable sealing material was applied to surround the elements, only the sealing material was irradiated with UV while the light-emitting device was prevented from being irradiated with the UV, and heat treatment was performed at 80° C. under an atmospheric pressure for one hour), so that the light-emitting device 5-1 was fabricated.

### (Method for Fabricating Light-Emitting Device 5-2)

A light-emitting device 5-2 was fabricated in a manner similar to that for the light-emitting device 5-1 except that standing in an air atmosphere was performed in the environment with fluorescent lamp light irradiation after formation of the electron-transport layer. Note that the illuminance of the fluorescent lamp light was 317 lux.

### (Method for Fabricating Light-Emitting Device 5-3)

A light-emitting device 5-3 was fabricated in a manner similar to that for the light-emitting device 5-1 except that standing in an air atmosphere was performed in the environment with orange light irradiation after formation of the electron-transport layer. Note that the illuminance of the orange light was 111 lux.

The element structures of the light-emitting device 5-1 to the light-emitting device 5-3 are listed in the following table.

TABLE 3

| | | | |
|---|---|---|---|
| Film | | | |
| thickness | Light-emitting | Light-emitting | Light-emitting |
| (nm) | device 5-1 | device 5-2 | device 5-3 |

| | | |
|---|---|---|
| Cap layer | 70 | DBT3P-II |
| Second electrode | 15 | Ag:Mg (1:0.1) |
| | 1.5 | LiF:Yb (2:1) |

| | | | |
|---|---|---|---|
| Air exposure | In light-blocking | Under fluorescent lamp | Under orange |
| | state | light irradiation | light irradiation |

| Electron-transport layer | | 15 | mPPhen2P |
|---|---|---|---|
| | | 10 | 2mPCCzPDBq |
| Light-emitting layer | | 10 | 4,6mCzP2Pm:PCCP:Ir(mpptz-diBuCNp)3 |
| | | | (0.8:0.2:0.06) |
| | | 30 | 4,6mCzP2Pm:PCCP:Ir(mpptz-diBuCNp)3 |
| | | | (0.5:0.5:0.06) |
| Hole-transport layer | | 20 | PCCP |
| | | 40 | BBABnf |
| Hole-injection layer | | 10 | BBABnf:OCHD-003 |
| | | | (1:0.1) |
| First | Transparent electrode | 85 | ITSO |
| electrode | Reflective electrode | 100 | Ag |

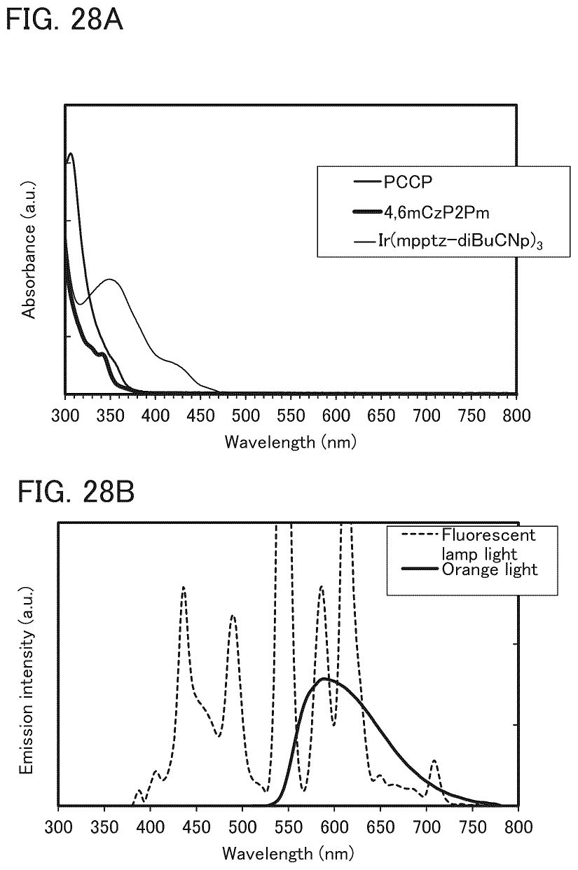

FIG. 28 shows the absorption spectra of the organic compounds used in the light-emitting layer of the light-emitting device 5, the emission spectrum of fluorescent lamp light, and the emission spectrum of orange light.

Note that the absorption spectrum of the host material was measured in a thin-film state. Specifically, each of the organic compounds was formed to a thickness of approximately 50 nm over a quartz substrate and measured. The measurement was performed with a UV-visible spectrophotometer (U-4100, Hitachi High-Technologies Corporation). The absorption spectrum of the thin film was calculated using an absorbance (−log₁₀ (% T/(100−% R))) obtained from a transmittance and a reflectance of the substrate and the thin film.

The measurement was performed on a light-emitting substance in a solution state. Specifically, the absorption spectrum (ultraviolet-visible absorption spectrum) of Ir(mpptz-diBuCNp)₃ in the dichloromethane solution was measured. The absorption spectrum was measured with an ultraviolet-visible spectrophotometer (V550 manufactured by JASCO Corporation).

From FIG. 28 and the above structural formulae, it was found that each of the substances other than the light-emitting substance (the host material) used for the light-emitting device 5 satisfies any of the following: having the longest-wavelength absorption edge in the absorption spectrum at a wavelength of less than or equal to 400 nm; having none of a structure where two adjacent six-membered aromatic rings are fused, a structure where two adjacent six-membered heteroaromatic rings are fused, and a structure where a six-membered aromatic ring and a six-membered heteroaromatic ring that are adjacent to each other are fused; the included fused ring is a fused ring where a six-membered ring and a five-membered ring are alternately fused; or not having a naphthalene skeleton; including none of a naphthalene ring, a phenanthrene ring, and a naphthacene ring; and not including a fused ring composed only of six-membered rings, thus, the light-emitting device is regarded as the light-emitting device of one embodiment of the present invention.

Specifically, the longest-wavelength absorption edge among the absorption edges in the absorption spectrum of PCCP was at 370 nm and that of 4,6mCzP2Pm was at 390 nm. The absorbances at a wavelength of greater than or equal to 400 nm and less than or equal to 475 nm of PCCP and 4,6mCzP2Pm were less than or equal to 0.01.

The longest-wavelength absorption edge among the absorption edges in the absorption spectrum of Ir(mpptz-diBuCNp)₃ was at 478 nm. The molar absorption coefficient at a wavelength of 400 nm of Ir(mpptz-diBuCNp)₃ was 5490 M⁻¹·cm⁻¹.

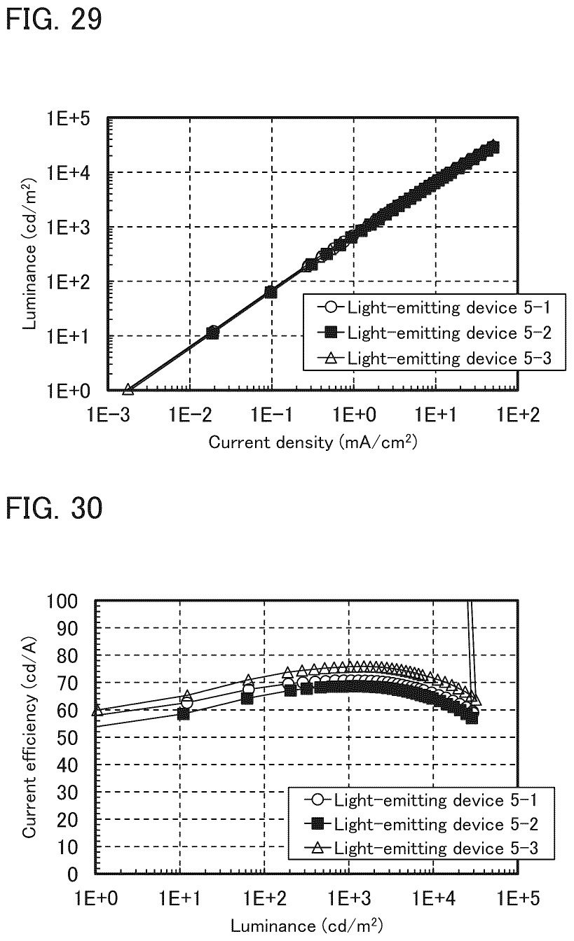

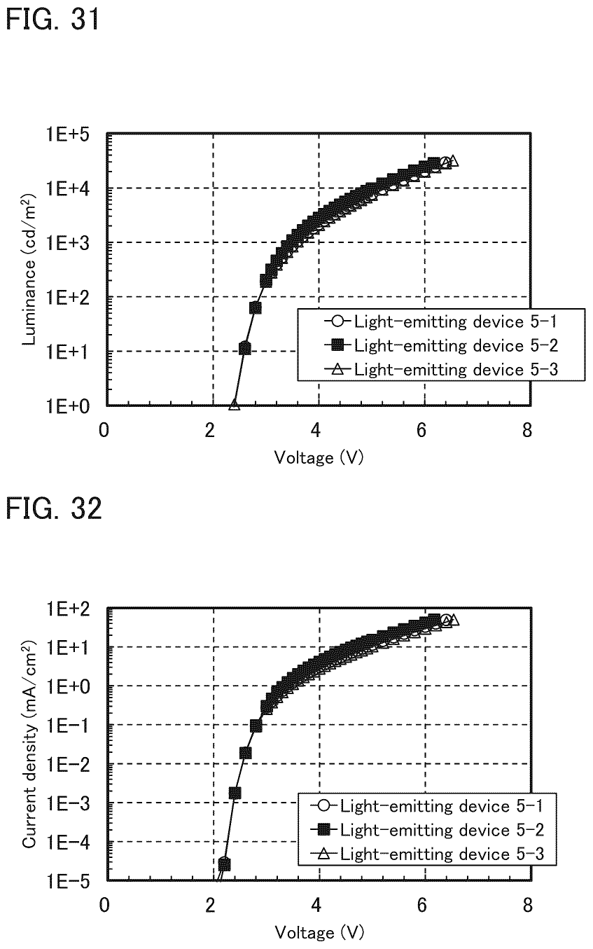

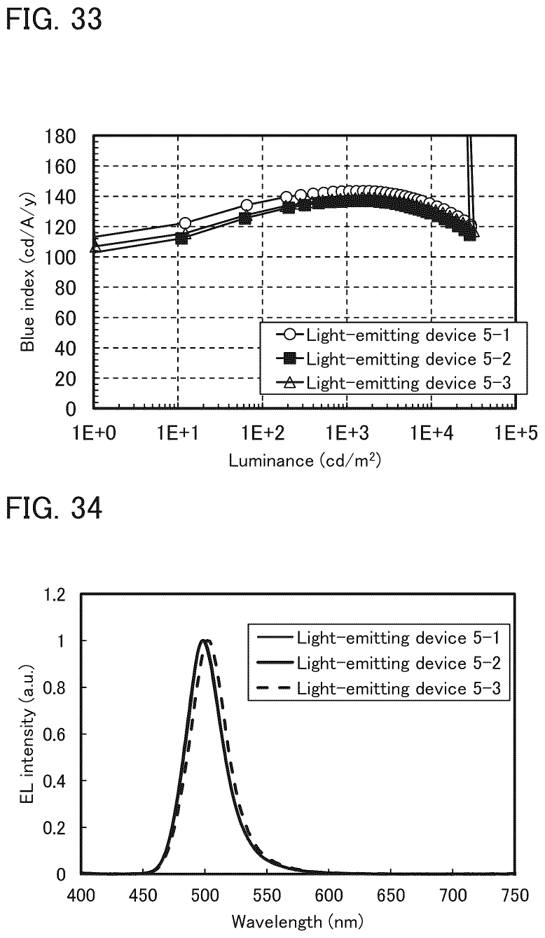

FIG. 29 shows luminance-current density characteristics of these light-emitting devices 5. FIG. 30 shows current efficiency-luminance characteristics thereof. FIG. 31 shows luminance-voltage characteristics thereof. FIG. 32 shows current density-voltage characteristics thereof. FIG. 33 shows blue index-luminance characteristics thereof. FIG. 34 shows emission spectra thereof. The values of the main voltage, current, current density, CIE chromaticity, current efficiency, and blue index at approximately 1000 cd/cm² are shown below. Note that the luminance, CIE chromaticity, and emission spectra were measured at normal temperature with a spectroradiometer (SR-UL1R manufactured by TOPCON CORPORATION).

TABLE 4

| | | | Current | Chroma- | Chroma- | Current | |
|---|---|---|---|---|---|---|---|
| | Voltage | Current | density | ticity | ticity | efficiency | BI |
| | (V) | (mA) | (mA/cm²) | x | y | (cd/A) | (cd/A/y) |
| Light-emitting | 3.5 | 0.05 | 1.2 | 0.09 | 0.49 | 70.7 | 143 |
| device 5-1 | | | | | | | |
| Light-emitting | 3.6 | 0.05 | 1.4 | 0.10 | 0.55 | 75.8 | 139 |
| device 5-2 | | | | | | | |
| Light-emitting | 3.5 | 0.06 | 1.6 | 0.09 | 0.50 | 68.7 | 137 |
| device 5-3 | | | | | | | |

It was found from FIG. 29 to FIG. 34 that in the case where the light-emitting device of one embodiment of the present invention is exposed to the air in the middle of fabrication, the driving voltage does not vary depending on the presence or absence of fluorescent lamp light irradiation or orange light irradiation. In addition, a reduction in current efficiency also did not occur in the light-emitting devices 5.

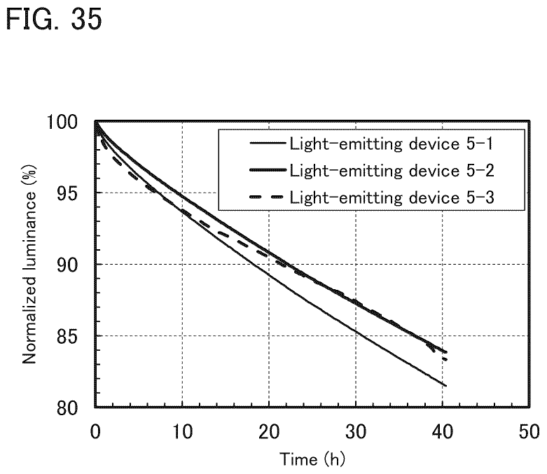

FIG. 35 shows the results of measuring changes in luminance over driving time in constant-current driving at a current density of 50 mA/cm². It was found from FIG. 35 that the presence or absence of fluorescent lamp light irradiation or orange light irradiation does not affect a change in luminance over driving time of the light-emitting of one embodiment of the present invention.

### [Comparative Light-Emitting Device 1 and the Comparative Light-Emitting Device 2]

The fabrication methods and characteristics of comparative light-emitting devices 1 and comparative light-emitting devices 2, which are light-emitting devices of embodiments of the present invention emitting blue fluorescent light, will be described in detail below. Organic compounds used for the comparative light-emitting device 1 and the comparative light-emitting device 2 are shown below.

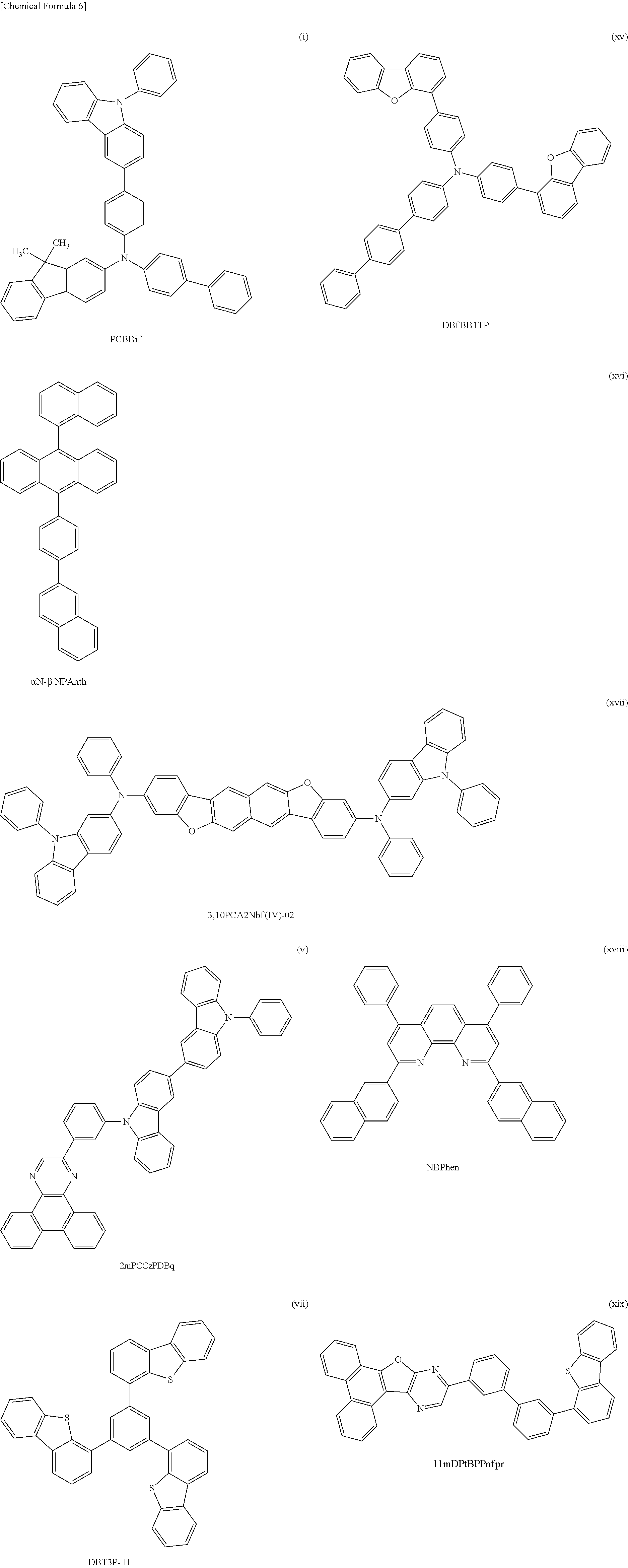

### (Method for Fabricating Comparative Light-Emitting Device 1-0)

First, 100-nm-thick silver (Ag) as a reflective electrode and 85-nm-thick indium tin oxide containing silicon oxide (ITSO) as a transparent electrode were stacked over a glass substrate sequentially from the substrate side by a sputtering method, whereby the first electrode 101 with a size of 2 mm×2 mm was formed. Note that ITSO functions as an anode, and the stacked-layer structure of Ag and ITSO is regarded as the first electrode 101.

Then, pretreatment for formation of the light-emitting device over the substrate was performed by washing the substrate surface with water.

After that, the substrate was transferred into a vacuum evaporation apparatus in which the pressure was reduced to approximately 1×10⁻⁴ Pa, vacuum baking was performed at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were formed by co-evaporation to a thickness of 10 nm such that the weight ratio of PCBBiF to OCHD-003 was 1:0.04, whereby the hole-injection layer 111 was formed.

Over the hole-injection layer 111, PCBBiF was deposited by evaporation to a thickness of 30 nm, and then N,N-bis[4-(dibenzofuran-4-yl)phenyl]-4-amino-p-terphenyl (abbreviation: DBfBB1TP) represented by Structural Formula (xv) above was formed by evaporation to a thickness of 10 nm, whereby the hole-transport layer 112 was formed.

Then, over the hole-transport layer 112, the light-emitting layer 113 was formed by co-evaporation of 9-(1-naphthyl)-10-[4-(2-naphthyl)phenyl]anthracene (abbreviation: α,N-βNPAnth) represented by Structural Formula (xvi) above and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (xvii) above to have a thickness of 20 nm and a weight ratio of 1:0.015 (=α,N-PNPAnth:3,10PCA2Nbf(IV)-02).

After that, a first electron-transport layer was formed to a thickness of 20 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above, and a second electron-transport layer was formed to a thickness of 15 nm by evaporation of 2,9-di(naphthalen-2-yl)-4,7-diphenyl-1,10-phenanthroline (abbreviation: NBPhen) represented by Structural Formula (xviii) above, whereby the electron-transport layer 114 was formed. Note that the first electron-transport layer also functions as a hole-blocking layer.

After that, lithium fluoride (LiF) and ytterbium (Yb) were deposited by co-evaporation to a thickness of 2 nm such that the volume ratio of LiF to Yb was 1:1 to form the electron-injection layer 115, and then, silver (Ag) and magnesium (Mg) were deposited by co-evaporation to a thickness of 15 nm such that the volume ratio of Ag to Mg was 1:0.1 to form the second electrode 102. Over the second electrode 102, 4,4′,4″-(benzene-1,3,5-triyl)tri(dibenzothiophene) (abbreviation: DBT3P-II) represented by Structural Formula (v) above was deposited to a thickness of 70 nm as a cap layer to improve light extraction efficiency.

Then, the light-emitting device was sealed using a glass substrate in a glove box containing a nitrogen atmosphere so as not to be exposed to the air (a UV curable sealing material was applied to surround the element, only the sealing material was irradiated with UV while the light-emitting device was prevented from being irradiated with the UV, and heat treatment was performed at 80° C. under an atmospheric pressure for one hour), so that a comparative light-emitting device 1-0 was fabricated.

### (Method for Fabricating Comparative Light-Emitting Device 1-1)

A comparative light-emitting device 1-1 was fabricated in a manner similar to that for the comparative light-emitting device 1-0 except that the electron-injection layer and the components thereafter were formed after standing in an air atmosphere for one hour in the light-blocking state and then heat treatment at 110° C. for one hour in an atmosphere under approximately 1×10⁻⁴ Pa or lower after formation of the electron-transport layer.

### (Method for Fabricating Comparative Light-Emitting Device 1-2)

A comparative light-emitting device 1-2 was fabricated in a manner similar to that for the comparative light-emitting device 1-0 except that the first hole-transport layer was formed to have a thickness of 35 nm and the electron-injection layer and the components thereafter were formed after standing in an air atmosphere for one hour under irradiation of fluorescent lamp light and then heat treatment at 110° C. for one hour in an atmosphere under approximately 1×10⁻⁴ Pa or lower after formation of the electron-transport layer. Note that the illuminance of the fluorescent lamp light was 317 lux.

### (Method for Fabricating Comparative Light-Emitting Device 1-3)

A comparative light-emitting device 1-3 was fabricated in a manner similar to that for the comparative light-emitting device 1-0 except that the electron-injection layer and the components thereafter were formed after standing in an air atmosphere for one hour under irradiation of orange light and then heat treatment at 110° C. for one hour in an atmosphere under approximately 1×10⁻⁴ Pa or lower after formation of the electron-transport layer. Note that the illuminance of the orange light was 111 lux.

The element structures of the comparative light-emitting device 1-0 to the comparative light-emitting device 1-3 are listed in the following table.

TABLE 5

| | | | | |
|---|---|---|---|---|
| Film | Comparative | Comparative | Comparative | Comparative |
| thickness | light-emitting | light-emitting | light-emitting | light-emitting |
| (nm) | device 1-0 | device 1-1 | device 1-2 | device 1-3 |

| | | |
|---|---|---|
| Cap layer | 70 | DBT3P-II |
| Second electrode | 20 | Ag:Mg (1:0.1) |
| | 2 | LiF:Yb (1:1) |

| | | | | |
|---|---|---|---|---|
| Air exposure | N/A (Continuous | In light-blocking | Under fluorescent lamp | Under orange light |
| | vacuum) | state | light irradiation | irradiation |

| Electron-transport layer | | 15 | NBPhen |
|---|---|---|---|
| | | 20 | 2mPCCzPDBq |
| Light-emitting layer | | 20 | αN-βNPAnth:3,10PCA2Nbf(IV)-02 |
| | | | (1:0.015) |
| Hole-transport layer | | 10 | DBfBB1TP |
| | | *1 | PCBBiF |
| Hole-injection layer | | 10 | PCBBiF:OCHD-003 |
| | | | (1:0.04) |
| First | Transparent electrode | 85 | ITSO |
| electrode | Reflective electrode | 100 | Ag |

*1: Comparative light-emitting device 1-0 30 nm
Comparative light-emitting device 1-1 30 nm
Comparative light-emitting device 1-2 35 nm
Comparative light-emitting device 1-3 30 nm

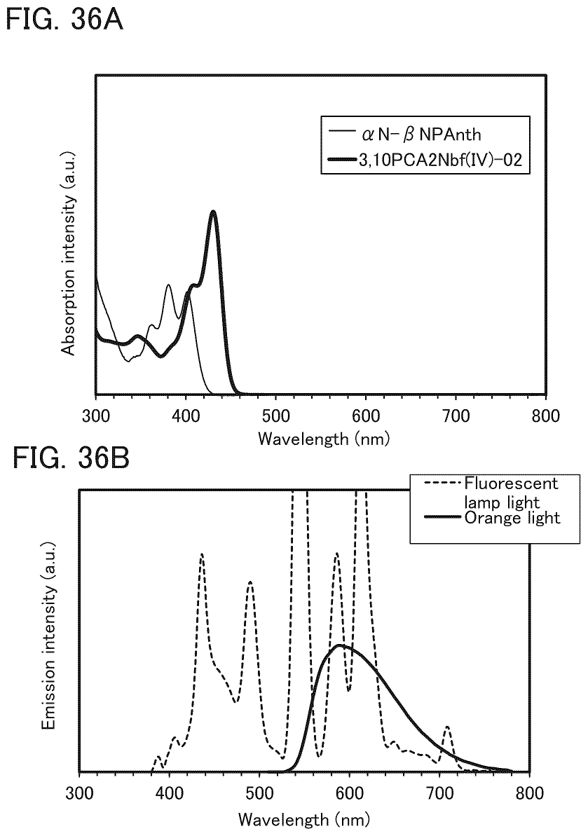

FIG. 36 shows the absorption spectra of the organic compounds used in the light-emitting layer of the comparative light-emitting device 1, the emission spectrum of fluorescent lamp light, and the emission spectrum of orange light.

Note that the absorption spectrum of the host material was measured in a thin-film state. Specifically, each of the organic compounds was formed to a thickness of approximately 50 nm over a quartz substrate and measured. The measurement was performed with a UV-visible spectrophotometer (U-4100, Hitachi High-Technologies Corporation). The absorption spectrum of the thin film was calculated using an absorbance (−log₁₀ (% T/(100−% R))) obtained from a transmittance and a reflectance of the substrate and the thin film.

The measurement was performed on a light-emitting substance in a solution state. Specifically, an absorption spectrum (ultraviolet-visible absorption spectrum) of 3,10PCA2Nbf(IV)-02 in a toluene solution was measured. The absorption spectrum was measured with an ultraviolet-visible spectrophotometer (V550 manufactured by JASCO Corporation).

From FIG. 36 and the above structural formulae, it was found that each of the substances other than the light-emitting substance (the host material) used for the light-emitting device 1 satisfies any of the following: having the longest-wavelength absorption edge in the absorption spectrum at a wavelength of less than or equal to 400 nm; having a structure where two adjacent six-membered aromatic rings are fused; having a naphthalene skeleton; and including a fused ring composed only of six-membered rings, thus, it is confirmed that the light-emitting device is not the light-emitting device of one embodiment of the present invention.

Specifically, the longest-wavelength absorption edge among the absorption edges in the absorption spectrum of αN-βNPAnth was at 420 nm. The absorbance at a wavelength of 400 nm of αN-βNPAnth was 0.29.

The longest-wavelength absorption edge among the absorption edges in the absorption spectrum of 3,10PCA2Nbf(IV)-02 was at 448 nm.

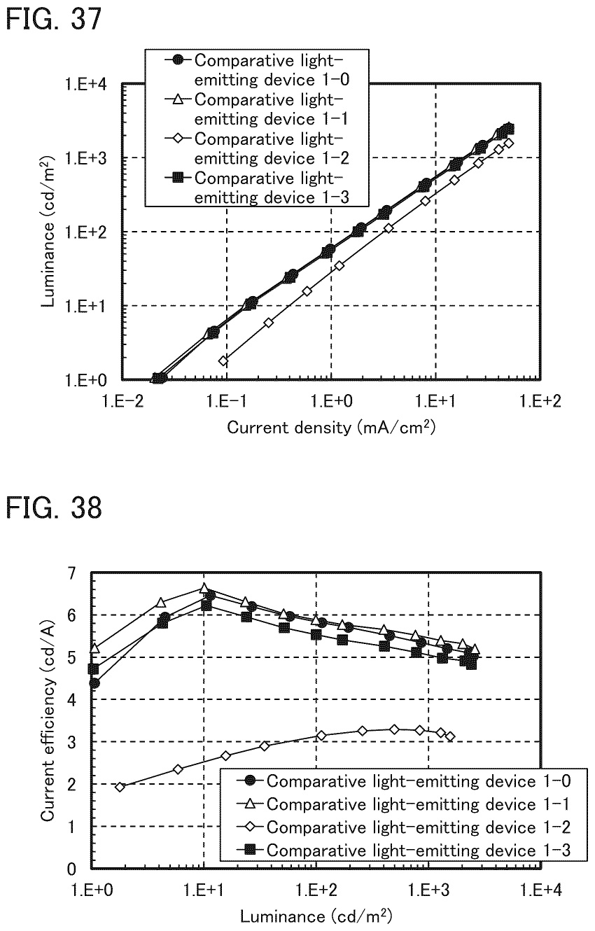

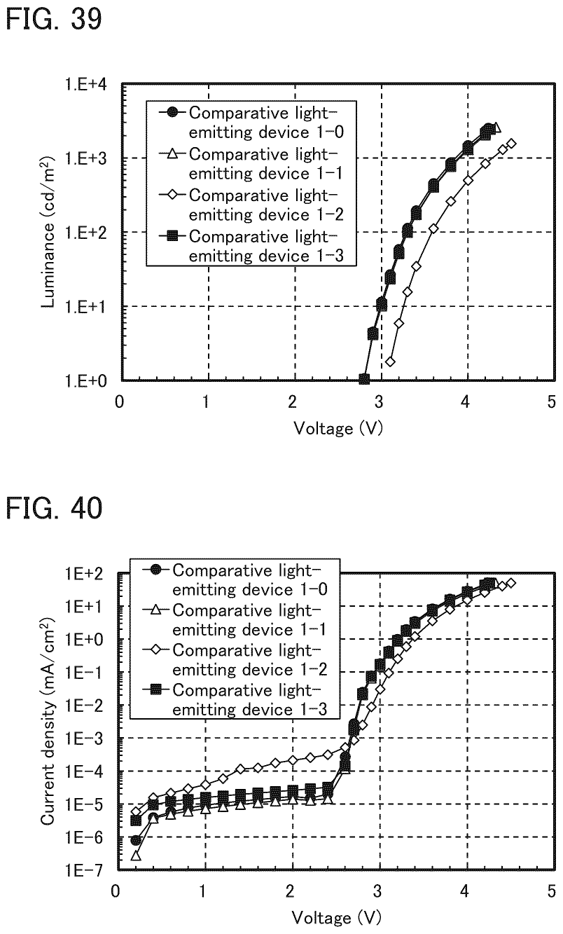

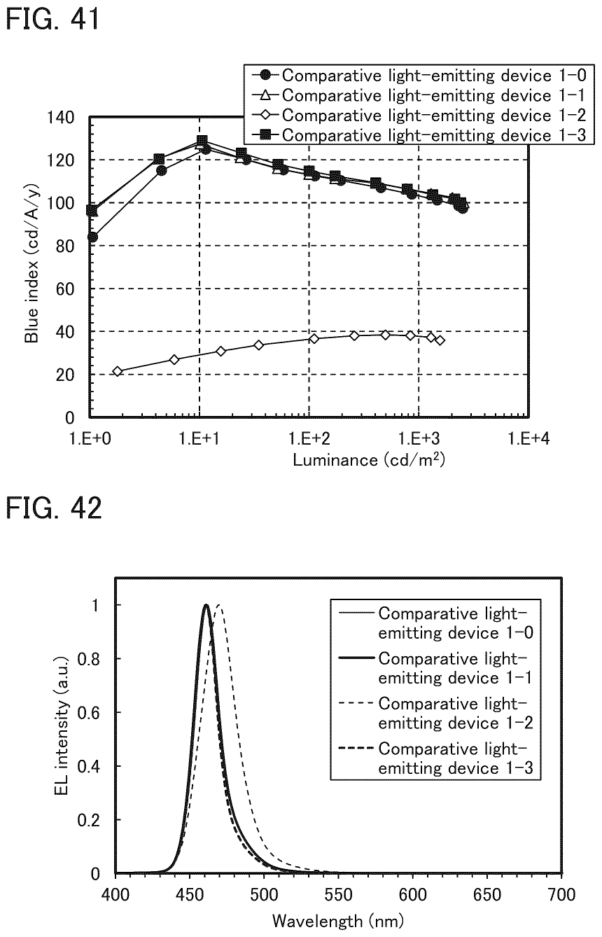

FIG. 37 shows luminance-current density characteristics of these comparative light-emitting devices 1. FIG. 38 shows current efficiency-luminance characteristics thereof. FIG. 39 shows luminance-voltage characteristics thereof. FIG. 40 shows current density-voltage characteristics thereof. FIG. 41 shows blue index-luminance characteristics thereof. FIG. 42 shows emission spectra thereof. The values of the main voltage, current, current density, CIE chromaticity, current efficiency, and blue index at approximately 1000 cd/cm² are shown below. Note that the luminance, CIE chromaticity, and emission spectra were measured at normal temperature with a spectroradiometer (SR-UL1R manufactured by TOPCON CORPORATION).

TABLE 6

| | | | Current | Chroma- | Chroma- | Current | |
|---|---|---|---|---|---|---|---|
| | Voltage | Current | density | ticity | ticity | efficiency | BI |
| | (V) | (mA) | (mA/cm²) | x | y | (cd/A) | (cd/A/y) |
| Comparative | 3.8 | 0.65 | 16.18 | 0.14 | 0.05 | 5 | 104 |
| light-emitting | | | | | | | |
| device 1-0 | | | | | | | |
| Comparative | 3.8 | 0.55 | 13.87 | 0.14 | 0.05 | 6 | 107 |
| light-emitting | | | | | | | |
| device 1-1 | | | | | | | |
| Comparative | 4.2 | 1.02 | 25.60 | 0.13 | 0.09 | 3 | 38 |
| light-emitting | | | | | | | |
| device 1-2 | | | | | | | |
| Comparative | 3.8 | 0.61 | 15.33 | 0.14 | 0.05 | 5 | 106 |
| light-emitting | | | | | | | |
| device 1-3 | | | | | | | |

It was found from FIG. 37 to FIG. 42 that among the comparative light-emitting devices 1, the comparative light-emitting device 1-0 fabricated continuously in a vacuum atmosphere without releasing a vacuum, the comparative light-emitting device 1-1 exposed to the air in the light-blocking state, and the comparative light-emitting device 1-3 exposed to the air under orange light irradiation do not have large differences in characteristics, whereas the comparative light-emitting device 1-2 exposed to the air under fluorescent lamp light irradiation was found to have significantly deteriorated characteristics of driving voltage and current efficiency. Furthermore, the emission spectrum was also changed, resulting in a significant decrease of the blue index.

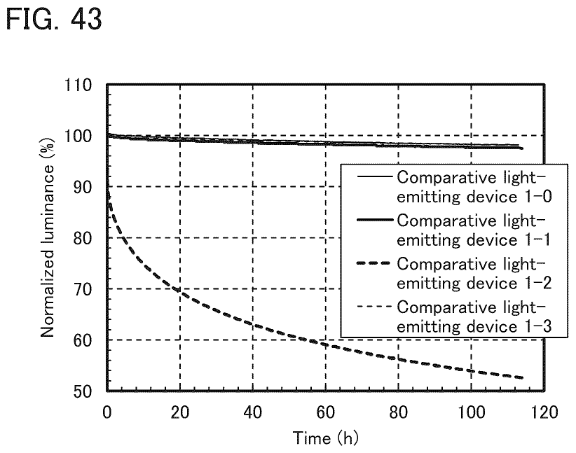

FIG. 43 shows the results of measuring changes in luminance over driving time in constant-current driving at a current density of 50 mA/cm². It was found from FIG. 43 that among the comparative light-emitting devices 1, the comparative light-emitting device 1-2 irradiated with fluorescent lamp light only has greatly reduced reliability.

### (Method for Fabricating Comparative Light-Emitting Device 2-0)

First, 100-nm-thick silver (Ag) as a reflective electrode and 85-nm-thick indium tin oxide including silicon oxide (ITSO) as a transparent electrode were stacked over a glass substrate sequentially from the substrate side by a sputtering method, whereby the first electrode 101 with a size of 2 mm×2 mm was formed. Note that ITSO functions as an anode, and the stacked-layer structure of Ag and ITSO is regarded as the first electrode 101.

Then, pretreatment for formation of the light-emitting device over the substrate was performed by washing the substrate surface with water.

After that, the substrate was transferred into a vacuum evaporation apparatus in which the pressure was reduced to approximately 1×10⁻⁴ Pa, vacuum baking was performed at 170° C. for 30 minutes in a heating chamber of the vacuum evaporation apparatus, and then the substrate was cooled down for approximately 30 minutes.

Then, the substrate was fixed to a substrate holder provided in the vacuum evaporation apparatus such that the surface over which the first electrode 101 was formed faced downward. Over an inorganic insulating film and the first electrode 101, the hole-injection layer 111 was formed by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) to have a thickness of 10 nm and a weight ratio of 1:0.04 (=PCBBiF:OCHD-003).

Over the hole-injection layer 111, the hole-transport layer 112 was formed to have a thickness of 95 nm by evaporation of PCBBiF.

Next, over the hole-transport layer 112, the light-emitting layer 113 was formed by co-evaporation of 11-[(3′-(dibenzothiophen-4-yl)biphenyl-3-yl]phenanthro[9′,10′:4,5]furo[2,3-b]pyrazine (abbreviation: 11mDBtBPPnfpr) represented by Structure Formula (xix) above, PCBBiF, and OCPG-006 which is a red phosphorescent substance to have a thickness of 40 nm and a weight ratio of 0.7:0.3:0.05 (=11mDBtBPPnfpr:PCBBiF:OCPG-006).

After that, a first electron-transport layer was formed to a thickness of 20 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above, and a second electron-transport layer was formed to a thickness of 15 nm by evaporation of 2,9-di(naphthalen-2-yl)-4,7-diphenyl-1,10-phenanthroline (abbreviation: NBPhen) represented by Structural Formula (xviii) above, whereby the electron-transport layer 114 was formed. Note that the first electron-transport layer also functions as a hole-blocking layer.

After that, lithium fluoride (LiF) and ytterbium (Yb) were formed by co-evaporation to a thickness of 2 nm such that the volume ratio of LiF to Yb was 1:0.5 to form the electron-injection layer 115, and then, silver (Ag) and magnesium (Mg) were formed by co-evaporation to a thickness of 20 nm such that the volume ratio of Ag to Mg was 1:0.1 to form the second electrode 102. Over the second electrode 102, a cap layer with a thickness of 70 nm was formed by evaporation of 4,4′,4″-(benzene-1,3,5-triyl)tri(dibenzothiophene) (abbreviation: DBT3P-II) represented by Structural Formula (v) above, so that light extraction efficiency was improved.

The light-emitting device was sealed using a glass substrate in a glove box containing a nitrogen atmosphere so as not to be exposed to the air (a UV curable sealing material was applied to surround the elements, only the sealing material was irradiated with UV while the light-emitting device was prevented from being irradiated with the UV, and heat treatment was performed at 80° C. under an atmospheric pressure for one hour), so that a comparative light-emitting device 2-0 was fabricated.

### (Method for Fabricating Comparative Light-Emitting Device 2-1)

A comparative light-emitting device 2-1 was fabricated in a manner similar to that for the comparative light-emitting device 2-0 except that the electron-injection layer and the components thereafter were formed after standing in an air atmosphere for one hour in the light-blocking state and then heat treatment at 110° C. for one hour in an atmosphere under approximately 1×10⁻⁴ Pa or lower after formation of the electron-transport layer.

### (Method for Fabricating Comparative Light-Emitting Device 2-2)

A comparative light-emitting device 2-2 was fabricated in a manner similar to that for the comparative light-emitting device 2-0 except that the electron-injection layer and the components thereafter were formed after standing in an air atmosphere for one hour under irradiation of fluorescent lamp light and then heat treatment at 110° C. for one hour in an atmosphere under approximately 1×10⁻⁴ Pa or lower after formation of the electron-transport layer. Note that the illuminance of the fluorescent lamp light was 317 lux.

### (Method for Fabricating Comparative Light-Emitting Device 2-3)

A comparative light-emitting device 2-3 was fabricated in a manner similar to that for the comparative light-emitting device 2-0 except that the electron-injection layer and the components thereafter were formed after standing in an air atmosphere for one hour under irradiation of orange light and then heat treatment at 110° C. for one hour in an atmosphere under approximately 1×10⁻⁴ Pa or lower after formation of the electron-transport layer. Note that the illuminance of the orange light was 111 lux.

The element structures of the comparative light-emitting device 2-0 to the comparative light-emitting device 2-3 are listed in the following table.

TABLE 7

| | | | | |
|---|---|---|---|---|
| Film | Comparative | Comparative | Comparative | Comparative |
| thickness | light-emitting | light-emitting | light-emitting | light-emitting |
| (nm) | device 2-0 | device 2-1 | device 2-2 | device 2-3 |

| | | |
|---|---|---|
| Cap layer | 70 | DBT3P-II |
| Second electrode | 20 | Ag:Mg (1:0.1) |
| | 2 | LiF:Yb (2:1) |

| | | | | |
|---|---|---|---|---|
| Air exposure | N/A (Continuous | In light-blocking | Under fluorescent lamp | Under orange light |
| | vacuum) | state | light irradiation | irradiation |

| Electron-transport layer | | 15 | NBPhen |
|---|---|---|---|
| | | 20 | 2mPCCzPDBq |
| Light-emitting layer | | 40 | 11mDBtBPPnfpr:PCBBiF:OCPG-006 |
| | | | (0.7:0.3:0.05) |
| Hole-transport layer | | 95 | PCBBiF |
| Hole-injection layer | | 10 | PCBBiF:OCHD-003 |
| | | | (1:0.04) |
| First | Transparent electrode | 85 | ITSO |
| electrode | Reflective electrode | 100 | Ag |

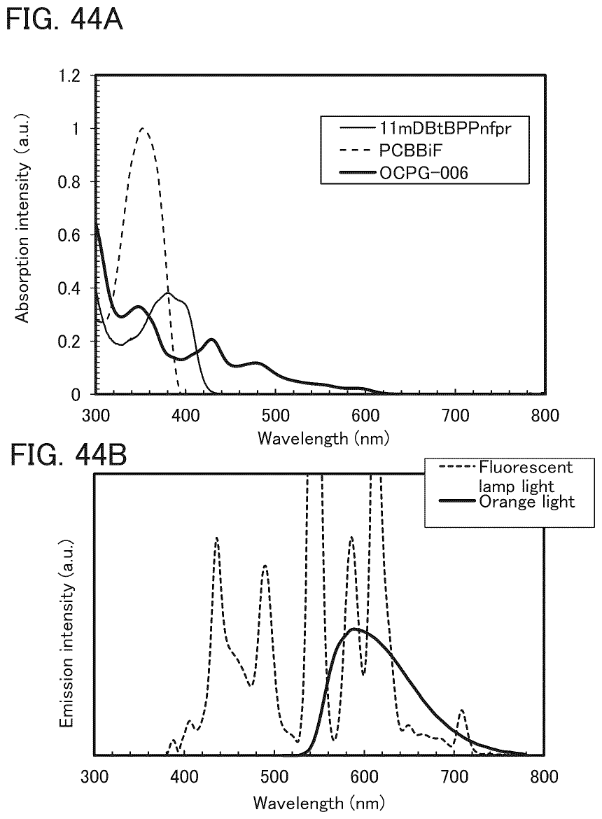

FIG. 44 shows the absorption spectra of the organic compounds used for the light-emitting layer of the comparative light-emitting device 1, the emission spectrum of fluorescent lamp light, and the emission spectrum of orange light.

Note that the absorption spectrum of the host material was measured in a thin-film state. Specifically, each of the organic compounds was formed to a thickness of approximately 50 nm over a quartz substrate and measured. The measurement was performed with a UV-visible spectrophotometer (U-4100, Hitachi High-Technologies Corporation). The absorption spectrum of the thin film was calculated using an absorbance (−log₁₀ (% T/(100−% R))) obtained from a transmittance and a reflectance of the substrate and the thin film.

The measurement was performed on a light-emitting substance in a solution state. Specifically, an absorption spectrum (ultraviolet-visible absorption spectrum) of OCPG-006 in a dichloromethane solution was measured. The absorption spectrum was measured with an ultraviolet-visible spectrophotometer (V550 manufactured by JASCO Corporation).

From FIG. 44 and the above structural formulae, it was found that 11mDBtBPPnfpr which is the substance other than the light-emitting substance used for the comparative light-emitting device 1 has the longest-wavelength absorption edge in the absorption spectrum at a wavelength of greater than or equal to 400 nm, has a structure where two adjacent six-membered aromatic rings are fused, has a naphthalene skeleton, and includes a fused ring composed only of six-membered rings; thus, it is confirmed that the light-emitting device is not the light-emitting device of one embodiment of the present invention.

Specifically, the longest-wavelength absorption edge among the absorption edges in the absorption spectrum of PCBBiF was at 399 nm and that of 11mDBtBPPnfpr was at 421 nm. The absorbance at a wavelength of 400 nm of PCBBiF was 0.04, and the absorbance at a wavelength of 400 nm of 11 mDBtBPPnfpr was 0.24.

The longest-wavelength absorption edge among the absorption edges in the absorption spectrum of OCPG-006 was at 621 nm. The molar absorption coefficient at a wavelength of 429 nm of OCPG-006 was 13920 M⁻¹·cm⁻¹.

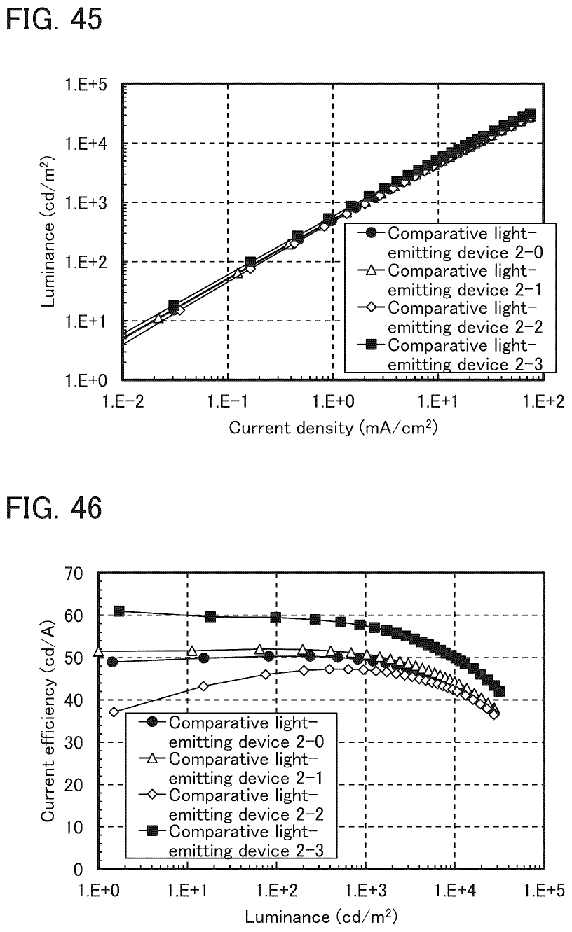

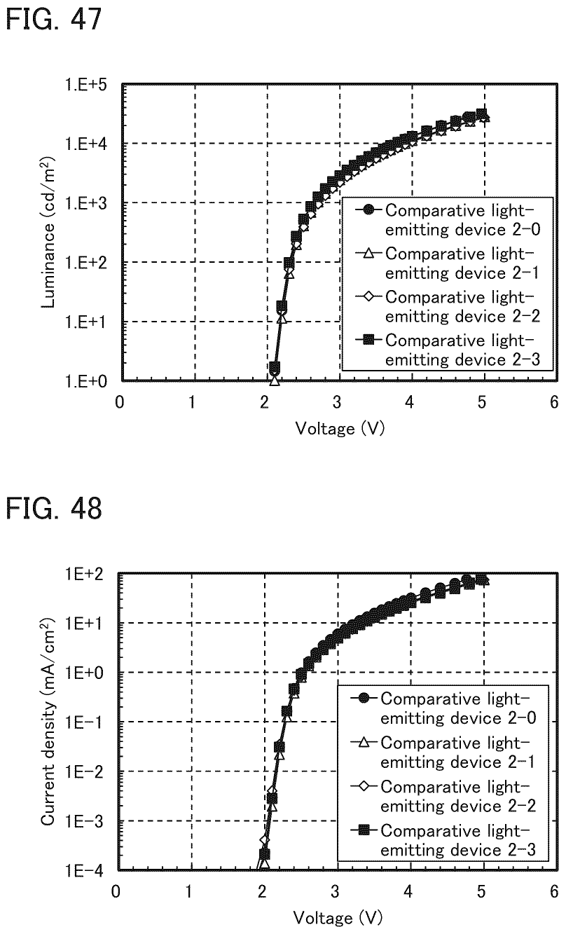

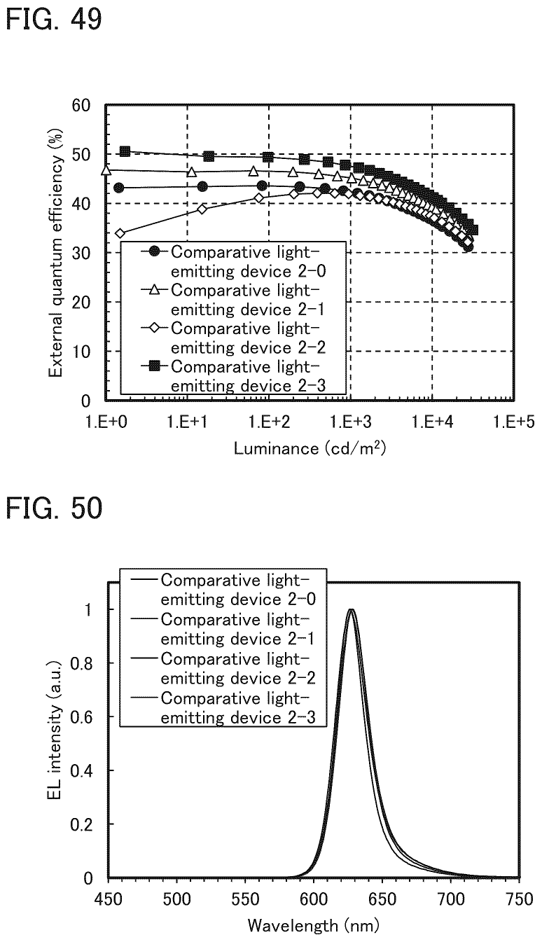

FIG. 45 shows the luminance-current density characteristics of these comparative light-emitting devices 1. FIG. 46 shows the current efficiency-luminance characteristics thereof. FIG. 47 shows the luminance-voltage characteristics thereof. FIG. 48 shows the current density-voltage characteristics thereof. FIG. 49 shows the external quantum efficiency-luminance characteristics thereof, and FIG. 50 shows the emission spectra thereof. The values of the main voltage, current, current density, CIE chromaticity, and current efficiency at approximately 1000 cd/cm² are shown below. Note that the luminance, CIE chromaticity, and emission spectra were measured at normal temperature with a spectroradiometer (SR-UL1R manufactured by TOPCON CORPORATION).

TABLE 8

| | | | Current | Chroma- | Chroma- | Current | External |
|---|---|---|---|---|---|---|---|
| | Voltage | Current | density | ticity | ticity | efficiency | quantum |
| | (V) | (mA) | (mA/cm²) | x | y | (cd/A) | efficiency (%) |
| Comparative | 2.6 | 0.07 | 1.64 | 0.69 | 0.31 | 50 | 43 |
| light-emitting | | | | | | | |
| device 2-0 | | | | | | | |
| Comparative | 2.7 | 0.08 | 2.03 | 0.70 | 0.30 | 51 | 45 |
| light-emitting | | | | | | | |
| device 2-1 | | | | | | | |
| Comparative | 2.7 | 0.08 | 2.01 | 0.70 | 0.30 | 47 | 42 |
| light-emitting | | | | | | | |
| device 2-2 | | | | | | | |
| Comparative | 2.6 | 0.06 | 1.49 | 0.69 | 0.31 | 58 | 48 |
| light-emitting | | | | | | | |
| device 2-3 | | | | | | | |

It was found from FIG. 45 to FIG. 50 that among the comparative light-emitting devices 2, the comparative light-emitting device 2-0 fabricated continuously in a vacuum atmosphere without releasing a vacuum, the comparative light-emitting device 2-1 exposed to the air in the light-blocking state, and the comparative light-emitting device 2-3 exposed to the air under orange light irradiation do not have large difference in characteristics, whereas the comparative light-emitting device 2-2 exposed to the air under fluorescent lamp light irradiation was found to have significantly deteriorated characteristics of the driving voltage and current efficiency.

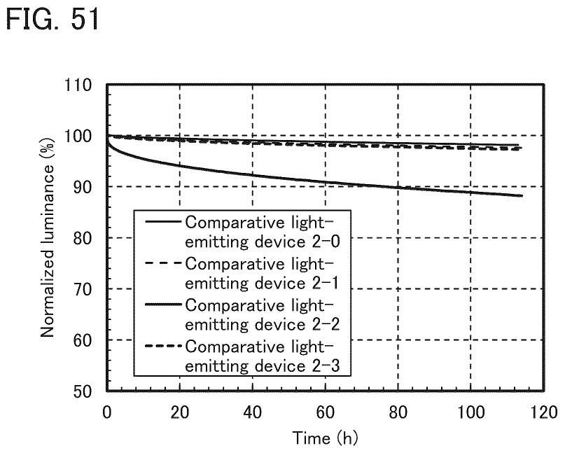

FIG. 51 shows the results of measuring changes in luminance over driving time in constant-current driving at a current density of 50 mA/cm². It was found from FIG. 51 that among the comparative light-emitting devices 2, the comparative light-emitting device 2-2 irradiated with fluorescent lamp light only has greatly reduced reliability.

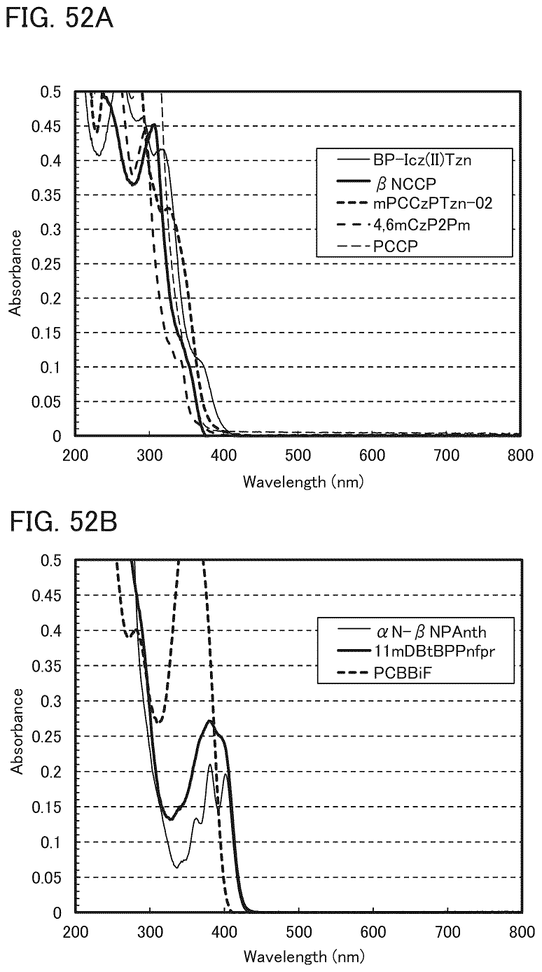

FIG. 52A is a graph showing the absorbances of the organic compounds other than the light-emitting substance (host materials) used in any of the light-emitting devices of one embodiment of the present invention (the light-emitting device 1 to the light-emitting device 4), and FIG. 52B is a graph showing the absorbances of the organic compounds other than the light-emitting substance (host materials) used in any of the light-emitting devices as comparative examples (the comparative light-emitting device 1 or the comparative light-emitting device 2). Note that these absorbances were each obtained by measuring a 50-nm-thick film which was formed of an organic compound to be measured. As described above, the light-emitting device of one embodiment of the present invention using a substance whose absorbance at a wavelength of 400 nm to 475 nm is less than or equal to 0.01 can have small reductions in initial characteristics and reliability even when exposed to air under white light irradiation. Note that even when the absorbance of the substance at a wavelength of 400 nm to 475 nm is greater than or equal to 0.01, in the case where the substance is, for example, BP-Icz(II)Tzn not having a weak naphthalene structure, the light-emitting device can have favorable characteristics even after exposure to the air and white light irradiation. Even when an organic compound does not include a naphthalene structure, the absorbance at a wavelength of 400 nm to 475 nm is preferably less than or equal to 0.01.

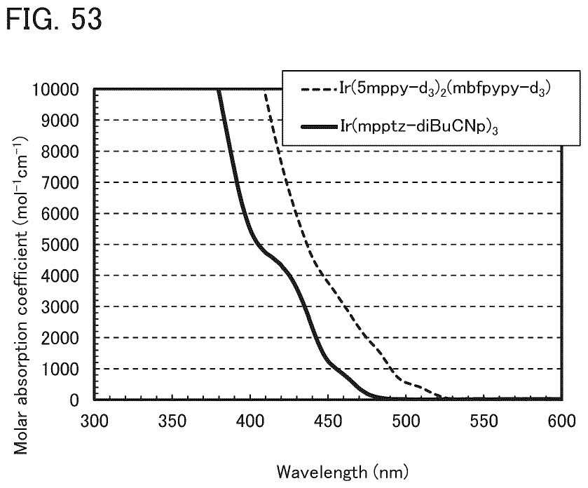

Note that FIG. 53 shows the molar absorption coefficients of the light-emitting substances used for the light-emitting device 1 to the light-emitting device 5. It was found that even when the light-emitting substance contained in the light-emitting layer together with the host material has the molar absorption coefficient higher than or equal to 1000 M⁻¹·cm⁻¹ at a wavelength of 400 nm to 475 nm, the characteristics of the light-emitting device of one embodiment of the present invention are not adversely affected.

### REFERENCE NUMERALS

100A: display apparatus, 100B: display apparatus, 100C: display apparatus, 100E: display apparatus, 100D: display apparatus, 101A: first electrode group, 101a: first electrode, 101b: first electrode, 101: first electrode, 102: second electrode, 103a: organic compound layer, 103b: organic compound layer, 103Bf: organic compound film, 103Gf: organic compound film, 103Rf: organic compound film, 103: organic compound layer, 104: first layer, 105: second layer, 110B: subpixel, 110G: subpixel, 110R: subpixel, 110: subpixel, 111a: hole-injection layer, 111b: hole-injection layer, 111: hole-injection layer, 112: hole-transport layer, 112a: hole-transport layer, 112b: hole-transport layer, 112B: conductive layer, 112R: conductive layer, 113: light-emitting layer, 113a: light-emitting layer, 113b: light-emitting layer, 114: electron-transport layer, 114a: electron-transport layer, 114b: electron-transport layer, 115: electron-injection layer, 116: charge-generation layer, 117: P-type layer, 118: electron-relay layer, 119: electron-injection buffer layer, 120: substrate, 122: resin layer, 125f: inorganic insulating film, 125: inorganic insulating layer, 126R: conductive layer, 126B: conductive layer, 127a: insulating layer, 127f: insulating film, 127: insulating layer, 128: layer, 129R: conductive layer, 129B: conductive layer, 130a: light-emitting device, 130B: light-emitting device, 130b: light-emitting device, 130G: light-emitting device, 130R: light-emitting device, 130: light-emitting device, 131: protective layer, 132B: coloring layer, 132G: coloring layer, 132R: coloring layer, 135: first layer, 135A: first layer group, 135a: first layer, 135b: first layer, 135R: first layer, 135G: first layer, 135B: first layer, 136: common layer, 140: connection portion, 141: region, 142: adhesive layer, 151B: conductive layer, 151C: conductive layer, 151cf: conductive film, 151f: conductive film, 151G: conductive layer, 151R: conductive layer, 151: conductive layer, 152B: conductive layer, 152C: conductive layer, 152f: conductive film, 152G: conductive layer, 152R: conductive layer, 152: conductive layer, 153: insulating layer, 156B: insulating layer, 156C: insulating layer, 156f: insulating film, 156G: insulating layer, 156R: insulating layer, 156: insulating layer, 157: light-blocking layer, 158B: sacrificial layer, 158Bf: sacrificial film, 158G: sacrificial layer, 158Gf: sacrificial film, 158R: sacrificial layer, 158Rf: sacrificial film, 159B: mask layer, 159Bf: mask film, 159G: mask layer, 159Gf: mask film, 159R: mask layer, 159Rf: mask film, 166: conductive layer, 171: insulating layer, 172: conductive layer, 173: insulating layer, 174: insulating layer, 175: insulating layer, 176: plug, 177: pixel portion, 178: pixel, 179: conductive layer, 190B: resist mask, 190G: resist mask, 190R: resist mask, 191: resist mask, 201: transistor, 204: connection portion, 205: transistor, 211: insulating layer, 213: insulating layer, 214: insulating layer, 215: insulating layer, 221: conductive layer, 222a: conductive layer, 222b: conductive layer, 223: conductive layer, 224B: conductive layer, 224C: conductive layer, 224G: conductive layer, 224R: conductive layer, 231: semiconductor layer, 240: capacitor, 241: conductive layer, 242: connection layer, 243: insulating layer, 245: conductive layer, 254: insulating layer, 255: insulating layer, 256: plug, 261: insulating layer, 271: plug, 280: display module, 281: display portion, 282: circuitportion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 351: substrate, 352: substrate, 353: FPC, 354: IC, 355: wiring, 356: circuit, 501: first electrode, 502: second electrode, 513: charge-generation layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 1117: light-blocking layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote controller, 7171: housing, 7173: stand, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9171: portable information terminal, 9172: portable information terminal, 9173: tablet terminal, 9200: portable information terminal, 9201: portable information terminal

1. A light-emitting device group comprising:
a first light-emitting device comprising:
a first bottom electrode included in a first electrode group over an insulating surface;
a second electrode over the first electrode group; and
first layers included in a first layer group between the first bottom electrode and the second electrode,
a second light-emitting device comprising:
a second bottom electrode included in the first electrode group over the insulating surface;
the second electrode over the second bottom electrode; and
second layers included in the first layer group between the second bottom electrode and the second electrode; and
a third light-emitting device comprising:
a third bottom electrode included in the first electrode group over the insulating surface;
the second electrode over the third bottom electrode; and
third layers included in the first layer group between the third bottom electrode and the second electrode,
wherein the first bottom electrode, the second bottom electrode and the third bottom electrode are independent from each other in,
wherein the second electrode is a continuous conductive layer shared by the first light-emitting device, the second light-emitting device and the third light-emitting device,
wherein the first bottom electrode, the second electrode and the first lavers overlap each other,
wherein the first lavers comprises a first light-emitting layer,
wherein the first light-emitting layer comprises a first emission center substance and a first substance,
wherein the first emission center substance is capable of emitting a fluorescence having a spectrum peak at a wavelength of less than or equal to 500 nm or emitting a phosphorescence having a spectrum peak in a wavelength range of 600 nm to 700 nm,
wherein a longest-wavelength absorption edge in an absorption spectrum of the first substance is at a wavelength of less than 400 nm, and
wherein a distance between the first layers and the second layers is greater than or equal to 2 μm and less than or equal to 5 μm.

2. A light-emitting device group comprising:
a first light-emitting device comprising:
a first bottom electrode included in a first electrode group over an insulating surface;
a second electrode over the first electrode group; and
first layers included in a first layer group between the first bottom electrode and the second electrode,
a second light-emitting device comprising:
a second bottom electrode included in the first electrode group over the insulating surface;
the second electrode over the second bottom electrode; and
second layers included in the first layer group between the second bottom electrode and the second electrode; and
a third light-emitting device comprising.
a third bottom electrode included in the first electrode group over the insulating surface;
the second electrode over the third bottom electrode; and
third layers included in the first layer group between the third bottom electrode and the second electrode,
wherein the first bottom electrode, the second bottom electrode and the third bottom electrode are independent from each other,
wherein the second electrode is a continuous conductive layer shared by the first light-emitting device, the second light-emitting device and the third light-emitting device,
wherein the first bottom electrode, the second electrode and the first layers overlap each other,
wherein the first layers comprises a first light-emitting layer,
wherein the first light-emitting layer comprises a first emission center substance and a first substance,
wherein the first emission center substance is capable of emitting a fluorescence having a spectrum peak at a wavelength of less than or equal to 500 nm or emitting a phosphorescence having a spectrum peak in a wavelength range of 600 nm to 700 nm,
wherein a longest-wavelength absorption edge in an absorption spectrum of the first substance is at a wavelength of less than 400 nm,
wherein the first substance does not comprise a fused ring composed only of six-membered rings, and
wherein a distance between the first layers and the second layers is greater than or equal to 2 μm and less than or equal to 5 μm.

3. A light-emitting device group comprising:
a first light-emitting device comprising:
a first bottom electrode included in a first electrode group over an insulating surface;
a second electrode over the first electrode group; and
first layers included in a first layer group between the first bottom electrode and the second electrode;
a second light-emitting device comprising:
a second bottom electrode included in the first electrode group over the insulating surface;
the second electrode over the second bottom electrode; and
second layers included in the first layer group between the second bottom electrode and the second electrode; and
a third light-emitting device comprising:
a third bottom electrode included in the first electrode group over the insulating surface;
the second electrode over the third bottom electrode; and
third layers included in the first layer group between the third bottom electrode and the second electrode,
wherein the first bottom electrode, the second bottom electrode and the third bottom electrode are independent from each other in,
wherein the second electrode is a continuous conductive layer shared by the first light-emitting device, the second light-emitting device and the third light-emitting device,
wherein the first bottom electrode, the second electrode and the first lavers overlap each other,
wherein the first lavers comprises a first light-emitting layer,
wherein the first light-emitting layer comprises a first emission center substance and a first substance,
wherein the first emission center substance is capable of emitting a fluorescence having a spectrum peak at a wavelength of less than or equal to 500 nm or emitting a phosphorescence having a spectrum peak in a wavelength range of 600 nm to 700 nm,
wherein a longest-wavelength absorption edge in an absorption spectrum of the first substance is at a wavelength of less than 400 nm,
wherein the first substance comprises none of a structure where two adjacent six-membered aromatic rings are fused, a structure where two adjacent six-membered heteroaromatic rings are fused, and a structure where a six-membered aromatic ring and a six-membered heteroaromatic ring that are adjacent to each other are fused, and
wherein a distance between the first layers and the second layers is greater than or equal to 2 μm and less than or equal to 5 μm.

4. (canceled)

5. (canceled)

6. (canceled)

7. (canceled)

8. (canceled)

9. The light-emitting device group according to claim 1, wherein the first substance does not absorb light with a wavelength of greater than or equal to 400 nm and less than or equal to 475 nm.

10. (canceled)

11. The light-emitting device group according to claim 1, wherein a difference between a wavelength of a longest-wavelength absorption edge in an absorption spectrum of the first emission center substance and a wavelength of a longest-wavelength absorption edge in an absorption spectrum of the first substance is greater than or equal to 60 nm.

12. The light-emitting device group according to claim 1, wherein an absorbance at a wavelength of greater than or equal to 400 nm and less than or equal to 475 nm of a 50-nm-thick film comprising the first substance is less than or equal to 0.01.

13. The light-emitting device group according to claim 1, wherein a molar absorption coefficient at a wavelength of greater than or equal to 400 nm and less than or equal to 475 nm of the first emission center substance is greater than or equal to 1000 M⁻¹·cm⁻¹.

14. The light-emitting device group according to claim 1, wherein the first substance comprises none of a naphthalene ring, a phenanthrene ring and a naphthacene ring.

15. The light-emitting device group according to claim 1,
wherein the first substance comprises a first fused ring, and
wherein a six-membered ring and a five-membered ring are alternately fused in the first fused ring.

16. The light-emitting device group according to claim 1,
wherein the second layers comprises a second light-emitting layer,
wherein the second light-emitting layer comprises a second emission center substance, a second substance and a third substance,
wherein the first emission center substance is capable of emitting a phosphorescence having a spectrum peak in a wavelength range of 500 nm to 600 nm,
wherein the second substance and the third substance are a combination forming an exciplex,
wherein an absorption band having a longest wavelength of the second emission center substance and an emission spectrum of the exciplex overlap each other, and
wherein a difference between a wavelength of a longest-wavelength absorption edge in an absorption spectrum of the first emission center substance and a wavelength of a longest-wavelength absorption edge in an absorption spectrum of the first substance is greater than or equal to 60 nm.

17. The light-emitting device group according to claim 16, wherein the first emission center substance is capable of emitting a fluorescence having a spectrum peak at a wavelength of less than or equal to 500 nm.

18. The light-emitting device group according to claim 16, wherein the first emission center substance is capable of emitting a phosphorescence having a spectrum peak in a wavelength range of 600 nm to 700 nm.
